(19) United States
(12) Patent Application Publication
(10) Pub. No.: US 2026/0299557 A1
(43) Pub. Date: Oct. 1, 2026

(54) ARTIFICIAL INTELLIGENCE-BASED INVENTORY MANAGEMENT FOR AUTONOMOUS SYSTEMS AND APPLICATIONS

(71) Applicant: NVIDIA Corporation, Santa Clara, CA (US)

(72) Inventors: Akul Santhosh, Santa Clara, CA (US); Aastha Jhunjhunwala, Santa Clara, CA (US); Sameer Dhillon, Union City, CA (US)

(21) Appl. No.: 19/091,183

(22) Filed: Mar. 26, 2025

(51) Int. Cl. G05B 19/4155; G06F 30/13; G06T 11/60

(52) U.S. Cl. CPC G05B 19/4155; G06F 30/13; G06T 11/60; G05B 2219/50391

(57) ABSTRACT

In various examples, Artificial Intelligence (AI)-based systems and methods may be used to autonomously manage the movement of items in a variety of environments, such as a retail space. For instance, the systems and methods of the present disclosure may (e.g., using one or more AI models) continuously update a virtual representation (e.g., digital twin) of an environment based on images depicting the environment. The virtual representation of the environment may be used to track locations of various objects in real time. In some examples, the systems of the present disclosure may use the virtual representation of the environment to select optimal machines for moving items, select optimal paths for the machines to follow, etc. Additionally, the systems of the present disclosure may use 3D models of items in the virtual representation to determine grasps and/or control commands for manipulators of the machines to pick up the items.

### BACKGROUND

Automation has been increasingly used across various industries to improve efficiency, reduce labor costs, and enhance operational accuracy. For instance, autonomous systems may assist with assembly and material handling in manufacturing use cases. Similarly, automated warehouses may use autonomous picking systems and self-navigating transport units to streamline order fulfillment. In addition, advancements in computer vision, artificial intelligence (AI), and machine learning have enabled automated systems to perform increasingly complex tasks with minimal human intervention. These technologies may enhance operational scalability, improve data-driven decision-making, and reduce dependency on manual processes.

However, existing automated solutions are often limited in their ability to dynamically adapt to real-time changes in their operating environments. For instance, conventional systems may rely on pre-programmed routes or static databases, which may not account for shifting obstacles, fluctuating resource availability, or changes in demand. Additionally, many automated systems may operate in isolation and lack integration between perception, planning, and execution, which may result in inefficiencies, such as delays in task execution or discrepancies between recorded and actual system states. Furthermore, existing solutions may not incorporate AI-driven task decomposition, requiring predefined workflows that may not generalize well to dynamic and unstructured environments. As a result, existing systems may struggle to optimize performance in real-world conditions where adaptability is critical.

### SUMMARY

Embodiments of the present disclosure relate to AI-based inventory management for autonomous systems and applications. Systems and methods are disclosed that may autonomously manage inventory and/or the movement of items in a variety of environments using Artificial Intelligence (AI)-based techniques. For instance, the systems and methods of the present disclosure may (e.g., using one or more AI models) continuously update a virtual representation (e.g., digital twin) of an environment based on images depicting the environment. The virtual representation of the environment may be used to track locations of various objects in real time, such as autonomous machines (e.g., robots), people, obstacles, items, or any other objects. In some examples, an agentic AI system may keep track of item information (e.g., inventories, locations, etc.) in real-time as items are added, removed, or moved within the environment, and the virtual representation of the environment may be updated using the item information. Additionally, in some instances, the systems of the present disclosure may use the virtual representation of the environment to select optimal machines for moving items, select optimal paths for the machines to follow, etc. Further, the systems of the present disclosure may use 3D models of items in the virtual representation to determine grasps and/or control commands for manipulators of the machines to pick up the items.

In contrast to conventional systems, the systems of the present disclosure, in some embodiments, are able to dynamically adapt to real-time environmental changes by leveraging a combination of multi-camera tracking, AI-based perception, and intelligent planning. For instance, unlike conventional systems that depend on static routes or pre-defined workflows, the systems of the present disclosure may integrate global and local navigation frameworks to optimize movement and execution of tasks in dynamic spaces (e.g., retail spaces), as described in detail herein. By maintaining a continuously updated virtual environment (also referred to as a “digital twin”), the systems of the present disclosure may ensure that real-world inventory changes, obstacle shifts, and operational disruptions are accounted for in real time. Additionally, by using agentic AI to perform task decomposition, the systems of the present disclosure may transform complex user requests into structured sequences of executable subtasks, enabling efficient coordination between perception, planning, and execution. Further, by generating and using 3D models within the virtual environment to generate grasp predictions for robotic manipulators using AI, the systems of the present disclosure may enable robotic systems to autonomously and accurately retrieve, transport, and place objects with minimal error. Thus, by integrating AI-driven task decomposition with real-time simulation updates and advanced robotic control, the disclosed systems and methods may improve upon inventory management and autonomous operations in dynamic environments, in contrast to conventional systems.

### BRIEF DESCRIPTION OF THE DRAWINGS

The present systems and methods for AI-based inventory management for autonomous systems and applications are described in detail below with reference to the attached drawing figures, wherein:

FIG. 1 is a data flow diagram illustrating an example of a process that may be performed by a system to autonomously manage an inventory of items in a dynamic environment, in accordance with some embodiments of the present disclosure;

FIG. 2 is a data flow diagram illustrating an example of a process for generating and/or updating a simulation of an environment (e.g., digital twin), in accordance with some embodiments of the present disclosure;

FIG. 3 is a data flow diagram illustrating an example of a process for determining optimized paths for navigating from a first location to a second location in a dynamic environment, in accordance with some embodiments of the present disclosure;

FIG. 4 is a data flow diagram illustrating an example of a process for generating grasp predictions for robotic manipulators to grasp items, in accordance with some embodiments of the present disclosure;

FIG. 5 is a data flow diagram illustrating an example of a process for determining control commands for controlling one or more machines, in accordance with some embodiments of the present disclosure;

FIG. 6 is a flow diagram illustrating an example of a method, which may be performed using the systems described herein, for autonomously moving items in a dynamic environment responsive to various user requests, in accordance with some embodiments of the present disclosure;

FIG. 7 is a flow diagram illustrating an example of a method for automated inventory management, in accordance with some embodiments of the present disclosure;

FIG. 8 is a flow diagram illustrating an example of a method for using a simulated version of an environment to determine optimal autonomous machines and operations for performing various tasks, in accordance with some embodiments of the present disclosure;

FIG. 9A is a block diagram of an example generative language model system suitable for use in implementing at least some embodiments of the present disclosure;

FIG. 9B is a block diagram of an example generative language model that includes a transformer encoder-decoder suitable for use in implementing at least some embodiments of the present disclosure;

FIG. 9C is a block diagram of an example generative language model that includes a decoder-only transformer architecture suitable for use in implementing at least some embodiments of the present disclosure;

FIG. 10 illustrates an example parallel processing unit suitable for use in implementing at least some embodiments of the present disclosure;

FIG. 11A illustrates an example general processing cluster within the parallel processing unit of FIG. 10 suitable for use in implementing at least some embodiments of the present disclosure;

FIG. 11B illustrates an example memory partition unit of the parallel processing unit of FIG. 10 suitable for use in implementing at least some embodiments of the present disclosure;

FIG. 12A illustrates an example of the streaming multi-processor of FIG. 11A suitable for use in implementing at least some embodiments of the present disclosure;

FIG. 12B is an example conceptual diagram of a processing system implemented using the PPU of FIG. 10 suitable for use in implementing at least some embodiments of the present disclosure;

FIG. 12C illustrates an example system in which the various architecture and/or functionality of the various embodiments may be implemented;

FIG. 13 illustrates an example ray tracing pipeline suitable for use in implementing at least some embodiments of the present disclosure;

FIG. 14 illustrates an example acceleration structure suitable for use in implementing at least some embodiments of the present disclosure;

FIG. 15 illustrates an example shader record suitable for use in implementing at least some embodiments of the present disclosure;

FIG. 16A is an illustration of an example autonomous vehicle, in accordance with some embodiments of the present disclosure;

FIG. 16B is an example of camera locations and fields of view for the example autonomous vehicle of FIG. 16A, in accordance with some embodiments of the present disclosure;

FIG. 16C is a block diagram of an example system architecture for the example autonomous vehicle of FIG. 16A, in accordance with some embodiments of the present disclosure;

FIG. 16D is a system diagram for communication between cloud-based server(s) and the example autonomous vehicle of FIG. 16A, in accordance with some embodiments of the present disclosure;

FIG. 17 is a block diagram of an example computing device suitable for use in implementing at least some embodiments of the present disclosure; and

FIG. 18 is a block diagram of an example data center suitable for use in implementing at least some embodiments of the present disclosure.

### DETAILED DESCRIPTION

Systems and methods are disclosed related to AI-based inventory management for autonomous systems and applications. For instance, a system(s) may obtain input data representing requests related to items located in an environment (e.g., a retail space). In some examples, the requests may include, but are not limited to, requests to purchase items, requests to move or rearrange items, requests to restock items, or any other requests. The system(s) may use an agentic AI architecture (e.g., one or more LLM agents) to process the input data and break the requests down into a plurality of tasks, which may then be provided to a platform (e.g., a spatial computing platform and/or a virtual simulation ecosystem, such as Nvidia's Omniverse). In some instances, the platform may continuously generate and/or update a simulated (e.g., virtual, 3D, etc.) version of the environment (also referred to as a “digital twin”) based on various data sources. These data sources may include, but are not limited to, real-time sensor data (e.g., image data) generated using one or more sensors (e.g., cameras) located within the environment, inventory and/or item information indicative of locations or positions of items, item statuses, item descriptions, and/or any other data sources. Based at least on receiving the tasks associated with the requests, the platform may use the simulated version of the environment to make various decisions, such as determining optimal machines (e.g., autonomous mobile robots) to deploy to complete the tasks, determining optimal paths for the machines to follow through the environment, determining grasp predictions for manipulators of the machines, or any other kinds of decisions based on the simulation. The platform may then send various control commands or instructions to the machines to cause the machines to perform a variety of operations associated with completing the tasks.

As described herein, in some examples, the input data may be text data, audio data, image data, or any other type of data capable of representing a request (e.g., a user request). The system(s) may include and/or use an agentic AI architecture (or “AI agents”) to convert the input data/request into a series of instructions or “tasks” that downstream components (e.g., a planner component) of the system(s) may execute. In some instances, the agentic AI architecture may include a series of language models (e.g., large language models (LLMs)) that may work together to decompose the input data/request into smaller tasks with predefined logic. For instance, the LLM agent system may process a user request and break it down into step-by-step actions that the system(s) can execute. These tasks may be mapped to different operational components, such as navigation planning, object manipulation, and inventory updates.

In some examples, the system(s) may include a platform, such as a spatial computing platform and/or a virtual simulation ecosystem (e.g., Nvidia's Omniverse). For instance, the platform may include various application programming interfaces (APIs), software development kits (SDKs), and/or services that may integrate Open Universal Scene Description (OpenUSD), real-time ray tracing rendering technologies (e.g., Nvidia RTX), and/or generative physical AI into existing software tools and/or simulation workflows for industrial and/or robotic use cases.

In some instances, the system(s) may use the platform to generate and/or continuously update the simulated version of the environment. The simulated environment may serve as a source of truth and, in some instances, a central control point for the system(s). In some examples, the generation of the simulated environment may be a one-time operation and then updated continuously in real-time as objects (e.g., people, machines, obstacles, etc.) appear and move within the environment. As described herein, the system(s) and or platform may integrate data from multiple sources—such as multi-camera tracking technology (e.g., NVIDIA Metropolis Multi Tracking Multi Camera (MTMC)), inventory tracking systems, sensor data from autonomous machines, etc.—to ensure accurate and up-to-date spatial representations of the environment.

In at least one example, the system(s) and/or platform may generate and/or update the simulated environment based on sensor data (e.g., image data) generated using one or more sensors (e.g., cameras) disposed in the environment. For instance, multiple cameras may be positioned in the environment such that a birds-eye-view (e.g., top-down) of the environment may be captured. In some examples, the system(s) may use multi-camera tracking (e.g., Nvidia's Metropolis MTMC) to detect objects (e.g., humans, robots, etc.) within the images depicting the environment. For example, the system(s) may use multi-camera tracking to analyze video feeds from multiple angles to track the movement of objects and identify changes in item placements, among other things. The tracking data may then be processed and synchronized with the digital twin, ensuring that the simulated environment accurately reflects the current state of the physical space. In some instances, AI-based object recognition models may be applied to classify detected objects, distinguishing between different types of items, autonomous machines, store personnel, or any other kinds of objects.

In some examples, the system(s) and/or platform may generate and/or update the simulated environment based on information obtained from an inventory management system (e.g., inventory management database). The inventory management system may be used to store information associated with one or more (e.g., each) items in the environment, such as item position(s), item status(es), item quantities, item descriptions, or any other information. In various examples, the system(s) and/or platform may synchronize updates to the inventory management system with updates to the simulated environment to ensure consistency between virtual representations and real-world conditions. For example, the system(s) may use the information in the inventory management database to position and/or populate 3D models of items within the simulated environment. In this way, the 3D models of items may be searched and fetched by the system(s) (e.g., using NVIDIA DeepSearch). In some examples, the AI agents and/or the platform may update the item information stored in the database in real time as changes occur. For instance, the current status of an item may be updated by the AI agents as an item transitions from being placed on a shelf, to being in motion with a robot, to being purchased, and/or through any other scenarios.

As described herein, in some instances, the AI agents may convert the input data/request into a plurality of tasks, and the system(s) may process these tasks to generate an execution plan for performing the tasks. For instance, the input data may represent a request to purchase one or more items, restock one or more items, rearrange one or more items, or any other type of requests, and the system(s) and/or platform may use the digital twin of the environment to determine the execution plan. The execution plan may include, in some instances, determining optimal machines to deploy to item pickup locations, determining optimal paths for the machines to traverse while in transit, determining predicted grasps/poses for manipulators of the machines to grasp the items, etc.

In some examples, the system(s) and/or platform may determine optimal paths for the machines (e.g., autonomous robots) to traverse between locations within the environment (e.g., to ensure optimal task performance). For instance, the system(s) may generate waypoint graphs that include nodes corresponding to relevant locations, such as item pickup locations, current machine locations, item drop off locations, or any other relevant locations in the environment. The system(s) may determine the optimal paths for the machines based at least on computing distances between nodes in the waypoint graphs. In some instances, the system(s) may use optimization algorithms (e.g., shortest path algorithms such as NVIDIA CuOPT) to determine the most efficient paths for the machines to follow. These paths may be dynamically adjusted based on changes in the environment, such as newly detected obstacles and/or updated item locations.

Additionally, in some instances, the system(s) may determine optimal machines to deploy for various tasks. For instance, the system(s) may assess a number of factors or constraints such as machine availability, proximity to the task location, current task assignments, and battery levels to select the most suitable machine(s) for tasks (e.g., each task). The selection process may also consider machine capabilities, such as whether a particular robot is equipped with a manipulator arm for grasping objects or whether it is better suited for transportation tasks. In at least one example, the system(s) may dynamically allocate tasks among multiple machines to improve efficiency and balance workload distribution. In such instances, if a machine encounters an obstacle or unexpected delay, the system(s) may reassign the task to another available machine that may be able to complete the task more efficiently.

The system(s) may also use AI-driven perception models to enhance task execution. For example, autonomous robots equipped with computer vision capabilities may analyze their surroundings in real-time to refine their movements, improve grasping accuracy, and avoid obstacles. These robots may communicate with the digital twin to provide real-time updates on task progress and environmental changes, ensuring synchronized operations between the physical and virtual environments.

In various examples, the system(s) may use perception models to facilitate the ability of the machines to grasp and manipulate different objects in the environment. For instance, the system(s) may generate or retrieve three-dimensional (3D) models corresponding to the items in the environment and use AI-based grasp prediction models (e.g., NVIDIA Isaac Manipulator Foundation Grasp) to generate dense grasp predictions for objects. In some instances, the grasp predictions may be computed using object assets obtained from the simulated environment. These grasp predictions may be used in conjunction with motion generation algorithms (e.g., NVIDIA cuMotion) to enable the machines to execute precise grasping and manipulation operations.

In some examples, the system(s) may determine whether obstacles are present along a planned path of a machine. For instance, sensor data may be obtained from the sensors (e.g., cameras, LiDAR, etc.) disposed within the environment and/or onboard the machines. The system(s) may analyze the sensor data to detect obstacles and, in response, modify the planned path of the machine(s) to avoid collisions. In some instances, the system(s) may generate alternative paths that deviate from the original planned path to ensure safe navigation through the environment. The modified paths may be determined based on real-time updates to the simulated environment, in some instances.

In various examples, the system(s) may use a combination of global and local navigation planning to optimize movement of the machines through the environment. For example, the system(s) may use a global navigation planner to determine high-level routes for machines based on an overall layout of the environment, while using a local navigation system (e.g., NVIDIA Isaac Perceptor) onboard the machines to adjust the movement of the machines in response to dynamic obstacles and real-time environmental changes. This approach may allow for adaptive navigation in complex and dynamic retail spaces where unexpected obstacles, such as customers or temporary obstructions, may frequently appear.

As described herein, in various instances, the machines used by the system(s) may include a fleet of autonomous robots equipped with manipulator arms and various sensors for perception and navigation. These machines may communicate with the simulated environment and the planner to receive mission instructions and execution plans. The machines may also process local sensor data to make autonomous decisions in real time. For instance, the machines may use object detection models (e.g., SyntheticaDETR) to identify items in the environment, compute 3D object poses, and/or determine appropriate grasping actions for item retrieval and transport.

In various examples, the system(s) may continuously learn and improve based on feedback obtained from real-world operations. In some examples, reinforcement learning techniques may be used to optimize navigation strategies, grasping techniques, and task execution over time. Additionally, the system(s) may analyze historical data to identify patterns and trends that may inform future decision-making. For instance, machine learning models may be used to predict inventory shortages and recommend proactive restocking actions to be performed by the autonomous machines based on past sales and demand patterns. Additionally, in some examples, the system(s) may support a range of operations beyond item retrieval and transport. For instance, the machines may be configured to rearrange items within the environment, perform inventory audits, and provide real-time analytics on inventory levels. The integration of AI-driven perception, navigation, and manipulation capabilities may enable the system(s) to support highly autonomous retail operations, reducing reliance on manual labor and improving operational efficiency.

The systems and methods described herein may be used for a variety of purposes, by way of example and without limitation, for machine (e.g., robot, vehicle, construction machinery, warehouse vehicles/machines, autonomous, semi-autonomous, and/or other machine types) control, machine locomotion, machine driving, synthetic data generation, model training (e.g., using real, augmented, and/or synthetic data, such as synthetic data generated using a simulation platform or system, synthetic data generation techniques such as but not limited to those described herein, etc.), perception, augmented reality (AR), virtual reality (VR), mixed reality (MR), robotics, security and surveillance (e.g., in a smart cities implementation), autonomous or semi-autonomous machine applications, deep learning, environment simulation, object or actor simulation and/or digital twinning, data center processing, conversational AI, light transport simulation (e.g., ray-tracing, path tracing, etc.), distributed or collaborative content creation for 3D assets (e.g., using universal scene descriptor (USD) data, such as OpenUSD, and/or other data types), cloud computing, generative artificial intelligence (e.g., using one or more diffusion models, transformer models, etc.), and/or any other suitable applications.

Disclosed embodiments may be comprised in a variety of different systems such as automotive systems (e.g., a control system for an autonomous or semi-autonomous machine, a perception system for an autonomous or semi-autonomous machine), systems implemented using a robot or robotic platform, aerial systems, medial systems, boating systems, smart area monitoring systems, systems for performing deep learning operations, systems for performing simulation operations (e.g., in a driving or vehicle simulation, in a robotics simulation, in a smart cities or surveillance simulation, etc.), systems for performing digital twin operations (e.g., in conjunction with a collaborative content creation platform or system, such as, without limitation, NVIDIA's OMNIVERSE and/or another platform, system, or service that uses USD or OpenUSD data types), systems implemented using an edge device, systems incorporating one or more virtual machines (VMs), systems for performing synthetic data generation operations (e.g., using one or more neural rendering fields (NERFs), gaussian splat techniques, diffusion models, transformer models, etc.), systems implemented at least partially in a data center, systems for performing conversational AI operations, systems implementing one or more language models—such as one or more large language models (LLMs), one or more small language models (SLMs), one or more vision language models (VLMs), one or more multi-modal language models, etc., systems for performing light transport simulation, systems for performing collaborative content creation for 3D assets (e.g., using universal scene descriptor (USD) data, such as OpenUSD, computer aided design (CAD) data, 2D and/or 3D graphics or design data, and/or other data types), systems implemented at least partially using cloud computing resources, and/or other types of systems.

Additionally, although many of the examples herein are described with respect to using language models, and specifically large language models (LLMs), this is not intended to be limiting. For example, and without limitation, any of the various language models and/or AI models described herein may include any type of machine learning model, such as a machine learning model(s) using linear regression, logistic regression, decision trees, support vector machines (SVM), Naïve Bayes, k-nearest neighbor (KNN), K means clustering, random forest, dimensionality reduction algorithms, gradient boosting algorithms, neural networks (e.g., auto-encoder neural networks, artificial neural networks (ANNs), convolutional neural networks (CNNs), recurrent neural networks (RNNs), perceptrons, Long/Short Term Memory (LSTM) networks, multi-layer perceptron (MLP) networks, deep stacking networks (DSNs), generative pre-trained (GPT) models or networks, feed forward networks, radial basis function ANNs, self-organizing maps (SOMs), Kohonen maps, Hopfield networks, Boltzmann machine, deep belief neural networks, deconvolutional neural networks, generative adversarial networks (GANs), liquid state machines, modular neural networks, liquid state machines, sequence-to-sequence models, networks using transformer architectures, diffusion models (e.g., diffusion probabilistic models, score-based generative models, etc.), neural radiance field (NeRF) models, Gaussian Splat models, models with encoder-only architectures, models with decoder-only architectures, models with encoder-decoder architectures, generative machine learning models, large language models (LLMs), small language models (SLMs), vision language models (VLMs), multi-modal language models (MMLMs), and/or other types of machine learning models.

In some examples, the AI models (e.g., LLMs) and/or other machine learning models described herein may be packaged as a microservice—such as an inference microservice (e.g., NVIDIA NIMs)—which may include a container (e.g., an operating system (OS)-level virtualization package) that may include an application programming interface (API) layer, a server layer, a runtime layer, and/or a model “engine.” For example, the inference microservice may include the container itself and the model(s) (e.g., weights and biases). In some instances, such as where the model(s) is small enough (e.g., has a small enough number of parameters), the model(s) may be included within the container itself. In other examples—such as where the model(s) is large—the model(s) may be hosted/stored in the cloud (e.g., in a data center) and/or may be hosted on-premises and/or at the edge (e.g., on a local server or computing device, but outside of the container). In such embodiments, the model(s) may be accessible via one or more APIs—such as REST APIs. As such, and in some embodiments, the model(s) described herein may be deployed as an inference microservice to accelerate deployment of a model(s) on any cloud, data center, or edge computing system, while ensuring the data is secure. For example, the inference microservice may include one or more APIs, a pre-configured container for simplified deployment, an optimized inference engine (e.g., built using a standardized AI model deployment an execution software, such as NVIDIA's Triton Inference Server, and/or one or more APIs for high performance deep learning inference, which may include an inference runtime and model optimizations that deliver low latency and high throughput for production applications—such as NVIDIA's TensorRT), and/or enterprise management data for telemetry (e.g., including identity, metrics, health checks, and/or monitoring).

The AI models described herein may be included as part of the microservice along with an accelerated infrastructure with the ability to deploy with a single command and/or orchestrate and auto-scale with a container orchestration system on accelerated infrastructure (e.g., on a single device up to data center scale). As such, the inference microservice may include the model(s) (e.g., that has been optimized for high performance inference), an inference runtime software to execute the model(s) and provide outputs/responses to inputs (e.g., user queries, prompts, etc.), and enterprise management software to provide health checks, identity, and/or other monitoring. In some embodiments, the inference microservice may include software to perform in-place replacement and/or updating to the model(s). When replacing or updating, the software that performs the replacement/updating may maintain user configurations of the inference runtime software and enterprise management software.

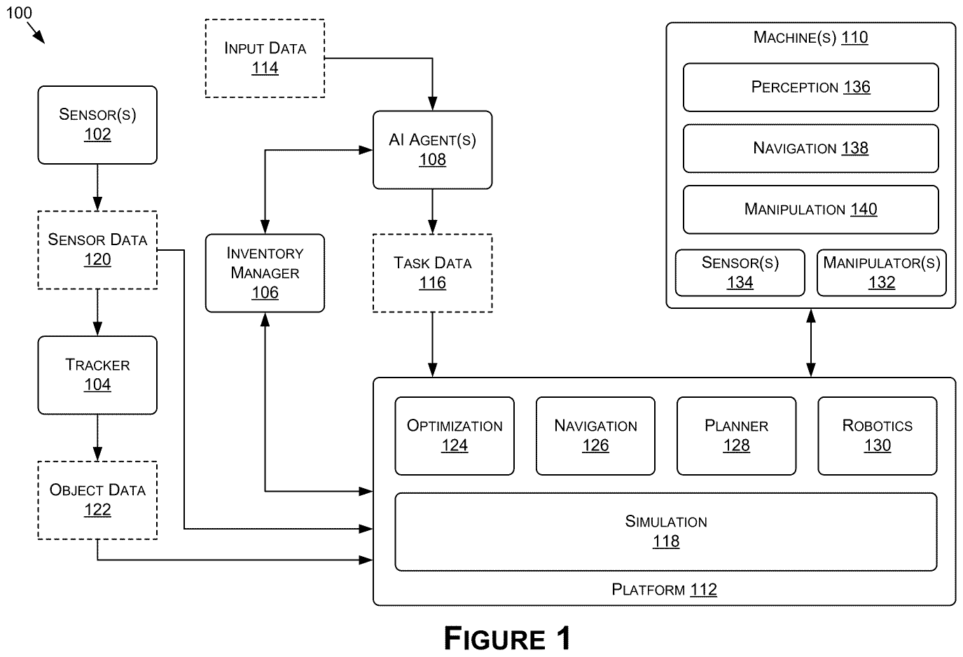

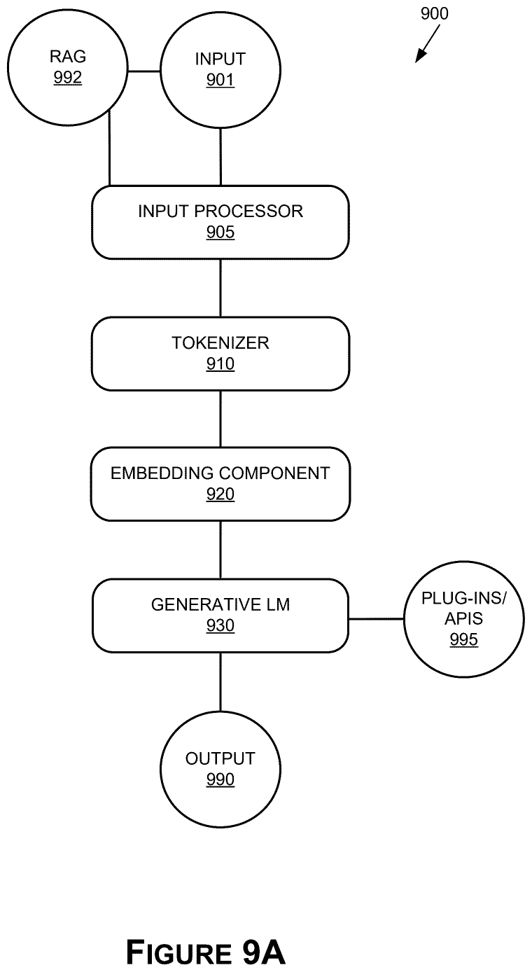

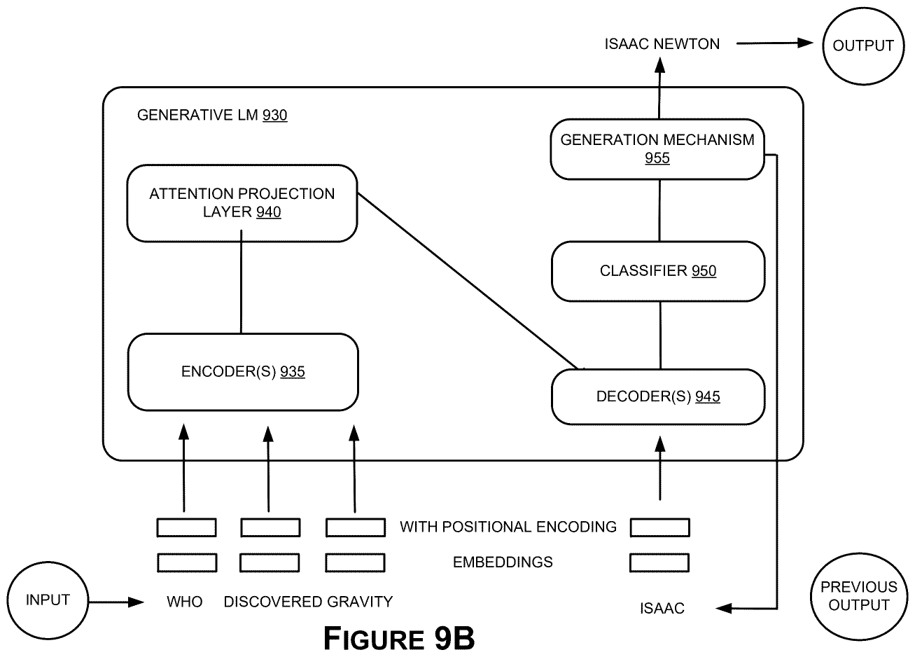

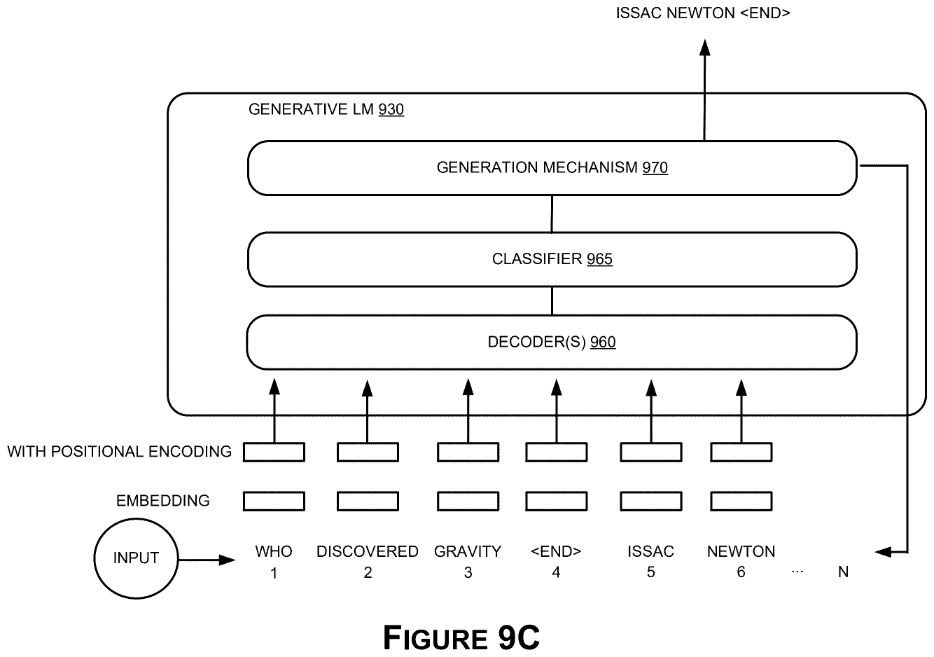

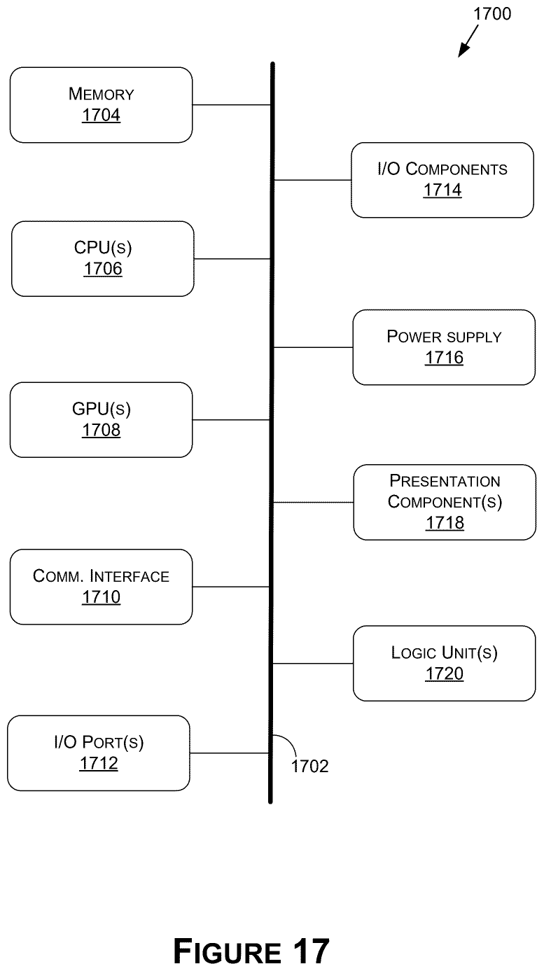

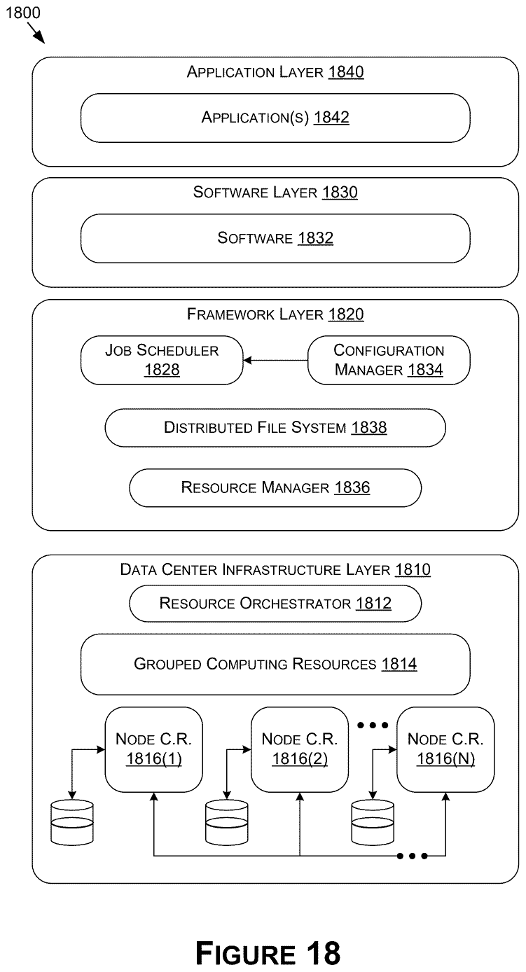

With reference to FIG. 1, FIG. 1 is a data flow diagram illustrating an example of a process 100 that may be performed by a system to autonomously manage an inventory of items in a dynamic environment, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out using one or more processor executing instructions stored in one or more memories. For example, in some embodiments, the systems and methods described herein may be implemented using one or more generative language models (e.g., as described in FIGS. 9A-9C), one or more computing devices or components thereof (e.g., as described in FIG. 17), and/or one or more data centers or components thereof (e.g., as described in FIG. 18).

The process 100 may be implemented using, amongst additional or alternative components, one or more sensors 102, a tracker component 104, an inventory manager 106, one or more AI agents 108, one or more machines 110 (e.g., robot(s)), and a platform 112. In some examples, one or more of these components may correspond to, be included in (e.g., a part of), or used by the system for autonomously managing the inventory of items in the dynamic environment. As a brief overview, the process 100 may include the AI agent(s) 108 processing input data 114 (e.g., which may represent requests related to purchasing items, moving or rearranging items, restocking items, etc.) to break down the input data 114 (or requests therein) into a plurality of tasks, which may be represented using the task data 116. The task data 116 may be provided to the platform 112 (e.g., a spatial computing platform, such as Nvidia's Omniverse), and the platform 112 may use various components to determine an execution plan for the tasks. For instance, the platform 112 may include a simulation component 118 that continuously generates and/or updates a simulated environment (e.g., digital twin) corresponding to the real environment based on sensor data 120 from the sensor(s) 102, object data 122 from the tracker 104, and/or item/inventory-related information from the inventory manager 106. Based at least on receiving the task data 116, the platform 112 may use the simulated version of the environment (and/or other data) to inform its other components (e.g., optimization component 124, navigation component 126, planer component 128, and robotics component 130) to make various decisions, such as determining an optimal machine(s) 110 (e.g., robot) for completing the tasks (e.g., each task), determining optimal paths for the machine(s) 110 to follow through the environment, determining grasp predictions for one or more manipulators 132 of the machine(s) 110, or any other kinds of decisions based on the digital twin simulation and/or other information. The platform 112 may send various control commands or instructions to the machine(s) 110 to cause the machine(s) 110 to perform a variety of operations associated with completing the tasks represented in the task data 116.

As described herein, in some examples, the input data 114 may be text data, audio data, image data, or any other type of data capable of representing a request (e.g., a user request). The AI agent(s) 108 may convert the input data 114 into a series of instructions or “tasks” that downstream components (e.g., the planner component 128) of the system may execute. In some instances, the AI agent(s) 108 may include a series of language models (e.g., LLMs, SLMs, MMLMs, VLMs, etc.) that may work together to decompose the input data 114 into smaller tasks with predefined logic. For instance, the AI agent(s) 108 may process a user request and break it down into step-by-step tasks that the downstream components of the system may execute. These tasks (e.g., task data 116) may be mapped to different operational components, such as the navigation component 126, planner component 128, robotics component 130, the inventory manager 106, or any other components described herein. In some examples, the AI agent(s) 108 may use information (e.g., inventory or item information) from the inventory manager 106 to break down the input data 114 and generate the task data 116. For instance, a task (e.g., each task) in the task data 116 may include data indicating, among other things, an identifier of the item, the location of the item, the stock of the item, or any other data obtained from the inventory manager 106.

In some examples, the platform 112 may correspond to, represent, or include a spatial computing platform, such as Nvidia's Omniverse. For instance, the platform 112 may include various APIs, SDKs, and/or services that may integrate OpenUSD, real-time ray tracing rendering technologies (e.g., Nvidia RTX), and/or generative physical AI into existing software tools and/or simulation workflows for industrial and/or machine automation use cases. As shown, the platform 112 may include the simulation component 118, the optimization component 124, the navigation component 126, the planner component 128, and the robotics component 130 (e.g., Nvidia's Isaac Manipulator).

In some instances, the simulation component 118 of the platform 112 may generate and/or continuously update the simulated version of the environment. The simulated environment may serve as a source of truth and, in some instances, a central control point for the system. In some examples, the generation of the simulated environment may be a one-time operation and then updated continuously in real-time as objects (e.g., people, machines, obstacles, etc.) appear and move within the environment. As described herein, the simulation component 118 may integrate data from multiple sources—such as multi-camera tracking technology (e.g., NVIDIA Metropolis MTMC), inventory tracking systems, sensor data from autonomous machines, etc.—to ensure accurate and up-to-date spatial representations of the environment.

In at least one example, the simulation component 118 may generate and/or update the simulated environment based on the sensor data 120 generated using the sensor(s) 102 disposed in the environment. For instance, the sensor(s) 102 may include multiple cameras that are positioned at various locations in the environment such that a birds-eye-view (e.g., top-down) of the environment may be captured. In some examples, the tracker component 104 may use multi-camera tracking (e.g., Nvidia's MTMC) and/or other techniques to process the sensor data 120 and generate the object data 122, which may represent object detections, classifications, object tracks, etc. within the environment. For example, the tracker component 104 may use multi-camera tracking to analyze video feeds from multiple angles to track the movement of objects and identify changes in item placements, among other things. The object data 122 may then be processed and synchronized with the simulated environment, ensuring that the simulated environment accurately reflects the current state of the physical space. In some instances, the tracker component 104 may apply or use AI-based object recognition models to classify detected objects, distinguishing between different types of items, autonomous machines, store personnel, or any other kinds of object classifications.

In some examples, the simulation component 118 may generate and/or update the simulated environment based on information obtained from the inventory manager 106. The inventory manager 106 may store (e.g., within a database(s)) information associated with one or more (e.g., each) items in the environment, such as item position(s), item status(es), item quantities, item descriptions, or any other information. In various examples, the simulation component 118 (and/or the platform 112) may synchronize updates to the inventory manager 106 with updates to the simulated environment to ensure consistency between virtual representations and real-world conditions. For example, the simulation component 118 may use the information from the inventory manager 106 to position and/or populate 3D models of items within the simulated environment. In this way, the 3D models of items may be searched and fetched. In some examples, the AI agent(s) 108 may update the item information stored by the inventory manager 106 in real time as changes occur, and the simulation component 118 may update the simulated environment in real-time based on these updates. For instance, the current status of an item may be updated by the AI agent(s) 108 as an item transitions from being placed on a shelf, to being in motion with a robot, to being purchased, and/or through any other scenarios, and the simulated environment may be updated to reflect the items position during these states.

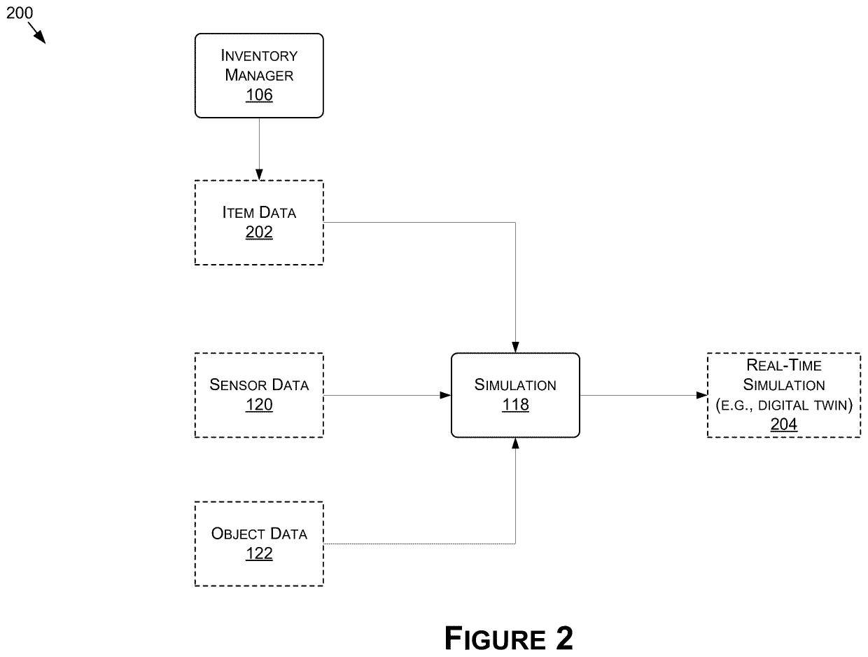

As an example, FIG. 2 is a data flow diagram illustrating an example of a process 200 for generating and/or updating a simulation of an environment (e.g., digital twin), in accordance with some embodiments of the present disclosure. As shown in FIG. 2, the simulation component 118 may receive item data 202 from the inventory manager 106, the sensor data 120, and the object data 122. The simulation component 118 may use one or more of these data sources (e.g., the item data 202, the sensor data 120, and/or the object data 122) to generate and update a real-time simulation 204 (e.g., a digital twin) of the environment. In some examples, the simulation component 118 may continuously receive these inputs (e.g., also referred to as receiving a “stream of data”). While this is just one example illustrating that the simulation component 118 may generate the real-time simulation 204 based on the item data 202, the sensor data 120, and/or the object data 122, in additional or alternative examples, the simulation component 118 may generate the real-time simulation 204 based on any type of data sources, as well as generate and update any number of simulations (e.g., one or more real-time simulations 204). For instance, the simulation component 118 may generate one or more separate simulations/digital twins for one or more rooms (e.g., each room) of an environment.

Referring back to the example of FIG. 1, the platform 112 may also include the optimization component 124, which may correspond to an optimization AI microservice, such as Nvidia's cuOpt. The optimization component 124 may, in some instances, be configured to determine optimal paths for the machine(s) 110 to follow between locations within the environment (e.g., to ensure optimal task performance). For instance, the optimization component 124 may generate waypoint graphs that include nodes corresponding to relevant locations, such as item pickup locations, current machine locations, item drop off locations, or any other relevant locations in the environment. The optimization component 124 may determine the optimal paths for the machine(s) 110 based at least on computing distances between nodes in the waypoint graphs. In some instances, the optimization component 124 may use optimization algorithms (e.g., shortest path algorithms) to determine the most efficient paths for the machines to follow. These paths may be dynamically adjusted based on changes in the environment, such as newly detected obstacles and/or updated item locations.

Additionally, in some instances, the optimization component 124 may determine optimal machines to deploy for various tasks. For instance, the optimization component 124 may assess a number of factors or constraints such as machine availability, proximity to the task location, current task assignments, and battery levels to select the most suitable machine(s) for the tasks (e.g., each task). The selection process may also consider machine capabilities, such as whether a particular machine/robot is equipped with a manipulator arm for grasping objects or whether it is better suited for transportation tasks.

In some examples, the navigation component 126 may process data from the optimization component 124 and/or real-time positions of the machine(s) 110 in the simulated environment to determine the most efficient way to complete a task. The navigation component 126 may continuously recalculate the optimal routes and/or actions based on real-time updates in the retail environment—such as new obstacles in pathways or changes in inventory locations—ensuring seamless and adaptive task execution. In at least one example, the navigation component 126 may dynamically allocate tasks among multiple machine(s) 110 to improve efficiency and balance workload distribution. In such instances, if a machine(s) 110 encounters an obstacle or unexpected delay, the navigation component 126 may reassign the task to another available machine(s) 110 that may be able to complete the task more efficiently. In some examples, the navigation component 126 may correspond to the “global navigation planner” described herein

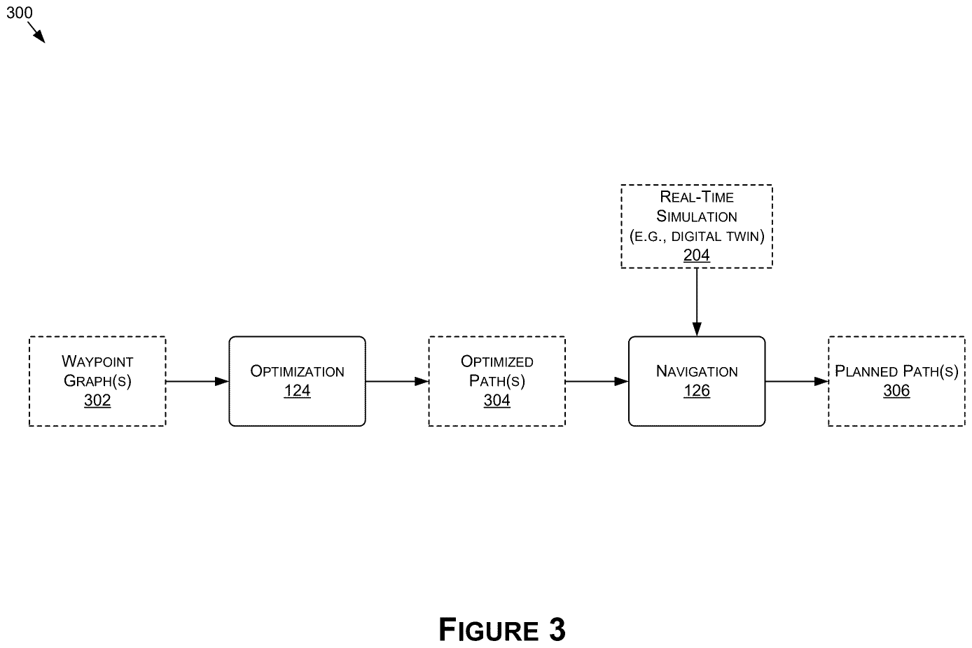

As an example, FIG. 3 is a data flow diagram illustrating an example of a process 300 for determining optimized paths for navigating from a first location to a second location in a dynamic environment, in accordance with some embodiments of the present disclosure. As shown, the optimization component 124 may receive one or more waypoint graphs 302 and use the waypoint graph(s) 302 to determine one or more optimized paths 304. The navigation component 126 may use the optimized path(s) 304 and the real-time simulation 204 (e.g., machine locations in the simulation) to determine one or more planned paths 306 for the machine(s) to follow. Although depicted in FIG. 3 as receiving the waypoint graph(s) 302, in some examples, the optimization component 124 may generate the waypoint graph(s) 302 (e.g., based on the simulated environment, based on the tasks, based on the inventory information, or based on any other sources of data).

Referring back to the example of FIG. 1, in some instances, the robotics component 130 may be configured to facilitate (e.g., using perception models, etc.) the ability of the machine(s) 110 to grasp and manipulate different objects in the environment. For instance, the robotics component 130 may generate or retrieve simulated 3D models corresponding to the items in the environment and use AI-based grasp prediction models (e.g., NVIDIA Isaac Manipulator Foundation Grasp) to generate dense grasp predictions for objects. In some instances, the grasp predictions may be computed using object assets obtained from the simulated environment. These grasp predictions may, in some instances, be used in conjunction with motion generation algorithms (e.g., NVIDIA cuMotion) to enable the machine(s) 110 to execute precise grasping and manipulation operations.

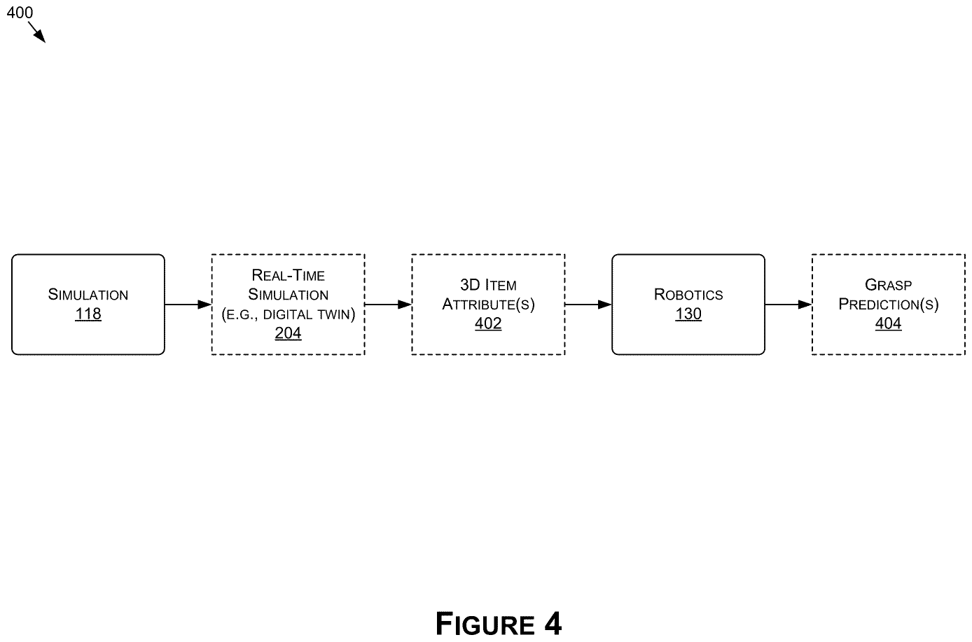

For instance, FIG. 4 is a data flow diagram illustrating an example of a process 400 for generating grasp predictions for robotic manipulators to grasp items, in accordance with some embodiments of the present disclosure. As shown, the simulation component 118 may generate and continuously update the real-time simulation 204 of the environment, and the robotics component 130 may obtain one or more 3D item attributes 402 from the simulation. In some instances, the 3D item attribute(s) 402 may include, but are not limited to, sizes or dimensions of items, shapes of items, locations of items, weights of items, compositions of items, 3D models of the items, or any other item-related attributes or information. Using the 3D item attribute(s) 402, the robotics component 130 may determine one or more grasp predictions 404 for the machine(s) to grasp or otherwise manipulate the item(s).

Referring back to the example of FIG. 1, the planner component 128, in some instances, may be configured to interpret task instructions (e.g., task data 116) generated by the AI agent(s) 108 and convert the tasks into executable action plans for the machine(s) 110 operating in the environment. The planner component 128 may integrate data from multiple sources, including the navigation component 126, the inventory manager 106, and real-time sensor data from the sensor(s) 102 and/or one or more sensors 134 of the machine(s) 110, to determine the most efficient execution strategy for the tasks. In some examples, the planner component 128 may also be able to use optimization algorithms to allocate tasks among the machine(s) 110, as well as continuously monitor task execution progress and dynamically adjust plans based on real-time environmental changes.

Additionally, the planner component 128 may interface with the simulated environment to simulate task execution strategies before deployment. By leveraging the simulated environment, the planner component 128 may predict potential bottlenecks, refine navigation routes, and optimize task distribution, improving the overall efficiency of the system. The planner component 128 may further communicate with the machine(s) 110 to provide step-by-step guidance on executing tasks, including precise navigation paths and object manipulation instructions generated by the robotics component 130 using AI-driven grasp predictions.

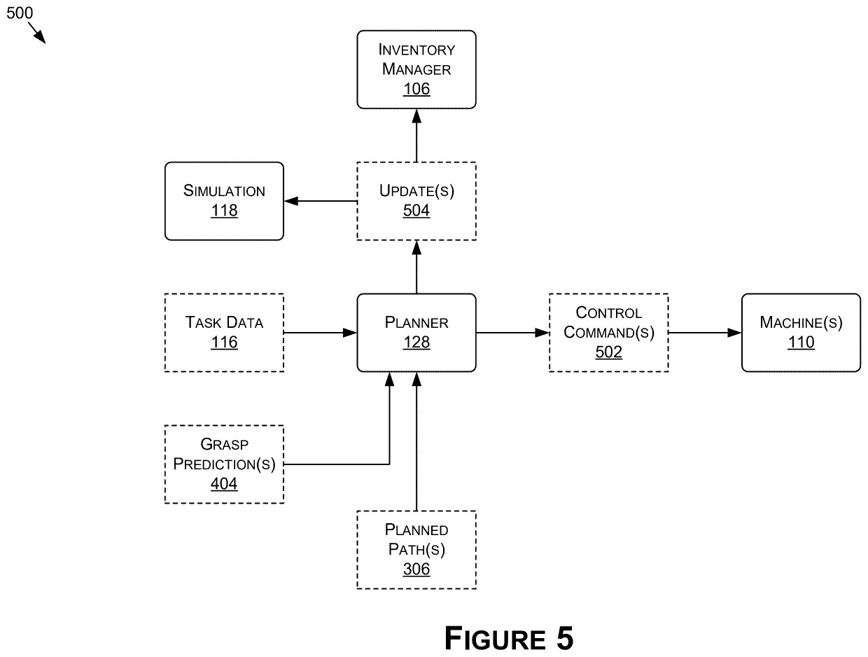

For instance, FIG. 5 is a data flow diagram illustrating an example of a process for determining control commands for controlling one or more machines, in accordance with some embodiments of the present disclosure. As shown, the planner component 128 may receive the task data 116, the planned path(s) 306, and the grasp prediction(s) 404 and use some or all of this information to determine one or more control commands 502 to send to the machine(s) 110. The control command(s) 502 may cause the machine(s) 110 to perform one or more operations associated with completing the tasks. For instance, the control command(s) 502 may include inputs to cause the machine(s) 110 to traverse the planned path(s) 306, to grasp objects using the manipulators, or any other control operations. Additionally, or alternatively, the control command(s) 502 may include the execution plans and the machine(s) 110 may include logic and functionalities to perform the tasks based on the information in the execution plans. In other words, instead of the planner 128 directly driving one or more actuators or motors of the machine(s) 110, the planner 128 may instruct the machine(s) 110 on the tasks they are to perform and/or how to perform them, and the machine(s) 110 may independently determine the operations to perform in order to complete the tasks according to the planner component's 128 instructions.

In some examples, the planner component 128 may send one or more updates 504 to the inventory manager 106 and/or the simulation component 118. The update(s) 504 may cause the inventory manager 106 to update item or inventory information stored therein, such as updating the status (e.g., tracking information) of an item, changes in item inventory, etc., Additionally, the update(s) 504 may cause the simulation component 118 to update the simulated environment. For instance, the simulated environment may be updated based on inventory changes (e.g., to adjust the number of items at a location in the digital twin).

Referring back to the example of FIG. 1, in some examples, the machine(s) 110 may include a fleet of autonomous robots equipped with the manipulator(s) 132 (e.g., manipulator arms) and the sensor(s) 134 (e.g., cameras, LiDAR, RADAR, ultrasonic, etc.) for perception and navigation. The machine(s) 110 may communicate with the platform 112 (and/or one or more components or data sources therein, such as the simulation component 118 or the planner component 128) to receive mission instructions and execution plans. The machine(s) 110 may also process local sensor data from the sensor(s) 134 to make autonomous decisions in real time. For instance, a perception component 136 of the machine(s) 110 may use object detection models (e.g., SyntheticaDETR) to identify items in the environment, while the manipulation component 140 may determine appropriate grasping actions for item retrieval and transport.

As shown, in some instances the machine(s) 110 may include the perception component 136 (e.g., Nvidia's Isaac Perceptor, etc.), a navigation component 138, and a manipulation component 140 (e.g., Nvidia's Isaac Manipulator, etc.). The perception component 136 may enable the machine(s) 110 to determine whether obstacles are present along a planned path of the machine(s) 110. For instance, the perception component 136 may obtain sensor data from the sensor(s) 134 of the machine(s) 110. The perception component 136 may analyze the sensor data to detect obstacles and, in response, the navigation component 138 may modify the planned path of the machine(s) 110 to avoid collisions. In some instances, the navigation component 138 may use information from the perception component 136 to generate alternative paths that deviate from the original planned path to ensure safe navigation through the environment.

In various examples, the machine(s) 110 may use a combination of global and local navigation planning to optimize movement through the environment. For example, the navigation component 126 of the platform 112 may serve as a global navigation planner to determine high-level routes for the machine(s) 110 based on an overall layout of the environment, while the navigation component 138 may serve as a local navigation system onboard the machine(s) 110 to adjust the movement of the machine(s) 110 in response to dynamic obstacles and real-time environmental changes. This approach may allow for adaptive navigation in complex and dynamic retail spaces where unexpected obstacles, such as customers or temporary obstructions, may frequently appear.

In some instances, the system (e.g., the tracker component 104, the inventory manager 106, the AI agent(s) 108, the machine(s) 110, and/or the platform 112) may continuously learn and improve based on feedback obtained from real-world operations. In some examples, reinforcement learning techniques may be used to optimize navigation strategies, grasping techniques, and task execution over time. Additionally, the system may analyze historical data to identify patterns and trends that may inform future decision-making. For instance, the AI agent(s) 108 may predict inventory shortages and recommend proactive restocking actions to be performed by the autonomous machine(s) 110 based on past sales and demand patterns. Additionally, in some examples, the system may support a range of operations beyond item retrieval and transport. For instance, the machine(s) 110 may be configured to rearrange items within the environment, perform inventory audits, and provide real-time analytics on inventory levels. The integration of AI-driven perception, navigation, and manipulation capabilities may enable the system to support highly autonomous retail operations, reducing reliance on manual labor and improving operational efficiency.

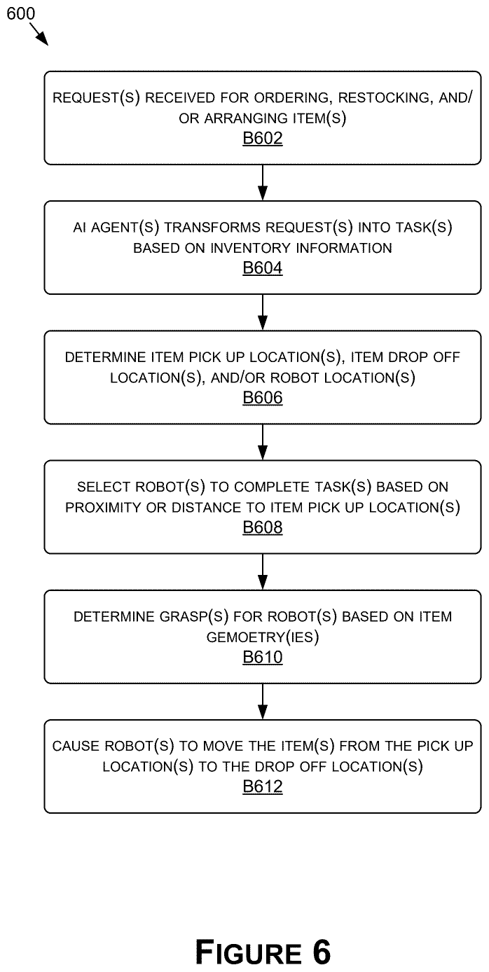

Now referring to FIGS. 6-8, each block of methods 600, 700, and 800, described herein, comprises a computing process that may be performed using any combination of hardware, firmware, and/or software. For instance, various functions may be carried out using one or more processors executing instructions stored in one or more memories. The methods may also be embodied as computer-usable instructions stored on computer storage media. The methods may be provided by a standalone application, a service or hosted service (standalone or in combination with another hosted service), as a microservice via an application programming interface (API) or a plug-in to another product, to name a few. In addition, methods 600, 700, and 800 are described, by way of example, with respect to the system of FIG. 1. However, one or more of these methods may additionally or alternatively be executed by any one system, or any combination of systems, including, but not limited to, those described herein.

FIG. 6 is a flow diagram illustrating an example of a method 600, which may be performed using the systems described herein, for autonomously moving items in a dynamic environment responsive to various user requests, in accordance with some embodiments of the present disclosure. The method 600, at block B602, includes receiving one or more requests for ordering, restocking, and/or arranging one or more items. For instance, the input data 114 representing the request(s) may be received (e.g., from one or more client devices).

The method 600, at block B604, includes using one or more AI agents to transform the request(s) into one or more tasks based on inventory information. For instance, the AI agent(s) 108 may process the input data 114 and information from the inventory manager 106 to generate the task data 116 representing the task(s). In some examples, one or more different agents may be used to determine tasks corresponding to one or more different portions of the input data.

The method 600, at block B606, includes determining one or more item pick up locations, one or more item drop off locations, and/or one or more robot locations. For instance, the optimization component 124 may determine the item pick up location(s), item drop off location(s) and/or the robot location(s) (e.g., machine location(s)) based on one or more of the simulated environment, the inventory information (from the inventory manager 106), the task data 116 (e.g., indicating preferred drop off location(s)), etc.

The method 600, at block B608, includes selecting one or more robots to complete the task(s) based on proximity or distance of the robot(s) to the item pick up location(s). For example, the navigation component 126 may select the robot(s) (e.g., machine(s) 110) to complete the task(s) based on their proximity or distance to the item pick up location(s). In some examples, the navigation component 126 may use the simulated environment and/or other data sources (e.g., optimized paths from the optimization component 124) to select the optimal robot(s) (e.g., machine(s) 110) to complete the task(s).

The method 600, at block B610, includes determining one or more grasps for the robot(s) based on one or more geometries of the item(s). For instance, the robotics component 130 may determine the grasp(s) for the robot(s) (e.g., machine(s) 110) based on one or more 3D models of the item(s). The 3D model(s) may be obtained, in some instances, from the simulated environment and/or the inventory manager 106.

The method 600, at block B612, includes causing the robot(s) to move the item(s) from the pick up location(s) to the drop of location(s). For instance, the planner component 128 may cause the robot(s) (e.g., machine(s) 110) to move the item(s) from the pick up location(s) to the drop off location(s) by sending one or more control inputs or instructions/tasks to the robot(s).

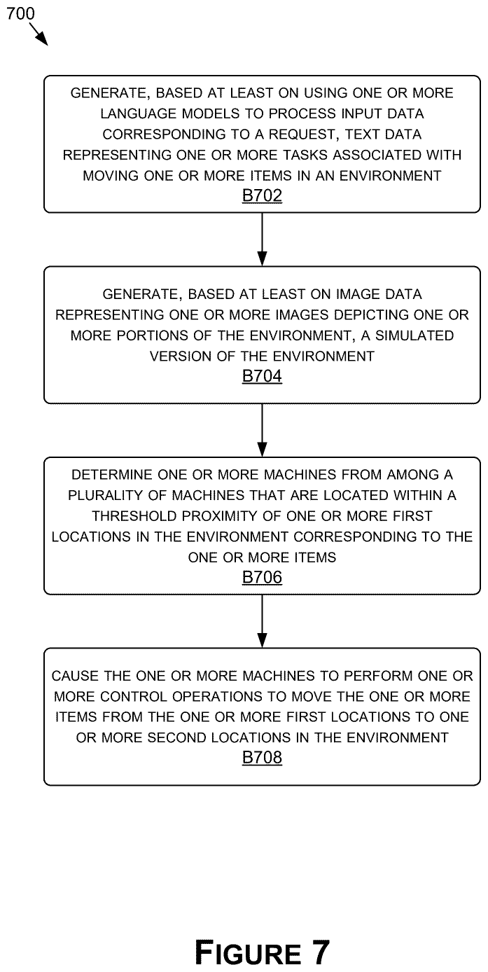

FIG. 7 is a flow diagram illustrating an example of a method 700 for automated inventory management, in accordance with some embodiments of the present disclosure. The method 700, at block B702, includes generating, based at least on using one or more language models to process input data corresponding to a request, text data representing one or more tasks associated with moving one or more items in an environment. For instance, the AI agent(s) 108 may generate the text data representing the tasks (e.g., task data 116) associated with moving the item(s) in the environment. In some instances, the AI agent(s) 108 may use the language model(s) (e.g., one or more LLMs, SLMs, VLMs, and/or MMLMs) to process the input data 114 corresponding to the request.

The method 700, at block B704, includes generating, based at least on image data representing one or more images depicting one or more portions of the environment, a simulated version of the environment. For instance, the simulation component 118 of the platform 112 may generate the simulated version of the environment based at least on the sensor data 120, the object data 122, and/or item/inventory data from the inventory manager 106. In some examples, the sensor data 120 may include image data representing the image(s) depicting the portion(s) of the environment from a bird's eye perspective (e.g., top-down).

The method 700, at block B706, includes determining one or more machines from among a plurality of machines that are located within a threshold proximity of one or more first locations in the environment corresponding to the one or more items. For instance, the optimization component 124 and/or the navigation component 126 may determine the machine(s) 110 that are located within the threshold proximity of the first location(s) corresponding to the item(s). In some examples, the threshold proximity may be based on a shortest path between the machine(s) and the item(s) (e.g., the machine that has the shortest path to the item may be selected). For instance, consider a scenario in which an item is positioned in a first aisle, a first machine is positioned in the first aisle 60 feet away from the first item, and a second machine is positioned in a second aisle 10 feet away from the first item. In such a scenario, while the second machine may be closest to the item, the second machine would have to follow a path from the second aisle to the first aisle (which may be a distance greater than 60 feet). However, the first machine would be able to take a direct path to the item down the first aisle, so the system(s) may select the first machine to complete the task (e.g., pick up the item) even though the direct line of sight distance between the second machine and the item is shorter.

The method 700, at block B708, includes causing the one or more machines to perform one or more control operations to move the one or more items from the one or more first locations to one or more second locations in the environment. For instance, the planner component 128 may cause the machine(s) 110 to perform the control operation(s) to move the item(s) from the first location(s) to the second location(s) in the environment. Additionally, in some instances, the local components of the machine(s) 110, such as the perception component 136, the navigation component 138, and/or the manipulation component 140 may also cause the machine(s) to perform the control operation(s). That is, the machine(s) 110 may perform the control operation(s) based on various inputs from a plurality of sources (e.g., the platform 112 and/or the local systems or components of the machine(s) itself).

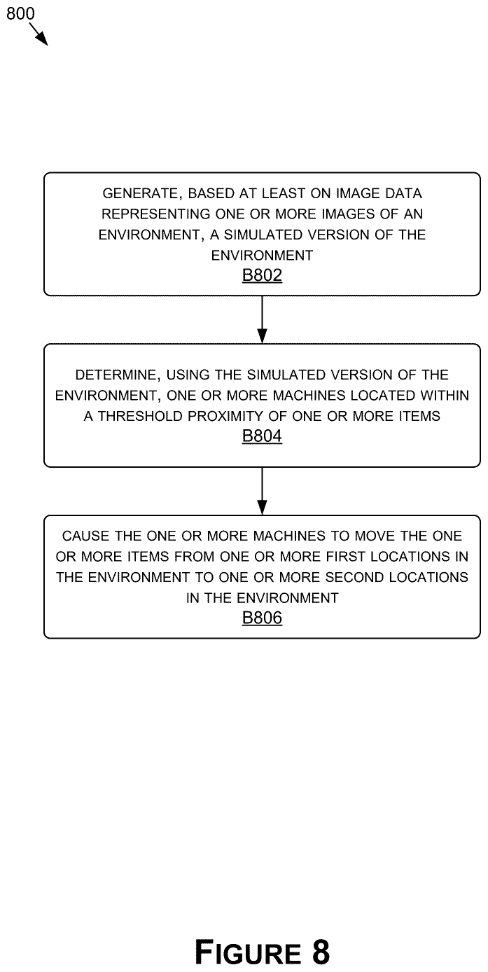

FIG. 8 is a flow diagram illustrating an example of a method 800 for using a simulated version of an environment to determine optimal autonomous machines and operations for performing various tasks, in accordance with some embodiments of the present disclosure. The method 800, at block B802, includes generating, based at least on image data representing one or more images of an environment, a simulated version of the environment. For instance, the simulation component 118 of the platform 112 may generate the simulated version of the environment based at least on the sensor data 120, the object data 122, and/or item/inventory data from the inventory manager 106. In some examples, the sensor data 120 may include image data representing the image(s) depicting the portion(s) of the environment from a bird's eye perspective (e.g., top-down). In some instances, the system(s) may continuously update the simulated environment as dynamic changes take place in the environment. In various examples, one or more light transport simulation algorithms may be used to render the simulated environment.

The method 800, at block B804, includes determining, using the simulated version of the environment, one or more machines located within a threshold proximity of one or more items. For instance, the optimization component 124 and/or the navigation component 126 may determine the machine(s) 110 that are located within the threshold proximity of the item(s). In some examples, the threshold proximity may be based on a shortest path between the machine(s) and the item(s) (e.g., the machine that has the shortest path to the item may be selected, instead of a machine with the shortest 3D distance between the item).

The method 800, at block B806, includes causing the one or more machines to move the one or more items from one or more first locations in the environment to one or more second locations in the environment. For instance, the planner component 128 may cause the machine(s) 110 to move the item(s) from the first location(s) to the second location(s). Additionally, in some instances, the local components of the machine(s) 110, such as the perception component 136, the navigation component 138, and/or the manipulation component 140 may also cause the machine(s) to move the item(s). That is, the machine(s) 110 may perform various control operation(s) to move the item(s) based on various inputs from a plurality of sources (e.g., the platform 112 and/or the local systems or components of the machine(s) itself).

### Example Language Models

In at least some embodiments, language models, such as large language models (LLMs), small language models (SLMs), vision language models (VLMs), multi-modal language models (MMLMs), and/or other types of generative artificial intelligence (AI) may be implemented. These models may be capable of understanding, summarizing, translating, and/or otherwise generating text (e.g., natural language text, code, etc.), images, video, computer aided design (CAD) assets, OMNIVERSE and/or METAVERSE file information (e.g., in USD format, such as OpenUSD), and/or the like, based on the context provided in input prompts or queries. These language models may be considered “large,” in embodiments, based on the models being trained on massive datasets and having architectures with large number of learnable network parameters (weights and biases)—such as millions or billions of parameters. The LLMs/SLMs/VLMs/MMLMs/etc. may be implemented for summarizing textual data, analyzing and extracting insights from data (e.g., textual, image, video, etc.), and generating new text/image/video/etc. in user-specified styles, tones, and/or formats. The LLMs/SLMs/VLMs/MMLMs/etc. of the present disclosure may be used exclusively for text processing, in embodiments, whereas in other embodiments, multi-modal LLMs may be implemented to accept, understand, and/or generate text and/or other types of content like images, audio, 2D and/or 3D data (e.g., in USD formats), and/or video. For example, vision language models (VLMs), or more generally multi-modal language models (MMLMs), may be implemented to accept image, video, audio, textual, 3D design (e.g., CAD), and/or other inputs data types and/or to generate or output image, video, audio, textual, 3D design, and/or other output data types.

Various types of LLMs/SLMs/VLMs/MMLMs/etc. architectures may be implemented in various embodiments. For example, different architectures may be implemented that use different techniques for understanding and generating outputs—such as text, audio, video, image, 2D and/or 3D design or asset data, etc. In some embodiments, LLMs/SLMs/VLMs/MMLMs/etc. architectures such as recurrent neural networks (RNNs) or long short-term memory networks (LSTMs) may be used, while in other embodiments transformer architectures—such as those that rely on self-attention and/or cross-attention (e.g., between contextual data and textual data) mechanisms—may be used to understand and recognize relationships between words or tokens and/or contextual data (e.g., other text, video, image, design data, USD, etc.). One or more generative processing pipelines that include LLMs/SLMs/VLMs/MMLMs/etc. may also include one or more diffusion block(s) (e.g., denoisers). The LLMs/SLMs/VLMs/MMLMs/etc. of the present disclosure may include encoder and/or decoder block(s). For example, discriminative or encoder-only models like BERT (Bidirectional Encoder Representations from Transformers) may be implemented for tasks that involve language comprehension such as classification, sentiment analysis, question answering, and named entity recognition. As another example, generative or decoder-only models like GPT (Generative Pretrained Transformer) may be implemented for tasks that involve language and content generation such as text completion, story generation, and dialogue generation. LLM/SLMs/VLMs/MMLMs/etc. that include both encoder and decoder components like T5 (Text-to-Text Transformer) may be implemented to understand and generate content, such as for translation and summarization. These examples are not intended to be limiting, and any architecture type-including but not limited to those described herein—may be implemented depending on the particular embodiment and the task(s) being performed using the LLMs/SLMs/VLMs/MMLMs/etc.

In various embodiments, the LLMs/SLMs/VLMs/MMLMs/etc. may be trained using unsupervised learning, in which an LLMs/SLMs/VLMs/MMLMs/etc. learns patterns from large amounts of unlabeled text/audio/video/image/design/USD/etc. data. Due to the extensive training, in embodiments, the models may not require task-specific or domain-specific training. LLMs/SLMs/VLMs/MMLMs/etc. that have undergone extensive pre-training on vast amounts of unlabeled data may be referred to as foundation models and may be adept at a variety of tasks like question-answering, summarization, filling in missing information, translation, image/video/design/USD/data generation. Some LLMs/SLMs/VLMs/MMLMs/etc. may be tailored for a specific use case using techniques like prompt tuning, fine-tuning, retrieval augmented generation (RAG), adding adapters (e.g., customized neural networks, and/or neural network layers, that tune or adjust prompts or tokens to bias the language model toward a particular task or domain), and/or using other fine-tuning or tailoring techniques that optimize the models for use on particular tasks and/or within particular domains.

In some embodiments, the LLMs/SLMs/VLMs/MMLMs/etc. of the present disclosure may be implemented using various model alignment techniques. For example, in some embodiments, guardrails may be implemented to identify improper or undesired inputs (e.g., prompts) and/or outputs of the models. In doing so, the system may use the guardrails and/or other model alignment techniques to either prevent a particular undesired input from being processed using the LLMs/SLMs/VLMs/MMLMs/etc., and/or preventing the output or presentation (e.g., display, audio output, etc.) of information generating using the LLMs/SLMs/VLMs/MMLMs/etc. In some embodiments, one or more additional models—or layers thereof—may be implemented to identify issues with inputs and/or outputs of the models. For example, these “safeguard” models may be trained to identify inputs and/or outputs that are “safe” or otherwise okay or desired and/or that are “unsafe” or are otherwise undesired for the particular application/implementation. As a result, the LLMs/SLMs/VLMs/MMLMs/etc. of the present disclosure may be less likely to output language/text/audio/video/design data/USD data/etc. that may be offensive, vulgar, improper, unsafe, out of domain, and/or otherwise undesired for the particular application/implementation.

In some embodiments, the LLMs/SLMs/VLMs/MMLMs/etc. may be configured to or capable of accessing or using one or more plug-ins, application programming interfaces (APIs), databases, data stores, repositories, etc. For example, for certain tasks or operations that the model is not ideally suited for, the model may have instructions (e.g., as a result of training, and/or based on instructions in a given prompt) to access one or more plug-ins (e.g., 3^{rd} party plugins) for help in processing the current input. In such an example, where at least part of a prompt is related to restaurants or weather, the model may access one or more restaurant or weather plug-ins (e.g., via one or more APIs) to retrieve the relevant information. As another example, where at least part of a response requires a mathematical computation, the model may access one or more math plug-ins or APIs for help in solving the problem(s), and may then use the response from the plug-in and/or API in the output from the model. This process may be repeated—e.g., recursively—for any number of iterations and using any number of plug-ins and/or APIs until a response to the input prompt can be generated that addresses each ask/question/request/process/operation/etc. As such, the model(s) may not only rely on its own knowledge from training on a large dataset(s), but also on the expertise or optimized nature of one or more external resources—such as APIs, plug-ins, and/or the like.

In some embodiments, multiple language models (e.g., LLMs/SLMs/VLMs/MMLMs/etc., multiple instances of the same language model, and/or multiple prompts provided to the same language model or instance of the same language model may be implemented, executed, or accessed (e.g., using one or more plug-ins, user interfaces, APIs, databases, data stores, repositories, etc.) to provide output responsive to the same query, or responsive to separate portions of a query. In at least one embodiment, multiple language models e.g., language models with different architectures, language models trained on different (e.g. updated) corpuses of data may be provided with the same input query and prompt (e.g., set of constraints, conditioners, etc.). In one or more embodiments, the language models may be different versions of the same foundation model. In one or more embodiments, at least one language model may be instantiated as multiple agents—e.g., more than one prompt may be provided to constrain, direct, or otherwise influence a style, a content, or a character, etc., of the output provided. In one or more example, non-limiting embodiments, the same language model may be asked to provide output corresponding to a different role, perspective, character, or having a different base of knowledge, etc.—as defined by a supplied prompt.

In any one of such embodiments, the output of two or more (e.g., each) language models, two or more versions of at least one language model, two or more instanced agents of at least one language model, and/or two more prompts provided to at least one language model may be further processed, e.g., aggregated, compared or filtered against, or used to determine (and provide) a consensus response. In one or more embodiments, the output from one language model—or version, instance, or agent—maybe be provided as input to another language model for further processing and/or validation. In one or more embodiments, a language model may be asked to generate or otherwise obtain an output with respect to an input source material, with the output being associated with the input source material. Such an association may include, for example, the generation of a caption or portion of text that is embedded (e.g., as metadata) with an input source text or image. In one or more embodiments, an output of a language model may be used to determine the validity of an input source material for further processing, or inclusion in a dataset. For example, a language model may be used to assess the presence (or absence) of a target word in a portion of text or an object in an image, with the text or image being annotated to note such presence (or lack thereof). Alternatively, the determination from the language model may be used to determine whether the source material should be included in a curated dataset, for example and without limitation.

FIG. 9A is a block diagram of an example generative language model system 900 suitable for use in implementing at least some embodiments of the present disclosure. In the example illustrated in FIG. 9A, the generative language model system 900 includes a retrieval augmented generation (RAG) component 992, an input processor 905, a tokenizer 910, an embedding component 920, plug-ins/APIs 995, and a generative language model (LM) 930 (which may include an LLM, a SLM, a VLM, a multi-modal LM, etc.).

At a high level, the input processor 905 may receive an input 901 comprising text and/or other types of input data (e.g., audio data, video data, image data, sensor data (e.g., LiDAR, RADAR, ultrasonic, etc.), 3D design data, CAD data, universal scene descriptor (USD) data—such as OpenUSD, etc.), depending on the architecture of the generative LM 930 (e.g., LLM/SLM/VLM/MMLM/etc.). In some embodiments, the input 901 includes plain text in the form of one or more sentences, paragraphs, and/or documents. Additionally or alternatively, the input 901 may include numerical sequences, precomputed embeddings (e.g., word or sentence embeddings), and/or structured data (e.g., in tabular formats, JSON, or XML). In some implementations in which the generative LM 930 is capable of processing multi-modal inputs, the input 901 may combine text (or may omit text) with image data, audio data, video data, design data, USD data, and/or other types of input data, such as but not limited to those described herein. Taking raw input text as an example, the input processor 905 may prepare raw input text in various ways. For example, the input processor 905 may perform various types of text filtering to remove noise (e.g., special characters, punctuation, HTML tags, stopwords, portions of an image(s), portions of audio, etc.) from relevant textual content. In an example involving stopwords (common words that tend to carry little semantic meaning), the input processor 905 may remove stopwords to reduce noise and focus the generative LM 930 on more meaningful content. The input processor 905 may apply text normalization, for example, by converting all characters to lowercase, removing accents, and/or or handling special cases like contractions or abbreviations to ensure consistency. These are just a few examples, and other types of input processing may be applied.

In some embodiments, a RAG component 992 (which may include one or more RAG models, and/or may be performed using the generative LM 930 itself) may be used to retrieve additional information to be used as part of the input 901 or prompt. RAG may be used to enhance the input to the LLM/SLM/VLM/MMLM/etc. with external knowledge, so that answers to specific questions or queries or requests are more relevant—such as in a case where specific knowledge is required. The RAG component 992 may fetch this additional information (e.g., grounding information, such as grounding text/image/video/audio/USD/CAD/etc.) from one or more external sources, which can then be fed to the LLM/SLM/VLM/MMLM/etc. along with the prompt to improve accuracy of the responses or outputs of the model.

For example, in some embodiments, the input 901 may be generated using the query or input to the model (e.g., a question, a request, etc.) in addition to data retrieved using the RAG component 992. In some embodiments, the input processor 905 may analyze the input 901 and communicate with the RAG component 992 (or the RAG component 992 may be part of the input processor 905, in embodiments) in order to identify relevant text and/or other data to provide to the generative LM 930 as additional context or sources of information from which to identify the response, answer, or output 990, generally. For example, where the input indicates that the user is interested in a desired tire pressure for a particular make and model of vehicle, the RAG component 992 may retrieve—using a RAG model performing a vector search in an embedding space, for example—the tire pressure information or the text corresponding thereto from a digital (embedded) version of the user manual for that particular vehicle make and model. Similarly, where a user revisits a chatbot related to a particular product offering or service, the RAG component 992 may retrieve a prior stored conversation history—or at least a summary thereof—and include the prior conversation history along with the current ask/request as part of the input 901 to the generative LM 930.

The RAG component 992 may use various RAG techniques. For example, naïve RAG may be used where documents are indexed, chunked, and applied to an embedding model to generate embeddings corresponding to the chunks. A user query may also be applied to the embedding model and/or another embedding model of the RAG component 992 and the embeddings of the chunks along with the embeddings of the query may be compared to identify the most similar/related embeddings to the query, which may be supplied to the generative LM 930 to generate an output.

In some embodiments, more advanced RAG techniques may be used. For example, prior to passing chunks to the embedding model, the chunks may undergo pre-retrieval processes (e.g., routing, rewriting, metadata analysis, expansion, etc.). In addition, prior to generating the final embeddings, post-retrieval processes (e.g., re-ranking, prompt compression, etc.) may be performed on the outputs of the embedding model prior to final embeddings being used as comparison to an input query.

As a further example, modular RAG techniques may be used, such as those that are similar to naïve and/or advanced RAG, but also include features such as hybrid search, recursive retrieval and query engines, StepBack approaches, sub-queries, and hypothetical document embedding.

As another example, Graph RAG may use knowledge graphs as a source of context or factual information. Graph RAG may be implemented using a graph database as a source of contextual information sent to the LLM/SLM/VLM/MMLM/etc. Rather than (or in addition to) providing the model with chunks of data extracted from larger sized documents—which may result in a lack of context, factual correctness, language accuracy, etc.—graph RAG may also provide structured entity information to the LLM/SLM/VLM/MMLM/etc. by combining the structured entity textual description with its many properties and relationships, allowing for deeper insights by the model. When implementing graph RAG, the systems and methods described herein use a graph as a content store and extract relevant chunks of documents and ask the LLM/SLM/VLM/MMLM/etc. to answer using them. The knowledge graph, in such embodiments, may contain relevant textual content and metadata about the knowledge graph as well as be integrated with a vector database. In some embodiments, the graph RAG may use a graph as a subject matter expert, where descriptions of concepts and entities relevant to a query/prompt may be extracted and passed to the model as semantic context. These descriptions may include relationships between the concepts. In other examples, the graph may be used as a database, where part of a query/prompt may be mapped to a graph query, the graph query may be executed, and the LLM/SLM/VLM/MMLM/etc. may summarize the results. In such an example, the graph may store relevant factual information, and a query (natural language query) to graph query tool (NL-to-Graph-query tool) and entity linking may be used. In some embodiments, graph RAG (e.g., using a graph database) may be combined with standard (e.g., vector database) RAG, and/or other RAG types, to benefit from multiple approaches.

In any embodiments, the RAG component 992 may implement a plugin, API, user interface, and/or other functionality to perform RAG. For example, a graph RAG plug-in may be used by the LLM/SLM/VLM/MMLM/etc. to run queries against the knowledge graph to extract relevant information for feeding to the model, and a standard or vector RAG plug-in may be used to run queries against a vector database. For example, the graph database may interact with a plug-in's REST interface such that the graph database is decoupled from the vector database and/or the embeddings models.

The tokenizer 910 may segment the (e.g., processed) text data into smaller units (tokens) for subsequent analysis and processing. The tokens may represent individual words, subwords, characters, portions of audio/video/image/etc., depending on the implementation. Word-based tokenization divides the text into individual words, treating each word as a separate token. Subword tokenization breaks down words into smaller meaningful units (e.g., prefixes, suffixes, stems), enabling the generative LM 930 to understand morphological variations and handle out-of-vocabulary words more effectively. Character-based tokenization represents each character as a separate token, enabling the generative LM 930 to process text at a fine-grained level. The choice of tokenization strategy may depend on factors such as the language being processed, the task at hand, and/or characteristics of the training dataset. As such, the tokenizer 910 may convert the (e.g., processed) text into a structured format according to tokenization schema being implemented in the particular embodiment.

The embedding component 920 may use any known embedding technique to transform discrete tokens into (e.g., dense, continuous vector) representations of semantic meaning. For example, the embedding component 920 may use pre-trained word embeddings (e.g., Word2Vec, GloVe, or FastText), one-hot encoding, Term Frequency-Inverse Document Frequency (TF-IDF) encoding, one or more embedding layers of a neural network, and/or otherwise.

In some implementations in which the input 901 includes image data/video data/etc., the input processor 901 may resize the data to a standard size compatible with format of a corresponding input channel and/or may normalize pixel values to a common range (e.g., 0 to 1) to ensure a consistent representation, and the embedding component 920 may encode the image data using any known technique (e.g., using one or more convolutional neural networks (CNNs) to extract visual features). In some implementations in which the input 901 includes audio data, the input processor 901 may resample an audio file to a consistent sampling rate for uniform processing, and the embedding component 920 may use any known technique to extract and encode audio features—such as in the form of a spectrogram (e.g., a mel-spectrogram). In some implementations in which the input 901 includes video data, the input processor 901 may extract frames or apply resizing to extracted frames, and the embedding component 920 may extract features such as optical flow embeddings or video embeddings and/or may encode temporal information or sequences of frames. In some implementations in which the input 901 includes multi-modal data, the embedding component 920 may fuse representations of the different types of data (e.g., text, image, audio, USD, video, design, etc.) using techniques like early fusion (concatenation), late fusion (sequential processing), attention-based fusion (e.g., self-attention, cross-attention), etc.

The generative LM 930 and/or other components of the generative LM system 900 may use different types of neural network architectures depending on the implementation. For example, transformer-based architectures such as those used in models like GPT may be implemented, and may include self-attention mechanisms that weigh the importance of different words or tokens in the input sequence and/or feedforward networks that process the output of the self-attention layers, applying non-linear transformations to the input representations and extracting higher-level features. Some non-limiting example architectures include transformers (e.g., encoder-decoder, decoder only, multi-modal), RNNs, LSTMs, fusion models, diffusion models, cross-modal embedding models that learn joint embedding spaces, graph neural networks (GNNs), hybrid architectures combining different types of architectures adversarial networks like generative adversarial networks or GANs or adversarial autoencoders (AAEs) for joint distribution learning, and others. As such, depending on the implementation and architecture, the embedding component 920 may apply an encoded representation of the input 901 to the generative LM 930, and the generative LM 930 may process the encoded representation of the input 901 to generate an output 990, which may include responsive text and/or other types of data.

As described herein, in some embodiments, the generative LM 930 may be configured to access or use- or capable of accessing or using-plug-ins/APIs 995 (which may include one or more plug-ins, application programming interfaces (APIs), databases, data stores, repositories, etc.). For example, for certain tasks or operations that the generative LM 930 is not ideally suited for, the model may have instructions (e.g., as a result of training, and/or based on instructions in a given prompt, such as those retrieved using the RAG component 992) to access one or more plug-ins/APIs 995 (e.g., 3^{rd} party plugins) for help in processing the current input. In such an example, where at least part of a prompt is related to restaurants or weather, the model may access one or more restaurant or weather plug-ins (e.g., via one or more APIs), send at least a portion of the prompt related to the particular plug-in/API 995 to the plug-in/API 995, the plug-in/API 995 may process the information and return an answer to the generative LM 930, and the generative LM 930 may use the response to generate the output 990. This process may be repeated—e.g., recursively—for any number of iterations and using any number of plug-ins/APIs 995 until an output 990 that addresses each ask/question/request/process/operation/etc. from the input 901 can be generated. As such, the model(s) may not only rely on its own knowledge from training on a large dataset(s) and/or from data retrieved using the RAG component 992, but also on the expertise or optimized nature of one or more external resources—such as the plug-ins/APIs 995.

FIG. 9B is a block diagram of an example implementation in which the generative LM 930 includes a transformer encoder-decoder. For example, assume input text such as “Who discovered gravity” is tokenized (e.g., by the tokenizer 910 of FIG. 9A) into tokens such as words, and each token is encoded (e.g., by the embedding component 920 of FIG. 99A) into a corresponding embedding (e.g., of size 512). Since these token embeddings typically do not represent the position of the token in the input sequence, any known technique may be used to add a positional encoding to each token embedding to encode the sequential relationships and context of the tokens in the input sequence. As such, the (e.g., resulting) embeddings may be applied to one or more encoder(s) 935 of the generative LM 930.

In an example implementation, the encoder(s) 935 forms an encoder stack, where each encoder includes a self-attention layer and a feedforward network. In an example transformer architecture, each token (e.g., word) flows through a separate path. As such, each encoder may accept a sequence of vectors, passing each vector through the self-attention layer, then the feedforward network, and then upwards to the next encoder in the stack. Any known self-attention technique may be used. For example, to calculate a self-attention score for each token (word), a query vector, a key vector, and a value vector may be created for each token, a self-attention score may be calculated for pairs of tokens by taking the dot product of the query vector with the corresponding key vectors, normalizing the resulting scores, multiplying by corresponding value vectors, and summing weighted value vectors. The encoder may apply multi-headed attention in which the attention mechanism is applied multiple times in parallel with different learned weight matrices. Any number of encoders may be cascaded to generate a context vector encoding the input. An attention projection layer 940 may convert the context vector into attention vectors (keys and values) for the decoder(s) 945.

In an example implementation, the decoder(s) 945 form a decoder stack, where each decoder includes a self-attention layer, an encoder-decoder self-attention layer that uses the attention vectors (keys and values) from the encoder to focus on relevant parts of the input sequence, and a feedforward network. As with the encoder(s) 935, in an example transformer architecture, each token (e.g., word) flows through a separate path in the decoder(s) 945. During a first pass, the decoder(s) 945, a classifier 950, and a generation mechanism 955 may generate a first token, and the generation mechanism 955 may apply the generated token as an input during a second pass. The process may repeat in a loop, successively generating and adding tokens (e.g., words) to the output from the preceding pass and applying the token embeddings of the composite sequence with positional encodings as an input to the decoder(s) 945 during a subsequent pass, sequentially generating one token at a time (known as auto-regression) until predicting a symbol or token that represents the end of the response. Within each decoder, the self-attention layer is typically constrained to attend only to preceding positions in the output sequence by applying a masking technique (e.g., setting future positions to negative infinity) before the softmax operation. In an example implementation, the encoder-decoder attention layer operates similarly to the (e.g., multi-headed) self-attention in the encoder(s) 935, except that it creates its queries from the layer below it and takes the keys and values (e.g., matrix) from the output of the encoder(s) 935.

As such, the decoder(s) 945 may output some decoded (e.g., vector) representation of the input being applied during a particular pass. The classifier 950 may include a multi-class classifier comprising one or more neural network layers that project the decoded (e.g., vector) representation into a corresponding dimensionality (e.g., one dimension for each supported word or token in the output vocabulary) and a softmax operation that converts logits to probabilities. As such, the generation mechanism 955 may select or sample a word or token based on a corresponding predicted probability (e.g., select the word with the highest predicted probability) and append it to the output from a previous pass, generating each word or token sequentially. The generation mechanism 955 may repeat the process, triggering successive decoder inputs and corresponding predictions until selecting or sampling a symbol or token that represents the end of the response, at which point, the generation mechanism 955 may output the generated response.

FIG. 9C is a block diagram of an example implementation in which the generative LM 930 includes a decoder-only transformer architecture. For example, the decoder(s) 960 of FIG. 9C may operate similarly as the decoder(s) 945 of FIG. 9B except each of the decoder(s) 960 of FIG. 9C omits the encoder-decoder self-attention layer (since there is no encoder in this implementation). As such, the decoder(s) 960 may form a decoder stack, where each decoder includes a self-attention layer and a feedforward network. Furthermore, instead of encoding the input sequence, a symbol or token representing the end of the input sequence (or the beginning of the output sequence) may be appended to the input sequence, and the resulting sequence (e.g., corresponding embeddings with positional encodings) may be applied to the decoder(s) 960. As with the decoder(s) 945 of FIG. 9B, each token (e.g., word) may flow through a separate path in the decoder(s) 960, and the decoder(s) 960, a classifier 965, and a generation mechanism 970 may use auto-regression to sequentially generate one token at a time until predicting a symbol or token that represents the end of the response. The classifier 965 and the generation mechanism 970 may operate similarly as the classifier 950 and the generation mechanism 955 of FIG. 9B, with the generation mechanism 970 selecting or sampling each successive output token based on a corresponding predicted probability and appending it to the output from a previous pass, generating each token sequentially until selecting or sampling a symbol or token that represents the end of the response. These and other architectures described herein are meant simply as examples, and other suitable architectures may be implemented within the scope of the present disclosure.

### Example Parallel Processing Architecture

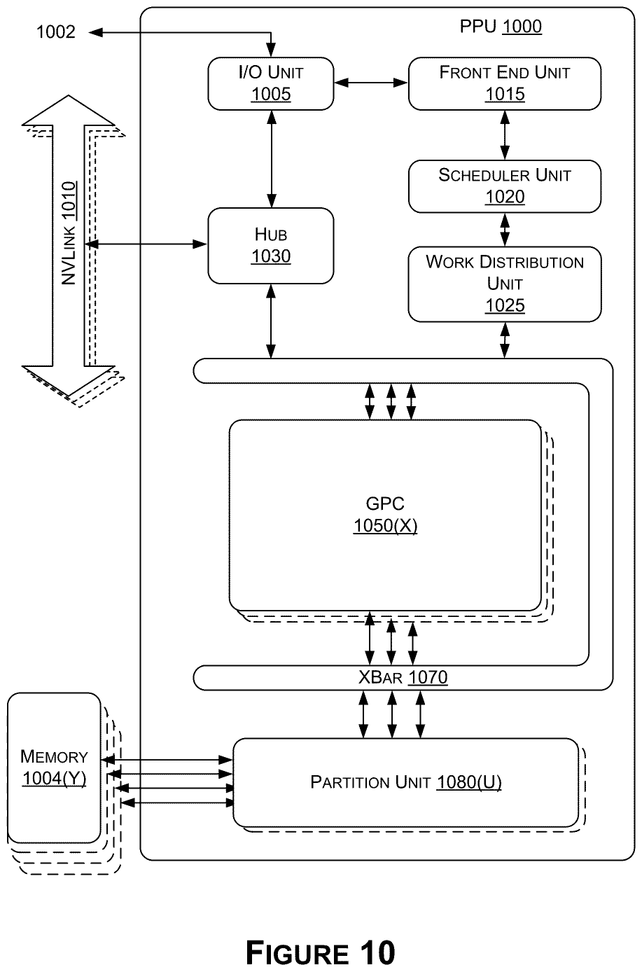

FIG. 10 illustrates an example parallel processing unit (PPU) 1000 suitable for use in implementing at least some embodiments of the present disclosure. In at least one embodiment, the PPU 1000 is a multi-threaded processor that is implemented on one or more integrated circuit devices. The PPU 1000 may have a latency hiding architecture designed to process many threads in parallel. A thread (e.g., a thread of execution) may refer to an instantiation of a set of instructions configured to be executed by the PPU 1000. In at least one embodiment, the PPU 1000 is a graphics processing unit (GPU) configured to implement a graphics rendering pipeline for processing three-dimensional (3D) graphics data in order to generate two-dimensional (2D) image data for display on a display device such as a liquid crystal display (LCD) device. In one or more embodiments, the PPU 1000 may be used for performing general-purpose computations. While one parallel processor is provided herein for illustrative purposes, it should be noted that such processor is set forth for illustrative purposes only, and that any processor may be employed to supplement and/or substitute for the same.

One or more PPUs 1000 may be configured to accelerate, by way of example and not limitation, thousands of High-Performance Computing (HPC), data center, and machine learning applications. The PPU 1000 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, light transport simulation, astronomy, molecular dynamics simulation, financial modeling, robotics, digital twinning, synthetic data generation, factory automation, real-time language translation, online search optimizations, personalized user recommendations, and the like.

As shown in FIG. 10, the PPU 1000 includes an Input/Output (I/O) unit 1005, a front end unit 1015, a scheduler unit 1020, a work distribution unit 1025, a hub 1030, a crossbar (Xbar) 1070, one or more general processing clusters (GPCs) 1050, and one or more partition units 1080. The PPU 1000 may be connected to a host processor or other PPUs 1000 via one or more high-speed NVLink 1010 interconnect. The PPU 1000 may be connected to a host processor or other peripheral devices via an interconnect 1002. The PPU 1000 may also be connected to a local memory comprising a number of memory devices 1004. In at least one embodiment, the local memory may comprise a number of dynamic random-access memory (DRAM) devices. The DRAM devices may be configured as a high-bandwidth memory (HBM) subsystem, with multiple DRAM dies stacked within each device.

The NVLink 1010 interconnect enables systems to scale and include one or more PPUs 1000 combined with one or more CPUs, supports cache coherence between the PPUs 1000 and CPUs, and CPU mastering. Data and/or commands may be transmitted by the NVLink 1010 through the hub 1030 to/from other units of the PPU 1000 such as one or more copy engines, a video encoder, a video decoder, a power management unit, etc. (not explicitly shown).

The I/O unit 1005 may be configured to transmit and receive communications (e.g., commands, data, etc.) from a host processor (not shown) over the interconnect 1002. The I/O unit 1005 may communicate with the host processor directly via the interconnect 1002 or through one or more intermediate devices such as a memory bridge. In at least one embodiment, the I/O unit 1005 may communicate with one or more other processors, such as one or more the PPUs 1000 via the interconnect 1002. In at least one embodiment, the I/O unit 1005 implements a Peripheral Component Interconnect Express (PCIe) interface for communications over a PCIe bus and the interconnect 1002 is a PCIe bus. In at least one embodiment, the I/O unit 1005 may implement other types of well-known interfaces for communicating with external devices.

The I/O unit 1005 decodes packets received via the interconnect 1002. In at least one embodiment, the packets represent commands configured to cause the PPU 1000 to perform various operations. The I/O unit 1005 transmits the decoded commands to various other units of the PPU 1000 as the commands may specify. For example, some commands may be transmitted to the front end unit 1015. Other commands may be transmitted to the hub 1030 or other units of the PPU 1000 such as one or more copy engines, a video encoder, a video decoder, a power management unit, etc. (not explicitly shown). In other words, the I/O unit 1005 may be configured to route communications between and among the various logical units of the PPU 1000.

In at least one embodiment, a program executed by the host processor encodes a command stream in a buffer that provides workloads to the PPU 1000 for processing. A workload may comprise several instructions and data to be processed by those instructions. The buffer may be a region in a memory that is accessible (e.g., read/write) by both the host processor and the PPU 1000. For example, the I/O unit 1005 may be configured to access the buffer in a system memory connected to the interconnect 1002 via memory requests transmitted over the interconnect 1002. In at least one embodiment, the host processor writes the command stream to the buffer and then transmits a pointer to the start of the command stream to the PPU 1000. The front end unit 1015 receives pointers to one or more command streams. The front end unit 1015 manages the one or more streams, reading commands from the streams and forwarding commands to the various units of the PPU 1000.

The front end unit 1015 is coupled to a scheduler unit 1020 that configures the various GPCs 1050 to process tasks defined by the one or more streams. The scheduler unit 1020 is configured to track state information related to the various tasks managed by the scheduler unit 1020. The state may indicate which GPC 1050 a task is assigned to, whether the task is active or inactive, a priority level associated with the task, and so forth. The scheduler unit 1020 manages the execution of a plurality of tasks on the one or more GPCs 1050.

The scheduler unit 1020 is coupled to a work distribution unit 1025 that is configured to dispatch tasks for execution on the GPCs 1050. The work distribution unit 1025 may track a number of scheduled tasks received from the scheduler unit 1020. In at least one embodiment, the work distribution unit 1025 manages a pending task pool and an active task pool for each of the GPCs 1050. The pending task pool may comprise a number of slots (e.g., 32 slots) that contain tasks assigned to be processed by a particular GPC 1050. The active task pool may comprise a number of slots (e.g., 4 slots) for tasks that are actively being processed by the GPCs 1050. As a GPC 1050 finishes the execution of a task, that task may be evicted from the active task pool for the GPC 1050 and one of the other tasks from the pending task pool is selected and scheduled for execution on the GPC 1050. If an active task has been idle on the GPC 1050, such as while waiting for a data dependency to be resolved, then the active task may be evicted from the GPC 1050 and returned to the pending task pool while another task in the pending task pool is selected and scheduled for execution on the GPC 1050.

The work distribution unit 1025 communicates with the one or more GPCs 1050 via XBar 1070. The XBar 1070 is an interconnect network that couples many of the units of the PPU 1000 to other units of the PPU 1000. For example, the XBar 1070 may be configured to couple the work distribution unit 1025 to a particular GPC 1050. Although not shown explicitly, one or more other units of the PPU 1000 may also be connected to the XBar 1070 via the hub 1030.

The tasks are managed by the scheduler unit 1020 and dispatched to a GPC 1050 by the work distribution unit 1025. The GPC 1050 is configured to process the task and generate results. The results may be consumed by other tasks within the GPC 1050, routed to a different GPC 1050 via the XBar 1070, or stored in the memory 1004. The results can be written to the memory 1004 via the partition units 1080, which may implement a memory interface for reading and writing data to/from the memory 1004. The results can be transmitted to another PPU 1000 or CPU via the NVLink 1010. In at least one embodiment, the PPU 1000 includes a number U of partition units 1080 that is equal to the number of separate and distinct memory devices 1004 coupled to the PPU 1000.

In at least one embodiment, a host processor executes a driver kernel that implements an application programming interface (API) that enables one or more applications executing on the host processor to schedule operations for execution on the PPU 1000. In at least one embodiment, multiple compute applications are simultaneously executed by the PPU 1000 and the PPU 1000 provides isolation, quality of service (QoS), and independent address spaces for the multiple compute applications. An application may generate instructions (e.g., API calls) that cause the driver kernel to generate one or more tasks for execution by the PPU 1000. The driver kernel may output tasks to one or more streams being processed by the PPU 1000. Each task may comprise one or more groups of related threads, wherein may be referred to as a warp. In at least one embodiment, a warp comprises 32 related threads that may be executed in parallel. Cooperating threads may refer to a plurality of threads including instructions to perform the task and that may exchange data through shared memory.

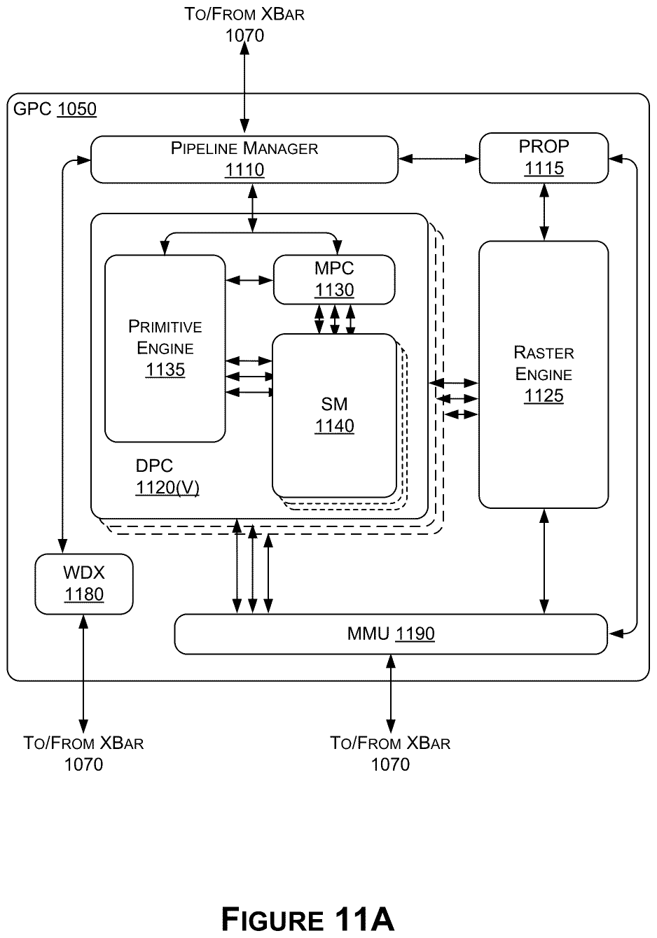

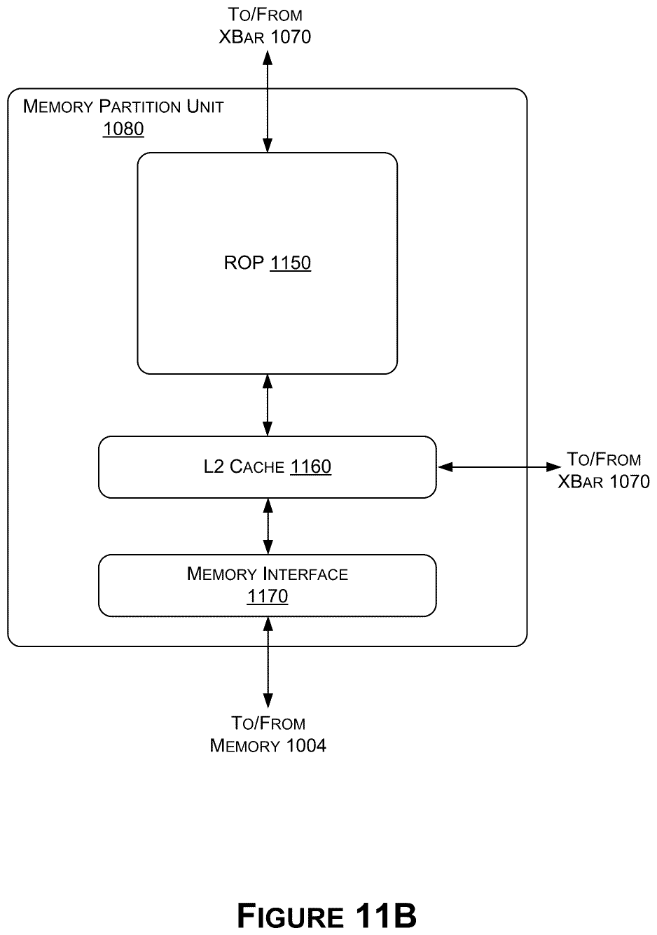

FIG. 11A illustrates an example GPC 1050 of the PPU 1000 of FIG. 10 suitable for use in implementing at least some embodiments of the present disclosure. As shown in FIG. 11A, each GPC 1050 may include a number of hardware units for processing tasks. In at least one embodiment, each GPC 1050 includes a pipeline manager 1110, a pre-raster operations unit (PROP) 1115, a raster engine 1125, a work distribution crossbar (WDX) 1180, a memory management unit (MMU) 1190, and one or more Data Processing Clusters (DPCs) 1120. It will be appreciated that the GPC 1050 of FIG. 11A may include other hardware units in lieu of or in addition to the units shown in FIG. 11A.

In at least one embodiment, the operation of the GPC 1050 is controlled by the pipeline manager 1110. The pipeline manager 1110 manages the configuration of the one or more DPCs 1120 for processing tasks allocated to the GPC 1050. In at least one embodiment, the pipeline manager 1110 may configure at least one of the one or more DPCs 1120 to implement at least a portion of a graphics rendering pipeline. For example, a DPC 1120 may be configured to execute a vertex shader program on the programmable streaming multiprocessor (SM) 1140. The pipeline manager 1110 may also be configured to route packets received from the work distribution unit 1025 to the appropriate logical units within the GPC 1050. For example, some packets may be routed to fixed function hardware units in the PROP 1115 and/or raster engine 1125 while other packets may be routed to the DPCs 1120 for processing by the primitive engine 1135 or the SM 1140. In at least one embodiment, the pipeline manager 1110 may configure at least one of the one or more DPCs 1120 to implement a neural network model and/or a computing pipeline.

The PROP unit 1115 may be configured to route data generated by the raster engine 1125 and the DPCs 1120 to a Raster Operations (ROP) unit. The PROP unit 1115 may also be configured to perform optimizations for color blending, organizing pixel data, performing address translations, and the like.

The raster engine 1125 may include a number of fixed function hardware units configured to perform various raster operations. In at least one embodiment, the raster engine 1125 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x,y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 1125 comprises fragments to be processed, for example, by a fragment shader implemented within a DPC 1120.

Each DPC 1120 included in the GPC 1050 includes an M-Pipe Controller (MPC) 1130, a primitive engine 1135, and one or more SMs 1140. The MPC 1130 controls the operation of the DPC 1120, routing packets received from the pipeline manager 1110 to the appropriate units in the DPC 1120. For example, packets associated with a vertex may be routed to the primitive engine 1135, which is configured to fetch vertex attributes associated with the vertex from the memory 1004. In contrast, packets associated with a shader program may be transmitted to the SM 1140.

The SM 1140 comprises a programmable streaming processor that is configured to process tasks represented by a number of threads. Each SM 1140 is multi-threaded and configured to execute a plurality of threads (e.g., 32 threads) from a particular group of threads concurrently. In at least one embodiment, the SM 1140 implements a SIMD (Single-Instruction, Multiple-Data) architecture where each thread in a group of threads (e.g., a warp) is configured to process a different set of data based on the same set of instructions. All threads in the group of threads execute the same instructions. In at least one embodiment, the SM 1140 implements a SIMT (Single-Instruction, Multiple Thread) architecture where each thread in a group of threads is configured to process a different set of data based on the same set of instructions, but where individual threads in the group of threads are allowed to diverge during execution. In at least one embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency.

The MMU 1190 may provide an interface between the GPC 1050 and the partition unit 1080. The MMU 1190 may provide translation of virtual addresses into physical addresses, memory protection, and arbitration of memory requests. In at least one embodiment, the MMU 1190 provides one or more translation lookaside buffers (TLBs) for performing translation of virtual addresses into physical addresses in the memory 1004.

FIG. 11B illustrates an example memory partition unit 1080 of the PPU 1000 of FIG. 10 suitable for use in implementing at least some embodiments of the present disclosure. As shown in FIG. 11B, the memory partition unit 1080 includes a Raster Operations (ROP) unit 1150, a level two (L2) cache 1160, and a memory interface 1170. The memory interface 1170 may be coupled to the memory 1004. Memory interface 1170 may implement 32, 64, 128, 1024-bit data buses, or the like, for high-speed data transfer. In at least one embodiment, the PPU 1000 incorporates U memory interfaces 1170, one memory interface 1170 per pair of partition units 1080, where each pair of partition units 1080 is connected to a corresponding memory device 1004. For example, the PPU 1000 may be connected to up to Y memory devices 1004, such as high bandwidth memory stacks or graphics double-data-rate, version 5, synchronous dynamic random access memory, or other types of persistent storage.

In at least one embodiment, the memory interface 1170 implements an HBM2 memory interface and Y equals half U. In at least one embodiment, the HBM2 memory stacks are located on the same physical package as the PPU 1000, providing substantial power and area savings compared with conventional GDDR5 SDRAM systems. In at least one embodiment, each HBM2 stack includes four memory dies and Y equals 4, with HBM2 stack including two 128-bit channels per die for a total of 8 channels and a data bus width of 1024 bits.

In at least one embodiment, the memory 1004 supports Single-Error Correcting Double-Error Detecting (SECDED) Error Correction Code (ECC) to protect data. ECC provides high reliability for compute applications that are sensitive to data corruption. Reliability is especially important in large-scale cluster computing environments where the PPUs 1000 process very large datasets and/or run applications for extended periods.

In at least one embodiment, the PPU 1000 implements a multi-level memory hierarchy. In at least one embodiment, the memory partition unit 1080 supports a unified memory to provide a single unified virtual address space for CPU and PPU 1000 memory, enabling data sharing between virtual memory systems. In at least one embodiment the frequency of accesses by a PPU 1000 to memory located on other processors is traced to ensure that memory pages are moved to the physical memory of the PPU 1000 that is accessing the pages more frequently. In at least one embodiment, the NVLink 1010 supports address translation services allowing the PPU 1000 to directly access a CPU's page tables and providing full access to CPU memory by the PPU 1000.

In at least one embodiment, copy engines transfer data between multiple PPUs 1000 or between PPUs 1000 and CPUs. The copy engines can generate page faults for addresses that are not mapped into the page tables. The memory partition unit 1080 can then service the page faults, mapping the addresses into the page table, after which the copy engine can perform the transfer. With hardware page faulting, addresses can be passed to the copy engines without worrying if the memory pages are resident, and the copy process is transparent.

Data from the memory 1004 or other system memory may be fetched by the memory partition unit 1080 and stored in the L2 cache 1160, which is located on-chip and is shared between the various GPCs 1050. As shown, each memory partition unit 1080 includes a portion of the L2 cache 1160 associated with a corresponding memory device 1004. Lower level caches may then be implemented in various units within the GPCs 1050. For example, each of the SMs 1140 may implement a level one (L1) cache. The L1 cache is private memory that may be dedicated to a particular SM 1140. Data from the L2 cache 1160 may be fetched and stored in each of the L1 caches for processing in the functional units of the SMs 1140. The L2 cache 1160 is coupled to the memory interface 1170 and the XBar 1070.

The ROP unit 1150 performs graphics raster operations related to pixel color, such as color compression, pixel blending, and the like. The ROP unit 1150 also implements depth testing in conjunction with the raster engine 1125, receiving a depth for a sample location associated with a pixel fragment from the culling engine of the raster engine 1125. The depth is tested against a corresponding depth in a depth buffer for a sample location associated with the fragment. If the fragment passes the depth test for the sample location, then the ROP unit 1150 updates the depth buffer and transmits a result of the depth test to the raster engine 1125. It will be appreciated that the number of partition units 1080 may be different than the number of GPCs 1050 and, therefore, each ROP unit 1150 may be coupled to each of the GPCs 1050. The ROP unit 1150 may track packets received from the different GPCs 1050 and determine which GPC 1050 that a result generated by the ROP unit 1150 is routed to through the Xbar 1070. Although the ROP unit 1150 is included within the memory partition unit 1080 in FIG. 11B, in other examples, the ROP unit 1150 may be outside of the memory partition unit 1080. For example, the ROP unit 1150 may reside in the GPC 1050 or another unit.

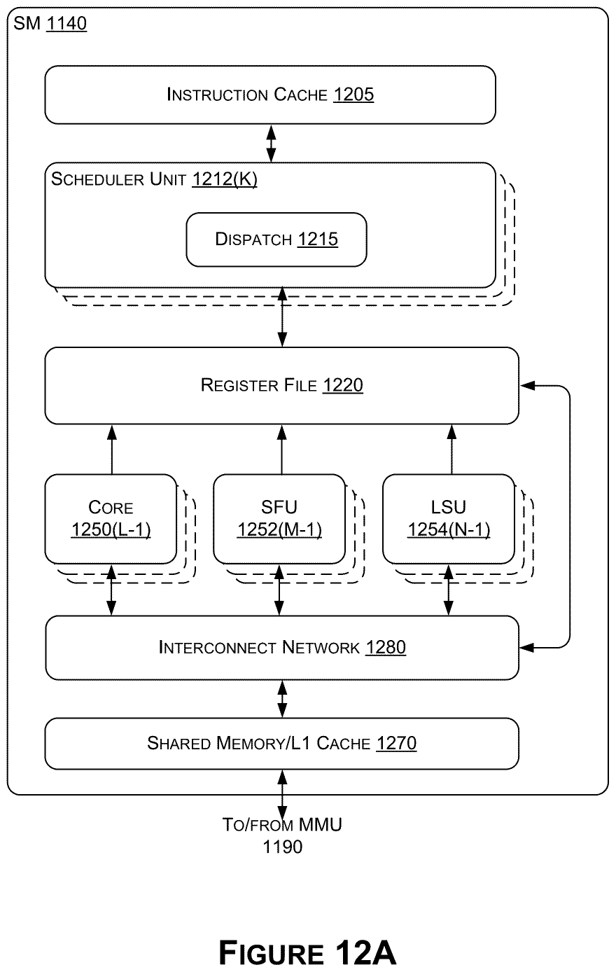

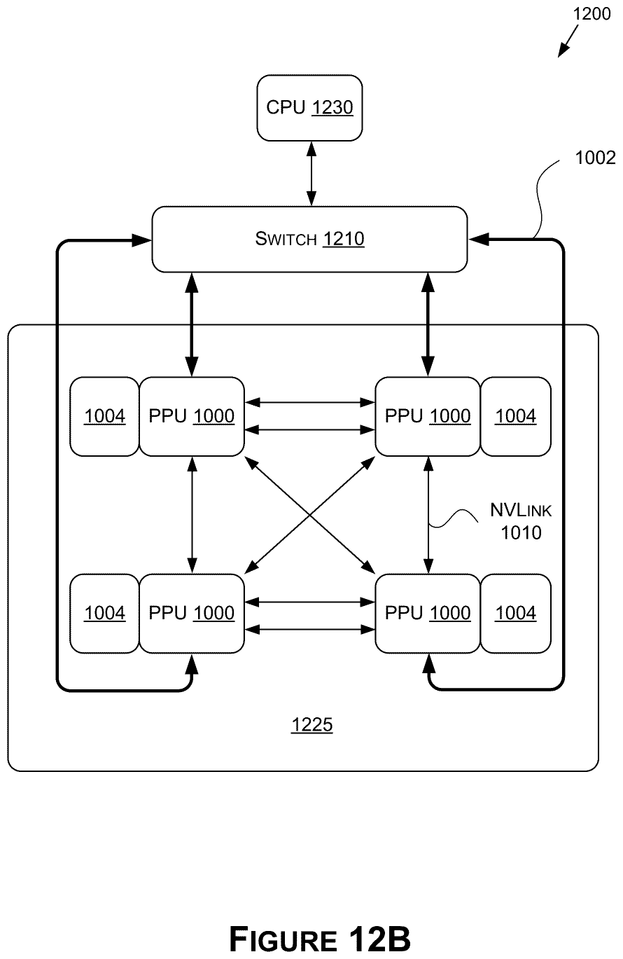

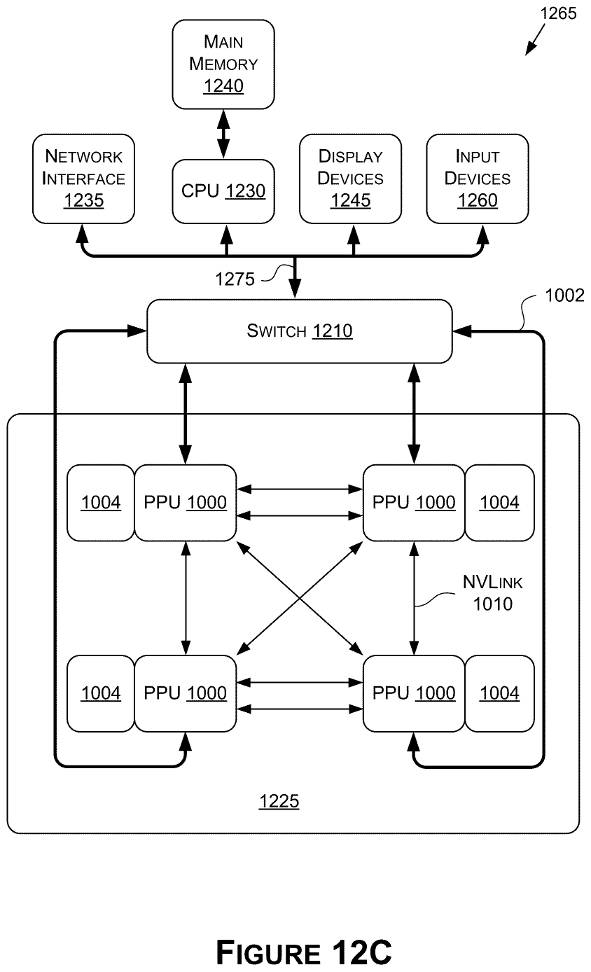

FIG. 12A illustrates an example of the streaming multi-processor 1140 of FIG. 11A suitable for use in implementing at least some embodiments of the present disclosure. As shown in FIG. 12A, the SM 1140 includes an instruction cache 1205, one or more scheduler units 1212, a register file 1220, one or more processing cores 1250, one or more special function units (SFUs) 1252, one or more load/store units (LSUs) 1254, an interconnect network 1280, and a shared memory/L1 cache 1270.

As described herein, the work distribution unit 1025 dispatches tasks for execution on the GPCs 1050 of the PPU 1000. The tasks may be allocated to a particular DPC 1120 within a GPC 1050 and, if the task is associated with a shader program, the task may be allocated to an SM 1140. The scheduler unit 1212 may receive the tasks from the work distribution unit 1025 and manage instruction scheduling for one or more thread blocks assigned to the SM 1140. The scheduler unit 1212 may schedule thread blocks for execution as warps of parallel threads, where each thread block is allocated at least one warp. In at least one embodiment, each warp executes 32 threads. The scheduler unit 1212 may manage a plurality of different thread blocks, allocating the warps to the different thread blocks and then dispatching instructions from the plurality of different cooperative groups to the various functional units (e.g., cores 1250, SFUs 1252, and LSUs 1254) during each clock cycle.

Cooperative Groups may refer to a programming model for organizing groups of communicating threads that allows developers to express the granularity at which threads are communicating, enabling the expression of richer, more efficient parallel decompositions. Cooperative launch APIs may support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch unit 1215 may be configured to transmit instructions to one or more of the functional units. In at least one embodiment, the scheduler unit 1212 includes two dispatch units 1215 that enable two different instructions from the same warp to be dispatched during each clock cycle. In at least embodiment, each scheduler unit 1212 may include a single dispatch unit 1215 or additional dispatch units 1215.

Each SM 1140 may include a register file 1220 that provides a set of registers for the functional units of the SM 1140. In at least one embodiment, the register file 1220 is divided between each of the functional units such that each functional unit is allocated a dedicated portion of the register file 1220. In at least one embodiment, the register file 1220 is divided between the different warps being executed by the SM 1140. The register file 1220 provides temporary storage for operands connected to the data paths of the functional units.

Each SM 1140 may include L processing cores 1250. In at least one embodiment, the SM 1140 includes a large number (e.g., 128, etc.) of distinct processing cores 1250. Each core 1250 may include a fully-pipelined, single-precision, double-precision, and/or mixed precision processing unit that includes a floating point arithmetic logic unit and an integer arithmetic logic unit. In at least one embodiment, the floating point arithmetic logic units implement the IEEE 754-2008 standard for floating point arithmetic. In at least one embodiment, the cores 1250 include 64 single-precision (32-bit) floating point cores, 64 integer cores, 32 double-precision (64-bit) floating point cores, and 8 tensor cores.

Tensor cores configured to perform matrix operations, and, in at least one embodiment, one or more tensor cores are included in the cores 1250. In particular, the tensor cores may be configured to perform deep learning matrix arithmetic, such as convolution operations for neural network training and inferencing. In at least one embodiment, each tensor core operates on a 4×4 matrix and performs a matrix multiply and accumulate operation D=A×B+C, where A, B, C, and D are 4×4 matrices.

Training complex neural networks requires massive amounts of parallel computing performance, including floating-point multiplications and additions that are supported by the PPU 1000. Inferencing is less compute-intensive than training, being a latency-sensitive process where a trained neural network is applied to new inputs it has not seen before to classify images, translate speech, and infer new information.

Neural networks rely heavily on matrix math operations, and complex multi-layered networks require tremendous amounts of floating-point performance and bandwidth for both efficiency and speed. With thousands of processing cores, optimized for matrix math operations, and delivering tens to hundreds of TFLOPS of performance, the PPU 1000 may form a computing platform capable of delivering performance required for deep neural network-based artificial intelligence and machine learning applications.

In at least one embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores may be used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each SM 1140 may also include M SFUs 1252 that perform special functions (e.g., attribute evaluation, reciprocal square root, and the like). In at least one embodiment, the SFUs 1252 may include a tree traversal unit configured to traverse a hierarchical tree data structure. In at least one embodiment, the SFUs 1252 may include texture unit configured to perform texture map filtering operations. In at least one embodiment, the texture units are configured to load texture maps (e.g., a 2D array of texels) from the memory 1004 and sample the texture maps to produce sampled texture values for use in shader programs executed by the SM 1140. In at least one embodiment, the texture maps are stored in the shared memory/L1 cache 1170. The texture units implement texture operations such as filtering operations using mip-maps (e.g., texture maps of varying levels of detail). In at least one embodiment, each SM 1140 includes two texture units.

Each SM 1140 may also include N LSUs 1254 that implement load and store operations between the shared memory/L1 cache 1270 and the register file 1220. Each SM 1140 may include an interconnect network 1280 that connects each of the functional units to the register file 1220 and the LSU 1254 to the register file 1220, shared memory/L1 cache 1270. In at least one embodiment, the interconnect network 1280 is a crossbar that can be configured to connect any of the functional units to any of the registers in the register file 1220 and connect the LSUs 1254 to the register file and memory locations in shared memory/L1 cache 1270.

The shared memory/L1 cache 1270 may include an array of on-chip memory that allows for data storage and communication between the SM 1140 and the primitive engine 1135 and between threads in the SM 1140. In at least one embodiment, the shared memory/L1 cache 1270 comprises 128 KB of storage capacity and is in the path from the SM 1140 to the partition unit 1080. The shared memory/L1 cache 1270 can be used to cache reads and writes. One or more of the shared memory/L1 cache 1270, L2 cache 1160, and memory 1004 may be backing stores.

Combining data cache and shared memory functionality into a single memory block may provide the best overall performance for both types of memory accesses. The capacity may be usable as a cache by programs that do not use shared memory. For example, if shared memory is configured to use half of the capacity, texture and load/store operations can use the remaining capacity. Integration within the shared memory/L1 cache 1270 may enable the shared memory/L1 cache 1270 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 10, may be bypassed, creating a much simpler programming model. In the general-purpose parallel computation configuration, the work distribution unit 1025 may assign and distribute blocks of threads directly to the DPCs 1120. The threads in a block may execute the same program, using a unique thread ID in the calculation to ensure each thread generates unique results, using the SM 1140 to execute the program and perform calculations, shared memory/L1 cache 1270 to communicate between threads, and the LSU 1254 to read and write global memory through the shared memory/L1 cache 1270 and the memory partition unit 1080. When configured for general purpose parallel computation, the SM 1140 can also write commands that the scheduler unit 1020 can use to launch new work on the DPCs 1120.

The PPU 1000 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In at least one embodiment, the PPU 1000 is embodied on a single semiconductor substrate. In at least one embodiment, the PPU 1000 is included in a system-on-a-chip (SoC) along with one or more other devices such as additional PPUs 1000, the memory, a reduced instruction set computer (RISC) CPU, a memory management unit (MMU), a digital-to-analog converter (DAC), and the like.

In at least one embodiment, the PPU 1000 may be included on a graphics card that includes one or more memory devices 1004. The graphics card may be configured to interface with a PCIe slot on a motherboard of a desktop computer. In at least one embodiment, the PPU 1000 may be an integrated graphics processing unit (iGPU) or parallel processor included in the chipset of the motherboard.

### Example of a Computing System

Systems with multiple GPUs and CPUs are used in a variety of industries as developers expose and use more parallelism in applications such as artificial intelligence computing. High-performance GPU-accelerated systems with tens to many thousands or more of compute nodes are deployed in data centers, research facilities, and supercomputers to solve ever larger problems. As the number of processing devices within the high-performance systems increases, the communication and data transfer mechanisms need to scale to support the increased bandwidth.

FIG. 12B is an example conceptual diagram of a processing system 1200 implemented using the PPU 1000 of FIG. 10 suitable for use in implementing at least some embodiments of the present disclosure. The processing system 1200 includes a CPU 1230, switch 1210, and multiple PPUs 1000 each and respective memories 1004. The NVLink 1010 provides high-speed communication links between each of the PPUs 1000. Although a particular number of NVLink 1010 and interconnect 1002 connections are illustrated in FIG. 12B, the number of connections to each PPU 1000 and the CPU 1230 may vary. The switch 1210 interfaces between the interconnect 1002 and the CPU 1230. The PPUs 1000, memories 1004, and NVLinks 1010 may be situated on a single semiconductor platform to form a parallel processing system 1225. In at least one embodiment, the switch 1210 supports two or more protocols to interface between various different connections and/or links.

In at least embodiment (not shown), the NVLink 1010 provides one or more high-speed communication links between each of the PPUs 1000 and the CPU 1230 and the switch 1210 interfaces between the interconnect 1002 and each of the PPUs 1000. The PPUs 1000, memories 1004, and interconnect 1002 may be situated on a single semiconductor platform to form a parallel processing module 1225. In at least one embodiment (not shown), the interconnect 1002 provides one or more communication links between each of the PPUs 1000 and the CPU 1230 and the switch 1210 interfaces between each of the PPUs 1000 using the NVLink 1010 to provide one or more high-speed communication links between the PPUs 1000. In at least one embodiment (not shown), the NVLink 1010 provides one or more high-speed communication links between the PPUs 1000 and the CPU 1230 through the switch 1210. In yet at least one embodiment (not shown), the interconnect 1002 provides one or more communication links between each of the PPUs 1000 directly. One or more of the NVLink 1010 high-speed communication links may be implemented as a physical NVLink interconnect or either an on-chip or on-die interconnect using the same protocol as the NVLink 1010.

In the context of the present description, a single semiconductor platform may refer to a sole unitary semiconductor-based integrated circuit fabricated on a die or chip. The term single semiconductor platform may also refer to multi-chip modules with increased connectivity which simulate on-chip operation and make substantial improvements over using a conventional bus implementation. Of course, the various circuits or devices may also be situated separately or in various combinations of semiconductor platforms per the desires of the user. Alternately, the parallel processing module 1225 may be implemented as a circuit board substrate and each of the PPUs 1000 and/or memories 1004 may be packaged devices. In at least one embodiment, the CPU 1230, switch 1210, and the parallel processing module 1225 are situated on a single semiconductor platform.

In at least one embodiment, the signaling rate of each NVLink 1010 is 20 to 25 Gigabits/second and each PPU 1000 includes six NVLink 1010 interfaces (as shown in FIG. 12B, five NVLink 1010 interfaces are included for each PPU 1000). Each NVLink 1010 may provide a data transfer rate of 25 Gigabytes/second in each direction, with six links providing 1000 Gigabytes/second. The NVLinks 1010 can be used exclusively for PPU-to-PPU communication as shown in FIG. 12B, or some combination of PPU-to-PPU and PPU-to-CPU, when the CPU 1230 also includes one or more NVLink 1010 interfaces.

In at least one embodiment, the NVLink 1010 allows direct load/store/atomic access from the CPU 1230 to the memory 1004 of the PPUs 1000. In at least one embodiment, the NVLink 1010 supports coherency operations, allowing data read from the memories 1004 to be stored in the cache hierarchy of the CPU 1230, reducing cache access latency for the CPU 1230. In at least one embodiment, the NVLink 1010 includes support for Address Translation Services (ATS), allowing the PPU 1000 to directly access page tables within the CPU 1230. One or more of the NVLinks 1010 may also be configured to operate in a low-power mode.

FIG. 12C illustrates an example system 1265 in which the various architecture and/or functionality of the various previous embodiments may be implemented suitable for use in implementing at least some embodiments of the present disclosure.

As shown, a system 1265 is provided including at least one central processing unit (CPU) 1230 that is connected to a communication bus 1275. The communication bus 1275 may be implemented using any suitable protocol, such as PCI (Peripheral Component Interconnect), PCI-Express, AGP (Accelerated Graphics Port), HyperTransport, or any other bus or point-to-point communication protocol(s). The system 1265 also includes a main memory 1240. Control logic (software) and data are stored in the main memory 1240 which may take the form of random access memory (RAM).

The system 1265 also includes input devices 1260, the parallel processing system 1225, and display devices 1245, e.g. a conventional CRT (cathode ray tube), LCD (liquid crystal display), LED (light emitting diode), plasma display or the like. User input may be received from the input devices 1260, e.g., keyboard, mouse, touchpad, microphone, and the like. Each of the foregoing modules and/or devices may even be situated on a single semiconductor platform to form the system 1265. Alternately, the various modules may also be situated separately or in various combinations of semiconductor platforms per the desires of the user.

Further, the system 1265 may be coupled to a network (e.g., a telecommunications network, local area network (LAN), wireless network, wide area network (WAN) such as the Internet, peer-to-peer network, cable network, or the like) through a network interface 1235 for communication purposes.

The system 1265 may also include a secondary storage (not shown). The secondary storage may include, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive may read from and/or writes to a removable storage unit.

Computer programs, or computer control logic algorithms, may be stored in the main memory 1240 and/or the secondary storage. Such computer programs, when executed, enable the system 1265 to perform various functions. The memory 1240, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the system 1265 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

### Ray Tracing Pipeline

In at least one embodiment, the PPU 1000 comprises a graphics processing unit (GPU). The PPU 1000 may be configured to receive commands that specify shader programs for processing graphics data. Graphics data may be defined as a set of primitives such as points, lines, triangles, quads, triangle strips, and the like. A primitive may include data that specifies a number of vertices for the primitive (e.g., in a model-space coordinate system) as well as attributes associated with each vertex of the primitive. The PPU 1000 may be configured to process the graphics primitives to generate a frame buffer (e.g., pixel data for each of the pixels of the display).

An application may write model data for a scene (e.g., a collection of vertices and attributes) to a memory such as a system memory or memory 1004. The model data may define each of the objects that may be visible on a display. The application may then make an API call to the driver kernel that requests the model data to be rendered and displayed. The driver kernel may read the model data and write commands to the one or more streams to perform operations to process the model data. The commands may reference different shader programs to be implemented on the SMs 1140 of the PPU 1000. For example, different SMs 1140 may be configured to execute different shader programs.

In at least one embodiment, the model data may be processed to perform one or more ray tracing operations, such as real-time tray tracing, to render the model data to a frame buffer. The contents of the frame buffer may be transmitted to a display controller for display on a display device. Ray tracing may refer to any of a variety of techniques for modeling or simulating light transport and/or other aspects of an environment, for example, for use in generating digital images or otherwise simulating the environment. Thus, while certain embodiments may be described with respect to light transport simulation, they may be applicable to simulating, modeling, and/or measuring any of a variety of aspects of an environment. Non-limiting examples of ray tracing include ray casting, recursive ray tracing, distribution ray tracing, photon mapping, and path tracing.

Ray tracing may be used to simulate a variety of optical effects—such as shadows, reflections, refractions, scattering phenomenon, ambient occlusions, global illuminations, or dispersion phenomenon (such as chromatic aberration). Ray tracing may involve generating ray-traced samples by casting rays in a virtual environment to sample lighting and/or other environmental conditions for pixels. The ray traced samples may be combined and used to determine pixel colors for an image. In at least one embodiment, to conserve computing resources, the lighting conditions may be sparsely sampled, resulting in noisy render data. Temporal accumulation may be used to increase the effective sample count by using information from previous frames. To produce a final render that approximates a render of a fully sampled scene, one or more denoising filters may by be applied to the noisy render data to reduce noise.

Many ray tracing algorithms may cast or shoot rays from a virtual camera, or eye, through a 2D viewing plane (e.g., a pixel plane) out into a 3D scene which may include one or more light sources. Some rays may directly reach the viewing plane from a light source, some may be blocked by an object in the scene causing shadows, and some may reflect or refract off an object before reaching the viewing plane. When the rays intersect objects, the color and lighting information at the points of intersection on object surfaces may contribute to various pixel color and illumination levels of pixels of the viewing plane. Different objects may have different surface properties that can cause them to reflect, refract, or absorb light in different ways, which may be accounted for in ray tracing. Rays may reflect off objects and hit other objects, or travel through the surfaces of transparent objects before reaching a light source, and the color and lighting information from all the intersected objects may contribute to the final pixel colors.

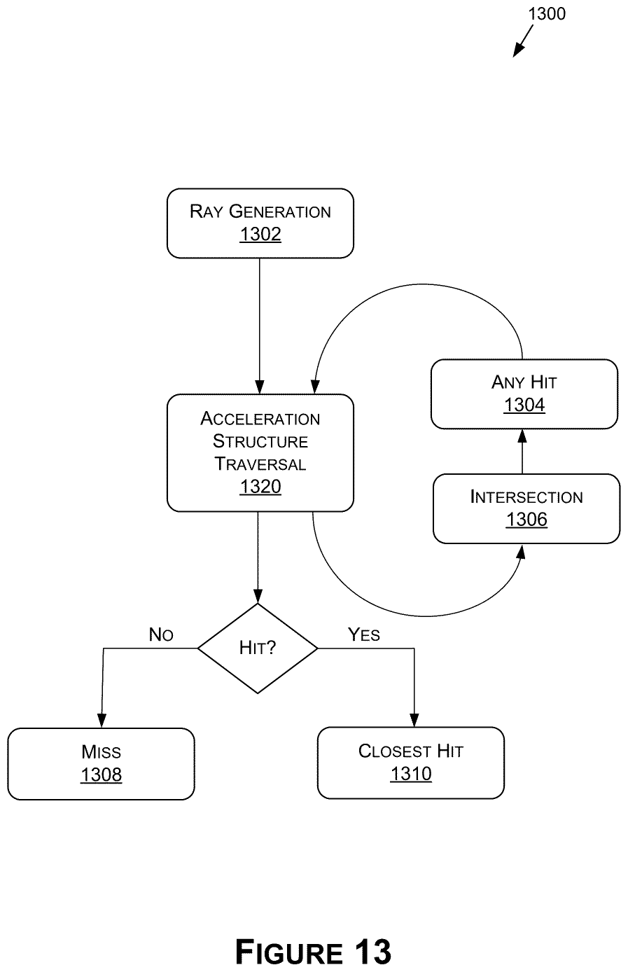

FIG. 13 illustrates an example ray tracing pipeline 1300 suitable for use in implementing at least some embodiments of the present disclosure. By way of example, and not limitations, the ray tracing pipeline 1300 may be implemented by the PPU 1000 of FIG. 10, in accordance with at least one embodiment. The ray tracing pipeline 1300 may include processing steps implemented to generate 2D computer-generated images from 3D geometry data using one or more ray tracing techniques.

In at least one embodiment, the ray tracing pipeline 1300 may be constructed using one or more ray generation shaders 1302, one or more any hit shaders 1304, one or more intersection shaders 1306, one or more miss shaders 1308, and/or one or more closest hit shaders 1310.

The ray tracing pipeline 1300 may be implemented via an application executed by a host processor, such as a CPU. In at least one embodiment, a device driver may implement an application programming interface (API) that defines various functions that can be used by an application in order to generate graphical data for display. The device driver may refer to a software program that includes instructions that control the operation of the PPU 1000, or other PPU used to implement the ray tracing pipeline 1300. The API may provide an abstraction for a programmer that lets a programmer use specialized graphics hardware, such as the PPU 1000, to generate the graphical data without requiring the programmer to use the specific instruction set for the PPU 1000. The application may include an API call that is routed to the device driver for the PPU 1000. The device driver may interpret the API call and perform various operations to respond to the API call. In at least one embodiment, the device driver performs operations by executing instructions on the CPU. In at least one embodiment, the device driver performs operations, at least in part, by launching operations on the PPU 1000 using an input/output interface between the CPU and the PPU 1000. In at least one embodiment, the device driver is configured to implement the ray tracing pipeline 1300 using the hardware of the PPU 1000.

Various programs may be executed within the PPU 1000 in order to implement the various stages of the ray tracing pipeline 1300. For example, the device driver may launch a kernel on the PPU 1000 to execute a stage implementing a ray generation shader 1302 on an SM 1140 (or multiple SMs 1140). The device driver (or the initial kernel executed by the PPU 1000) may also launch other kernels on the PPU 1000 to execute other stages of the ray tracing pipeline 1300.

The ray generation shader 1302 may be the first shader involved in ray tracing dispatch. The ray generation shader 1302 may call a High Level Shader Language (HLSL) function called TraceRay( ) This TraceRay( ) function may cast a single ray into the scene to search for intersections, which may trigger other shaders in the process. In at least one embodiment, the ray generation shader 1302 may call TraceRay( ) any number of times.

An any hit shader 1304 and an intersection shader 1306 may be invoked whenever TraceRay( ) finds a potential intersection between the ray and the scene. The intersection shader 1306 may determine whether the ray intersects an individual geometric primitive—for example a sphere, a subdivision surface, a triangle, or other form of primitive. Once an intersection is found, the any hit shader 1304 may be used to process the intersection further or potentially discard the intersection. An any hit shader 1304 may, by way of example and not limitation, use alpha testing by performing a texture lookup and deciding based on the texel's value whether or not to discard an intersection.

Once TraceRay( ) has completed the search for ray-scene intersections, either a miss shader 1308 or a closest hit shader 1310 may be invoked, depending on the outcome of the search. The closest hit shader 1310 may perform most shading operations, such as, material evaluation, texture lookups, and so on. The miss shader 1308 may be used to implement environment lookups, for example. In at least one embodiment, one or more of the closest hit shader 1310 or the miss shader 1308 may recursively trace rays by calling TraceRay( ) themselves.

The ray tracing pipeline 1300 constructed from any of the various shaders described herein may define a single-ray programming model. In at least one embodiment, each thread of the PPU 1000, and/or other PPU used to implement the ray tracing pipeline 1300, may handle one ray at a time. In at least one embodiment, each thread cannot communicate with other threads or see other rays currently being processed. This may simplify shader code, while allowing for vendor-specific optimizations using the API.

In at least one embodiment, different shaders and/or shader types may communicate with each other using a ray payload. A ray payload may refer to a user-defined struct that's passed as an INOUT parameter to TraceRay( ) For example, an any hit shader 1304, a closest hit shader 1310, and/or a miss shader 1308 may read from and/or write to the ray payload, and therefore pass back the result of their computations to the caller of TraceRay( ).

In at least one embodiment, a ray generation shader 1302 may trace primary rays, which may include rays being sent into the scene originating from a virtual camera. However, ray generation shaders 1302 are not limited to this functionality. In at least one embodiment, a ray generation shader 1302 may base ray generation on rasterized g-buffer data (e.g., to trace reflections). Using this approach, ray tracing may be used to complement rasterization, rather than replace rasterization.

When using traditional rasterization, only the shaders required by the current object being drawn may have to be active on the PPU. This may allow rasterization pipeline objects to be relatively small, containing a single set of vertex shaders, pixel shaders, etc. In contrast, a ray tracing pipeline 1300 may be used to arbitrarily shoot rays into the scene. This may mean the rays could hit any object or many objects in the scene. Therefore, it may be the case that all shaders for all objects could potentially be hit and therefore it may be desirable for the shaders to all be resident on the PPU and ready for execution.

In at least one embodiment, a state object may be used to group shaders together for execution. At a high level, a state object of a ray tracing pipeline 1300 may be seen as a binary executable resulting from a link step across all the shaders compiled for the scene. The relationship between different shaders may be specified at state object creation. For example, triplets of intersection shaders 1306, any hit shaders 1304, and/or closest hit shaders 1310 may be bundled into hit groups. The application may specify the state object of the ray tracing pipeline 1300 to be executed when calling a DispatchRays( ) function on a command list. A DispathRays( ) function may invoke a ray generation shader 1302 for each pixel for an image. In at least one embodiment, an application may create any number of state objects for a ray tracing pipeline 1300 and may re-use precompiled shaders for this purpose.

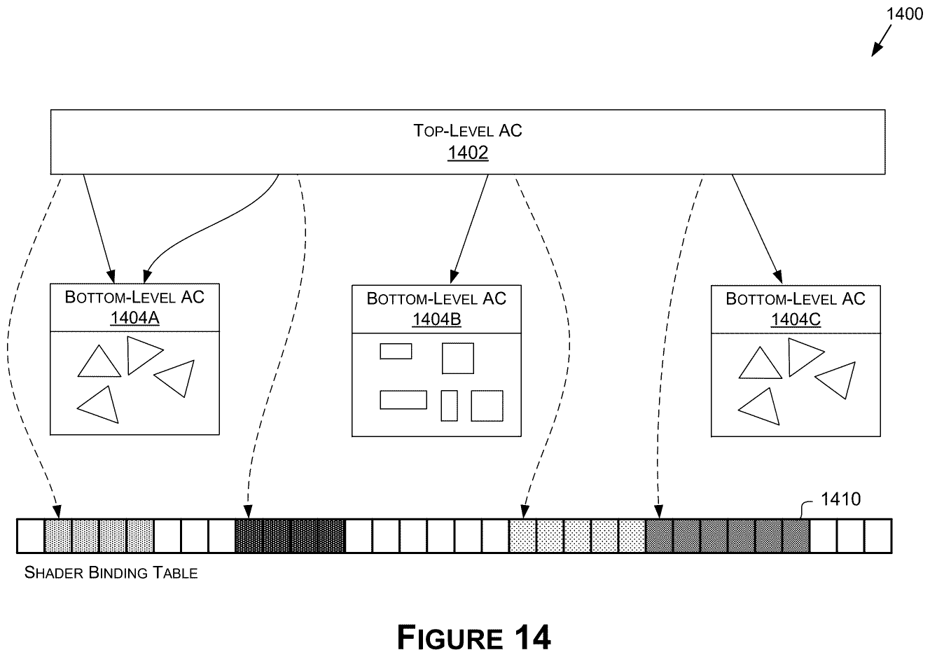

Referring now to FIG. 14, FIG. 14 illustrates an example acceleration structure 1400 suitable for use in implementing at least some embodiments of the present disclosure. The acceleration structure 1400 includes one or more top-level acceleration structures, such as a top-level acceleration structure 1402, and one or more bottom-level acceleration structures, such as bottom-level acceleration structures 1404A, 1404B, and 1404C.

The acceleration structure 1400 may comprise a spatial search data structure used in a ray tracing pipeline 1300 for acceleration structure traversal 1320 to efficiently compute intersections of rays with scene geometry. In at least one embodiment, the application may build an acceleration structure 1400 explicitly using a command list method BuildRaytracingAccelerationStructure( ). In at least one embodiment, the application may optimize an acceleration structure 1400 for different types of content, such as static versus animated content.

A top-level acceleration structure 1402 may be built from one or more references to one or more bottom-level acceleration structures 1404A, 1404B, and/or 1404C. These references may be referred to as instance descriptors. Each instance descriptor may include a transformation matrix to position the instance descriptor in the scene, and an offset into a shader table 1410 (which may also be referred to as a “shader binding table”) to locate material information. In at least one embodiment, a top-level acceleration structure 1402 may be used as a scene parameter provided to TraceRay( ) in a ray generation shader 1302, and may represent an entry point of the intersection search.

A ray tracing pipeline 1300 may specify the shaders that exist in a scene and an acceleration structure 1400 may specify geometry for the scene. The shader table 1410 may refer to a data structure used to tie the geometry to the shaders. For example, the shader table 1410 may define which shader is associated with which object in the scene. In addition, the shader table 1410 may hold information about the resources accessed by each shader, such as textures, buffers, and constants.

A shader table 1410 may comprise a chunk of PPU memory, which may be managed by the application. The application may be responsible for allocating the resource, filling the shader table 1410 with valid data, transferring it to the PPU, and correctly synchronizing the shader table 1410 with ray tracing dispatches. The application may also maintain multiple shader tables 1410, and, for example, multi-buffer them to update one copy while using another for rendering.

A shader table 1410 may comprise an array of equal-sized shader records. Each shader record may associate a shader (or a hit group) with a set of resources. In at least one embodiment, there may exist one record per geometry object in the scene, and a shader table 1410 may include thousands of entries or more.

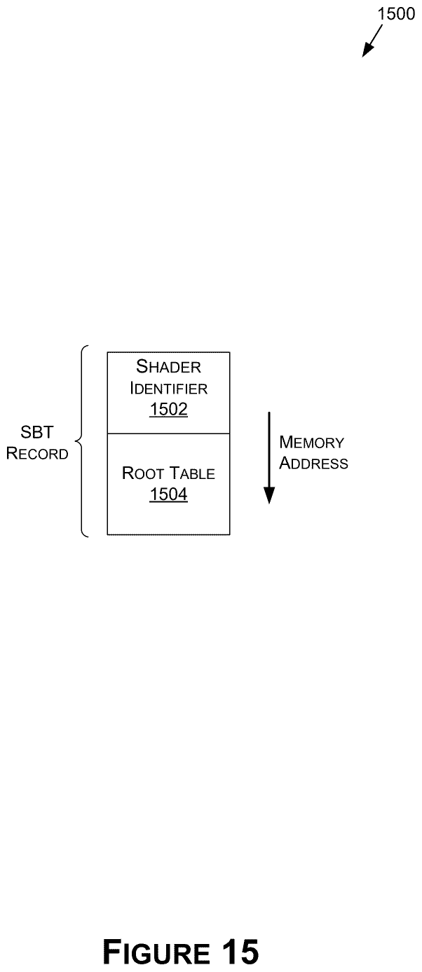

Referring now to FIG. 15, FIG. 15 illustrates an example shader record 1500 suitable for use in implementing at least some embodiments of the present disclosure. The shader record 1500 is an example of a shader record that may be included in the shader table 1410 of FIG. 14. The shader record 1500 includes a shader identifier 1502 and a root table 1504.

In at least one embodiment, the shader identifier 1502 may be represented in a beginning portion of the shader record 1500 in memory. The shader identifier 1502 may be an opaque identifier, which the application obtains by querying for the shader identifier 1502 from a compiled shader. The root table 1504 may contain the shader's resources. The layout of the root table 1504 may be defined by the shader's local root signature. The root signature may contain any combination of constants, descriptor tables, and root descriptors. For ray tracing, the application may directly access the root table 1504 in memory (e.g., rather than using “setter” methods), which may allow for efficient updates. In at least one embodiment, a shader table 1410 may be updated from a PPU shader.

As described herein, shader table offsets may be used when building a top-level acceleration structure 1402 from instance descriptors. The system may use these offsets to locate the correct shader record 1500 whenever TraceRay( ) finds an intersection. The system may then bind the resources defined in the shader record 1500 and execute the appropriate shader for the intersected geometry.

### Example Autonomous Vehicle

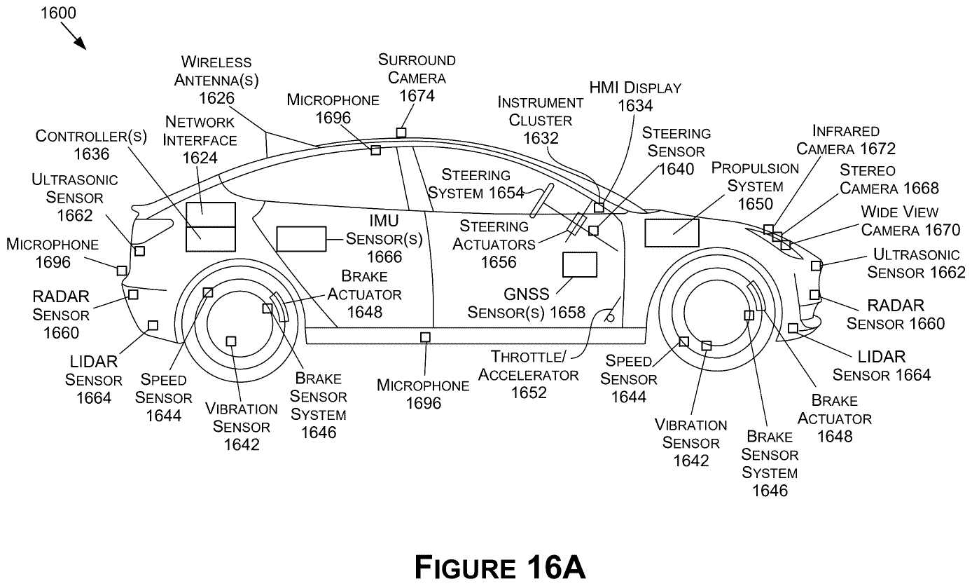

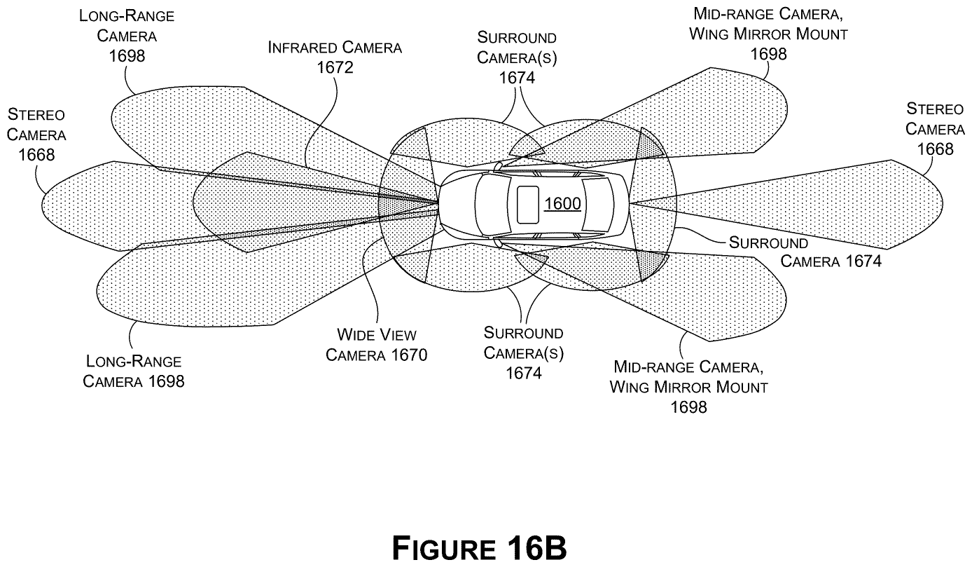

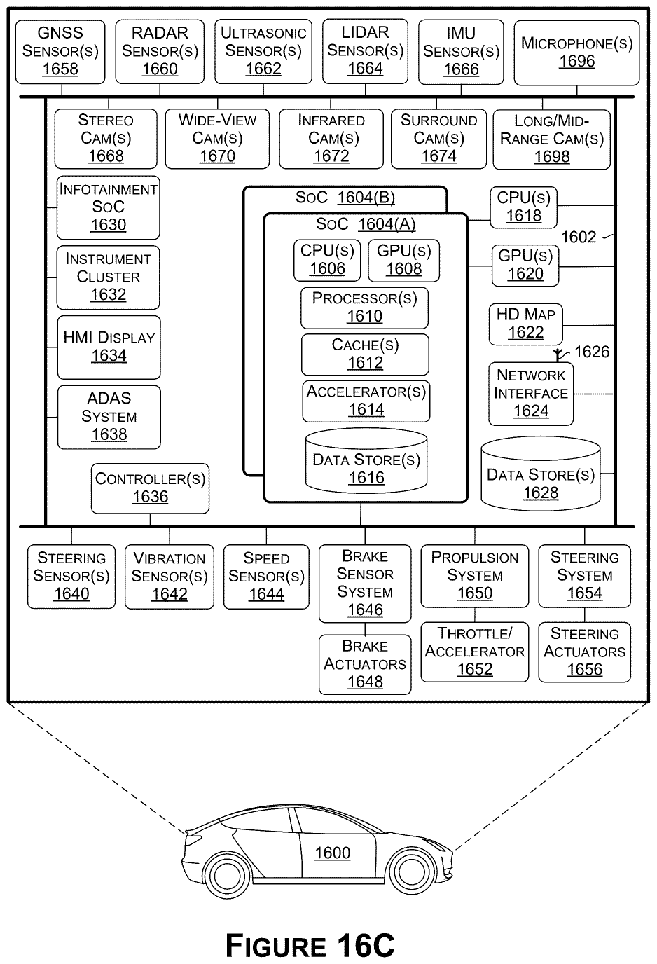

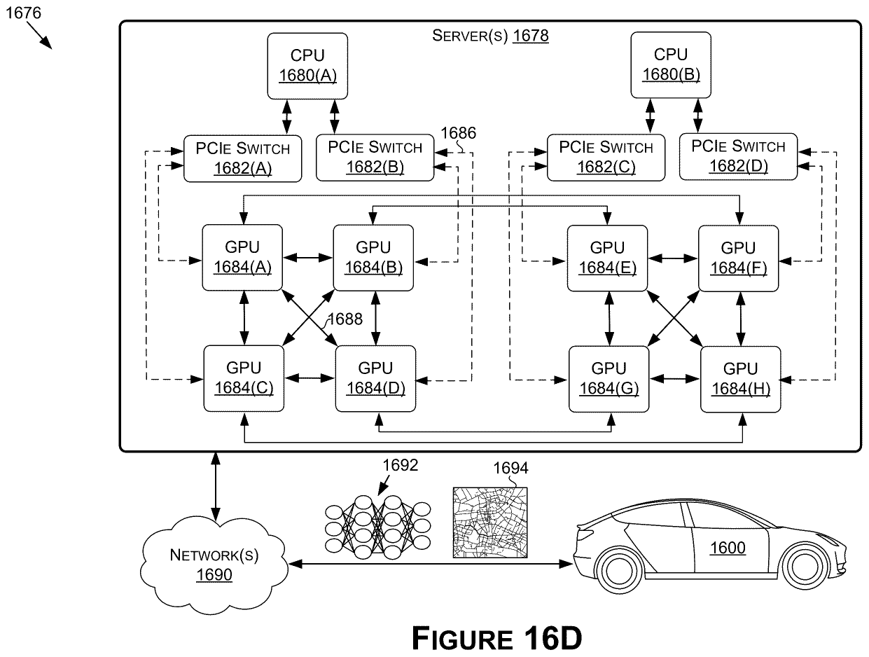

FIG. 16A is an illustration of an example autonomous vehicle 1600, in accordance with some embodiments of the present disclosure. The autonomous vehicle 1600 (alternatively referred to herein as the “vehicle 1600”) may include, without limitation, a passenger vehicle, such as a car, a truck, a bus, a first responder vehicle, a shuttle, an electric or motorized bicycle, a motorcycle, a fire truck, a police vehicle, an ambulance, a boat, a construction vehicle, an underwater craft, a robotic vehicle, a drone, an airplane, a vehicle coupled to a trailer (e.g., a semi-tractor-trailer truck used for hauling cargo), and/or another type of vehicle (e.g., that is unmanned and/or that accommodates one or more passengers). Autonomous vehicles are generally described in terms of automation levels, defined by the National Highway Traffic Safety Administration (NHTSA), a division of the US Department of Transportation, and the Society of Automotive Engineers (SAE) “Taxonomy and Definitions for Terms Related to Driving Automation Systems for On-Road Motor Vehicles” (Standard No. J3016-201806, published on Jun. 15, 2018, Standard No. J3016-201609, published on Sep. 30, 2016, and previous and future versions of this standard). The vehicle 1600 may be capable of functionality in accordance with one or more of Level 3-Level 5 of the autonomous driving levels. The vehicle 1600 may be capable of functionality in accordance with one or more of Level 1-Level 5 of the autonomous driving levels. For example, the vehicle 1600 may be capable of driver assistance (Level 1), partial automation (Level 2), conditional automation (Level 3), high automation (Level 4), and/or full automation (Level 5), depending on the embodiment. The term “autonomous,” as used herein, may include any and/or all types of autonomy for the vehicle 1600 or other machine, such as being fully autonomous, being highly autonomous, being conditionally autonomous, being partially autonomous, providing assistive autonomy, being semi-autonomous, being primarily autonomous, or other designation.

The vehicle 1600 may include components such as a chassis, a vehicle body, wheels (e.g., 2, 4, 6, 8, 18, etc.), tires, axles, and other components of a vehicle. The vehicle 1600 may include a propulsion system 1650, such as an internal combustion engine, hybrid electric power plant, an all-electric engine, and/or another propulsion system type. The propulsion system 1650 may be connected to a drive train of the vehicle 1600, which may include a transmission, to enable the propulsion of the vehicle 1600. The propulsion system 1650 may be controlled in response to receiving signals from the throttle/accelerator 1652.

A steering system 1654, which may include a steering wheel, may be used to steer the vehicle 1600 (e.g., along a desired path or route) when the propulsion system 1650 is operating (e.g., when the vehicle is in motion). The steering system 1654 may receive signals from a steering actuator 1656. The steering wheel may be optional for full automation (Level 5) functionality.

The brake sensor system 1646 may be used to operate the vehicle brakes in response to receiving signals from the brake actuators 1648 and/or brake sensors.

Controller(s) 1636, which may include one or more system on chips (SoCs) 1604 (FIG. 16C) and/or GPU(s), may provide signals (e.g., representative of commands) to one or more components and/or systems of the vehicle 1600. For example, the controller(s) may send signals to operate the vehicle brakes via one or more brake actuators 1648, to operate the steering system 1654 via one or more steering actuators 1656, to operate the propulsion system 1650 via one or more throttle/accelerators 1652. The controller(s) 1636 may include one or more onboard (e.g., integrated) computing devices (e.g., supercomputers) that process sensor signals, and output operation commands (e.g., signals representing commands) to enable autonomous driving and/or to assist a human driver in driving the vehicle 1600. The controller(s) 1636 may include a first controller 1636 for autonomous driving functions, a second controller 1636 for functional safety functions, a third controller 1636 for artificial intelligence functionality (e.g., computer vision), a fourth controller 1636 for infotainment functionality, a fifth controller 1636 for redundancy in emergency conditions, and/or other controllers. In some examples, a single controller 1636 may handle two or more of the above functionalities, two or more controllers 1636 may handle a single functionality, and/or any combination thereof.

The controller(s) 1636 may provide the signals for controlling one or more components and/or systems of the vehicle 1600 in response to sensor data received from one or more sensors (e.g., sensor inputs). The sensor data may be received from, for example and without limitation, global navigation satellite systems (“GNSS”) sensor(s) 1658 (e.g., Global Positioning System sensor(s)), RADAR sensor(s) 1660, ultrasonic sensor(s) 1662, LIDAR sensor(s) 1664, inertial measurement unit (IMU) sensor(s) 1666 (e.g., accelerometer(s), gyroscope(s), magnetic compass(es), magnetometer(s), etc.), microphone(s) 1696, stereo camera(s) 1668, wide-view camera(s) 1670 (e.g., fisheye cameras), infrared camera(s) 1672, surround camera(s) 1674 (e.g., 360 degree cameras), long-range and/or mid-range camera(s) 1698, speed sensor(s) 1644 (e.g., for measuring the speed of the vehicle 1600), vibration sensor(s) 1642, steering sensor(s) 1640, brake sensor(s) (e.g., as part of the brake sensor system 1646), and/or other sensor types.

One or more of the controller(s) 1636 may receive inputs (e.g., represented by input data) from an instrument cluster 1632 of the vehicle 1600 and provide outputs (e.g., represented by output data, display data, etc.) via a human-machine interface (HMI) display 1634, an audible annunciator, a loudspeaker, and/or via other components of the vehicle 1600. The outputs may include information such as vehicle velocity, speed, time, map data (e.g., the High Definition (“HD”) map 1622 of FIG. 16C), location data (e.g., the vehicle's 1600 location, such as on a map), direction, location of other vehicles (e.g., an occupancy grid), information about objects and status of objects as perceived by the controller(s) 1636, etc. For example, the HMI display 1634 may display information about the presence of one or more objects (e.g., a street sign, caution sign, traffic light changing, etc.), and/or information about driving maneuvers the vehicle has made, is making, or will make (e.g., changing lanes now, taking exit 34B in two miles, etc.).

The vehicle 1600 further includes a network interface 1624 which may use one or more wireless antenna(s) 1626 and/or modem(s) to communicate over one or more networks. For example, the network interface 1624 may be capable of communication over Long-Term Evolution (“LTE”), Wideband Code Division Multiple Access (“WCDMA”), Universal Mobile Telecommunications System (“UMTS”), Global System for Mobile communication (“GSM”), IMT-CDMA Multi-Carrier (“CDMA2000”), etc. The wireless antenna(s) 1626 may also enable communication between objects in the environment (e.g., vehicles, mobile devices, etc.), using local area network(s), such as Bluetooth, Bluetooth Low Energy (“LE”), Z-Wave, ZigBee, etc., and/or low power wide-area network(s) (“LPWANs”), such as LoRaWAN, SigFox, etc.

FIG. 16B is an example of camera locations and fields of view for the example autonomous vehicle 1600 of FIG. 16A, in accordance with some embodiments of the present disclosure. The cameras and respective fields of view are one example embodiment and are not intended to be limiting. For example, additional and/or alternative cameras may be included and/or the cameras may be located at different locations on the vehicle 1600.

The camera types for the cameras may include, but are not limited to, digital cameras that may be adapted for use with the components and/or systems of the vehicle 1600. The camera(s) may operate at automotive safety integrity level (ASIL) B and/or at another ASIL. The camera types may be capable of any image capture rate, such as 60 frames per second (fps), 120 fps, 240 fps, etc., depending on the embodiment. The cameras may be capable of using rolling shutters, global shutters, another type of shutter, or a combination thereof. In some examples, the color filter array may include a red clear clear clear (RCCC) color filter array, a red clear clear blue (RCCB) color filter array, a red blue green clear (RBGC) color filter array, a Foveon X3 color filter array, a Bayer sensors (RGGB) color filter array, a monochrome sensor color filter array, and/or another type of color filter array. In some embodiments, clear pixel cameras, such as cameras with an RCCC, an RCCB, and/or an RBGC color filter array, may be used in an effort to increase light sensitivity.

In some examples, one or more of the camera(s) may be used to perform advanced driver assistance systems (ADAS) functions (e.g., as part of a redundant or fail-safe design). For example, a Multi-Function Mono Camera may be installed to provide functions including lane departure warning, traffic sign assist and intelligent headlamp control. One or more of the camera(s) (e.g., all of the cameras) may record and provide image data (e.g., video) simultaneously.

One or more of the cameras may be mounted in a mounting assembly, such as a custom designed (three dimensional (“3D”) printed) assembly, in order to cut out stray light and reflections from within the car (e.g., reflections from the dashboard reflected in the windshield mirrors) which may interfere with the camera's image data capture abilities. With reference to wing-mirror mounting assemblies, the wing-mirror assemblies may be custom 3D printed so that the camera mounting plate matches the shape of the wing-mirror. In some examples, the camera(s) may be integrated into the wing-mirror. For side-view cameras, the camera(s) may also be integrated within the four pillars at each corner of the cabin.

Cameras with a field of view that include portions of the environment in front of the vehicle 1600 (e.g., front-facing cameras) may be used for surround view, to help identify forward facing paths and obstacles, as well aid in, with the help of one or more controllers 1636 and/or control SoCs, providing information critical to generating an occupancy grid and/or determining the preferred vehicle paths. Front-facing cameras may be used to perform many of the same ADAS functions as LIDAR, including emergency braking, pedestrian detection, and collision avoidance. Front-facing cameras may also be used for ADAS functions and systems including Lane Departure Warnings (“LDW”), Autonomous Cruise Control (“ACC”), and/or other functions such as traffic sign recognition.

A variety of cameras may be used in a front-facing configuration, including, for example, a monocular camera platform that includes a complementary metal oxide semiconductor (“CMOS”) color imager. Another example may be a wide-view camera(s) 1670 that may be used to perceive objects coming into view from the periphery (e.g., pedestrians, crossing traffic or bicycles). Although only one wide-view camera is illustrated in FIG. 16B, there may be any number (including zero) of wide-view cameras 1670 on the vehicle 1600. In addition, any number of long-range camera(s) 1698 (e.g., a long-view stereo camera pair) may be used for depth-based object detection, especially for objects for which a neural network has not yet been trained. The long-range camera(s) 1698 may also be used for object detection and classification, as well as basic object tracking.

Any number of stereo cameras 1668 may also be included in a front-facing configuration. In at least one embodiment, one or more of stereo camera(s) 1668 may include an integrated control unit comprising a scalable processing unit, which may provide a programmable logic (“FPGA”) and a multi-core micro-processor with an integrated Controller Area Network (“CAN”) or Ethernet interface on a single chip. Such a unit may be used to generate a 3D map of the vehicle's environment, including a distance estimate for all the points in the image. An alternative stereo camera(s) 1668 may include a compact stereo vision sensor(s) that may include two camera lenses (one each on the left and right) and an image processing chip that may measure the distance from the vehicle to the target object and use the generated information (e.g., metadata) to activate the autonomous emergency braking and lane departure warning functions. Other types of stereo camera(s) 1668 may be used in addition to, or alternatively from, those described herein.

Cameras with a field of view that include portions of the environment to the side of the vehicle 1600 (e.g., side-view cameras) may be used for surround view, providing information used to create and update the occupancy grid, as well as to generate side impact collision warnings. For example, surround camera(s) 1674 (e.g., four surround cameras 1674 as illustrated in FIG. 16B) may be positioned to on the vehicle 1600. The surround camera(s) 1674 may include wide-view camera(s) 1670, fisheye camera(s), 360 degree camera(s), and/or the like. Four example, four fisheye cameras may be positioned on the vehicle's front, rear, and sides. In an alternative arrangement, the vehicle may use three surround camera(s) 1674 (e.g., left, right, and rear), and may leverage one or more other camera(s) (e.g., a forward-facing camera) as a fourth surround view camera.

Cameras with a field of view that include portions of the environment to the rear of the vehicle 1600 (e.g., rear-view cameras) may be used for park assistance, surround view, rear collision warnings, and creating and updating the occupancy grid. A wide variety of cameras may be used including, but not limited to, cameras that are also suitable as a front-facing camera(s) (e.g., long-range and/or mid-range camera(s) 1698, stereo camera(s) 1668), infrared camera(s) 1672, etc.), as described herein.

FIG. 16C is a block diagram of an example system architecture for the example autonomous vehicle 1600 of FIG. 16A, in accordance with some embodiments of the present disclosure. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory.

Each of the components, features, and systems of the vehicle 1600 in FIG. 16C are illustrated as being connected via bus 1602. The bus 1602 may include a Controller Area Network (CAN) data interface (alternatively referred to herein as a “CAN bus”). A CAN may be a network inside the vehicle 1600 used to aid in control of various features and functionality of the vehicle 1600, such as actuation of brakes, acceleration, braking, steering, windshield wipers, etc. A CAN bus may be configured to have dozens or even hundreds of nodes, each with its own unique identifier (e.g., a CAN ID). The CAN bus may be read to find steering wheel angle, ground speed, engine revolutions per minute (RPMs), button positions, and/or other vehicle status indicators. The CAN bus may be ASIL B compliant.

Although the bus 1602 is described herein as being a CAN bus, this is not intended to be limiting. For example, in addition to, or alternatively from, the CAN bus, FlexRay and/or Ethernet may be used. Additionally, although a single line is used to represent the bus 1602, this is not intended to be limiting. For example, there may be any number of busses 1602, which may include one or more CAN busses, one or more FlexRay busses, one or more Ethernet busses, and/or one or more other types of busses using a different protocol. In some examples, two or more busses 1602 may be used to perform different functions, and/or may be used for redundancy. For example, a first bus 1602 may be used for collision avoidance functionality and a second bus 1602 may be used for actuation control. In any example, each bus 1602 may communicate with any of the components of the vehicle 1600, and two or more busses 1602 may communicate with the same components. In some examples, each SoC 1604, each controller 1636, and/or each computer within the vehicle may have access to the same input data (e.g., inputs from sensors of the vehicle 1600), and may be connected to a common bus, such the CAN bus.

The vehicle 1600 may include one or more controller(s) 1636, such as those described herein with respect to FIG. 16A. The controller(s) 1636 may be used for a variety of functions. The controller(s) 1636 may be coupled to any of the various other components and systems of the vehicle 1600, and may be used for control of the vehicle 1600, artificial intelligence of the vehicle 1600, infotainment for the vehicle 1600, and/or the like.

The vehicle 1600 may include a system(s) on a chip (SoC) 1604. The SoC 1604 may include CPU(s) 1606, GPU(s) 1608, processor(s) 1610, cache(s) 1612, accelerator(s) 1614, data store(s) 1616, and/or other components and features not illustrated. The SoC(s) 1604 may be used to control the vehicle 1600 in a variety of platforms and systems. For example, the SoC(s) 1604 may be combined in a system (e.g., the system of the vehicle 1600) with an HD map 1622 which may obtain map refreshes and/or updates via a network interface 1624 from one or more servers (e.g., server(s) 1678 of FIG. 16D).

The CPU(s) 1606 may include a CPU cluster or CPU complex (alternatively referred to herein as a “CCPLEX”). The CPU(s) 1606 may include multiple cores and/or L2 caches. For example, in some embodiments, the CPU(s) 1606 may include eight cores in a coherent multi-processor configuration. In some embodiments, the CPU(s) 1606 may include four dual-core clusters where each cluster has a dedicated L2 cache (e.g., a 2 MB L2 cache). The CPU(s) 1606 (e.g., the CCPLEX) may be configured to support simultaneous cluster operation enabling any combination of the clusters of the CPU(s) 1606 to be active at any given time.

The CPU(s) 1606 may implement power management capabilities that include one or more of the following features: individual hardware blocks may be clock-gated automatically when idle to save dynamic power; each core clock may be gated when the core is not actively executing instructions due to execution of WFI/WFE instructions; each core may be independently power-gated; each core cluster may be independently clock-gated when all cores are clock-gated or power-gated; and/or each core cluster may be independently power-gated when all cores are power-gated. The CPU(s) 1606 may further implement an enhanced algorithm for managing power states, where allowed power states and expected wakeup times are specified, and the hardware/microcode determines the best power state to enter for the core, cluster, and CCPLEX. The processing cores may support simplified power state entry sequences in software with the work offloaded to microcode.

The GPU(s) 1608 may include an integrated GPU (alternatively referred to herein as an “iGPU”). The GPU(s) 1608 may be programmable and may be efficient for parallel workloads. The GPU(s) 1608, in some examples, may use an enhanced tensor instruction set. The GPU(s) 1608 may include one or more streaming microprocessors, where each streaming microprocessor may include an L1 cache (e.g., an L1 cache with at least 96 KB storage capacity), and two or more of the streaming microprocessors may share an L2 cache (e.g., an L2 cache with a 512 KB storage capacity). In some embodiments, the GPU(s) 1608 may include at least eight streaming microprocessors. The GPU(s) 1608 may use compute application programming interface(s) (API(s)). In addition, the GPU(s) 1608 may use one or more parallel computing platforms and/or programming models (e.g., NVIDIA's CUDA).

The GPU(s) 1608 may be power-optimized for best performance in automotive and embedded use cases. For example, the GPU(s) 1608 may be fabricated on a Fin field-effect transistor (FinFET). However, this is not intended to be limiting and the GPU(s) 1608 may be fabricated using other semiconductor manufacturing processes. Each streaming microprocessor may incorporate a number of mixed-precision processing cores partitioned into multiple blocks. For example, and without limitation, 64 PF32 cores and 32 PF64 cores may be partitioned into four processing blocks. In such an example, each processing block may be allocated 16 FP32 cores, 8 FP64 cores, 16 INT32 cores, two mixed-precision NVIDIA TENSOR COREs for deep learning matrix arithmetic, an L0 instruction cache, a warp scheduler, a dispatch unit, and/or a 64 KB register file. In addition, the streaming microprocessors may include independent parallel integer and floating-point data paths to provide for efficient execution of workloads with a mix of computation and addressing calculations. The streaming microprocessors may include independent thread scheduling capability to enable finer-grain synchronization and cooperation between parallel threads. The streaming microprocessors may include a combined L1 data cache and shared memory unit in order to improve performance while simplifying programming.

The GPU(s) 1608 may include a high bandwidth memory (HBM) and/or a 16 GB HBM2 memory subsystem to provide, in some examples, about 900 GB/second peak memory bandwidth. In some examples, in addition to, or alternatively from, the HBM memory, a synchronous graphics random-access memory (SGRAM) may be used, such as a graphics double data rate type five synchronous random-access memory (GDDR5).

The GPU(s) 1608 may include unified memory technology including access counters to allow for more accurate migration of memory pages to the processor that accesses them most frequently, thereby improving efficiency for memory ranges shared between processors. In some examples, address translation services (ATS) support may be used to allow the GPU(s) 1608 to access the CPU(s) 1606 page tables directly. In such examples, when the GPU(s) 1608 memory management unit (MMU) experiences a miss, an address translation request may be transmitted to the CPU(s) 1606. In response, the CPU(s) 1606 may look in its page tables for the virtual-to-physical mapping for the address and transmits the translation back to the GPU(s) 1608. As such, unified memory technology may allow a single unified virtual address space for memory of both the CPU(s) 1606 and the GPU(s) 1608, thereby simplifying the GPU(s) 1608 programming and porting of applications to the GPU(s) 1608.

In addition, the GPU(s) 1608 may include an access counter that may keep track of the frequency of access of the GPU(s) 1608 to memory of other processors. The access counter may help ensure that memory pages are moved to the physical memory of the processor that is accessing the pages most frequently.

The SoC(s) 1604 may include any number of cache(s) 1612, including those described herein. For example, the cache(s) 1612 may include an L3 cache that is available to both the CPU(s) 1606 and the GPU(s) 1608 (e.g., that is connected both the CPU(s) 1606 and the GPU(s) 1608). The cache(s) 1612 may include a write-back cache that may keep track of states of lines, such as by using a cache coherence protocol (e.g., MEI, MESI, MSI, etc.). The L3 cache may include 4 MB or more, depending on the embodiment, although smaller cache sizes may be used.

The SoC(s) 1604 may include an arithmetic logic unit(s) (ALU(s)) which may be leveraged in performing processing with respect to any of the variety of tasks or operations of the vehicle 1600—such as processing DNNs. In addition, the SoC(s) 1604 may include a floating point unit(s) (FPU(s))—or other math coprocessor or numeric coprocessor types—for performing mathematical operations within the system. For example, the SoC(s) 1604 may include one or more FPUs integrated as execution units within a CPU(s) 1606 and/or GPU(s) 1608.

The SoC(s) 1604 may include one or more accelerators 1614 (e.g., hardware accelerators, software accelerators, or a combination thereof). For example, the SoC(s) 1604 may include a hardware acceleration cluster that may include optimized hardware accelerators and/or large on-chip memory. The large on-chip memory (e.g., 4 MB of SRAM), may enable the hardware acceleration cluster to accelerate neural networks and other calculations. The hardware acceleration cluster may be used to complement the GPU(s) 1608 and to off-load some of the tasks of the GPU(s) 1608 (e.g., to free up more cycles of the GPU(s) 1608 for performing other tasks). As an example, the accelerator(s) 1614 may be used for targeted workloads (e.g., perception, convolutional neural networks (CNNs), etc.) that are stable enough to be amenable to acceleration. The term “CNN,” as used herein, may include all types of CNNs, including region-based or regional convolutional neural networks (RCNNs) and Fast RCNNs (e.g., as used for object detection).

The accelerator(s) 1614 (e.g., the hardware acceleration cluster) may include a deep learning accelerator(s) (DLA). The DLA(s) may include one or more Tensor processing units (TPUs) that may be configured to provide an additional ten trillion operations per second for deep learning applications and inferencing. The TPUs may be accelerators configured to, and optimized for, performing image processing functions (e.g., for CNNs, RCNNs, etc.). The DLA(s) may further be optimized for a specific set of neural network types and floating point operations, as well as inferencing. The design of the DLA(s) may provide more performance per millimeter than a general-purpose GPU, and vastly exceeds the performance of a CPU. The TPU(s) may perform several functions, including a single-instance convolution function, supporting, for example, INT8, INT16, and FP16 data types for both features and weights, as well as post-processor functions.

The DLA(s) may quickly and efficiently execute neural networks, especially CNNs, on processed or unprocessed data for any of a variety of functions, including, for example and without limitation: a CNN for object identification and detection using data from camera sensors; a CNN for distance estimation using data from camera sensors; a CNN for emergency vehicle detection and identification and detection using data from microphones; a CNN for facial recognition and vehicle owner identification using data from camera sensors; and/or a CNN for security and/or safety related events.

The DLA(s) may perform any function of the GPU(s) 1608, and by using an inference accelerator, for example, a designer may target either the DLA(s) or the GPU(s) 1608 for any function. For example, the designer may focus processing of CNNs and floating point operations on the DLA(s) and leave other functions to the GPU(s) 1608 and/or other accelerator(s) 1614.

The accelerator(s) 1614 (e.g., the hardware acceleration cluster) may include a programmable vision accelerator(s) (PVA), which may alternatively be referred to herein as a computer vision accelerator. The PVA(s) may be designed and configured to accelerate computer vision algorithms for the advanced driver assistance systems (ADAS), autonomous driving, and/or augmented reality (AR) and/or virtual reality (VR) applications. The PVA(s) may provide a balance between performance and flexibility. For example, each PVA(s) may include, for example and without limitation, any number of reduced instruction set computer (RISC) cores, direct memory access (DMA), and/or any number of vector processors.

The RISC cores may interact with image sensors (e.g., the image sensors of any of the cameras described herein), image signal processor(s), and/or the like. Each of the RISC cores may include any amount of memory. The RISC cores may use any of a number of protocols, depending on the embodiment. In some examples, the RISC cores may execute a real-time operating system (RTOS). The RISC cores may be implemented using one or more integrated circuit devices, application specific integrated circuits (ASICs), and/or memory devices. For example, the RISC cores may include an instruction cache and/or a tightly coupled RAM.

The DMA may enable components of the PVA(s) to access the system memory independently of the CPU(s) 1606. The DMA may support any number of features used to provide optimization to the PVA including, but not limited to, supporting multi-dimensional addressing and/or circular addressing. In some examples, the DMA may support up to six or more dimensions of addressing, which may include block width, block height, block depth, horizontal block stepping, vertical block stepping, and/or depth stepping.

The vector processors may be programmable processors that may be designed to efficiently and flexibly execute programming for computer vision algorithms and provide signal processing capabilities. In some examples, the PVA may include a PVA core and two vector processing subsystem partitions. The PVA core may include a processor subsystem, DMA engine(s) (e.g., two DMA engines), and/or other peripherals. The vector processing subsystem may operate as the primary processing engine of the PVA, and may include a vector processing unit (VPU), an instruction cache, and/or vector memory (e.g., VMEM). A VPU core may include a digital signal processor such as, for example, a single instruction, multiple data (SIMD), very long instruction word (VLIW) digital signal processor. The combination of the SIMD and VLIW may enhance throughput and speed.

Each of the vector processors may include an instruction cache and may be coupled to dedicated memory. As a result, in some examples, each of the vector processors may be configured to execute independently of the other vector processors. In other examples, the vector processors that are included in a particular PVA may be configured to employ data parallelism. For example, in some embodiments, the plurality of vector processors included in a single PVA may execute the same computer vision algorithm, but on different regions of an image. In other examples, the vector processors included in a particular PVA may simultaneously execute different computer vision algorithms, on the same image, or even execute different algorithms on sequential images or portions of an image. Among other things, any number of PVAs may be included in the hardware acceleration cluster and any number of vector processors may be included in each of the PVAs. In addition, the PVA(s) may include additional error correcting code (ECC) memory, to enhance overall system safety.

The accelerator(s) 1614 (e.g., the hardware acceleration cluster) may include a computer vision network on-chip and SRAM, for providing a high-bandwidth, low latency SRAM for the accelerator(s) 1614. In some examples, the on-chip memory may include at least 4 MB SRAM, consisting of, for example and without limitation, eight field-configurable memory blocks, that may be accessible by both the PVA and the DLA. Each pair of memory blocks may include an advanced peripheral bus (APB) interface, configuration circuitry, a controller, and a multiplexer. Any type of memory may be used. The PVA and DLA may access the memory via a backbone that provides the PVA and DLA with high-speed access to memory. The backbone may include a computer vision network on-chip that interconnects the PVA and the DLA to the memory (e.g., using the APB).

The computer vision network on-chip may include an interface that determines, before transmission of any control signal/address/data, that both the PVA and the DLA provide ready and valid signals. Such an interface may provide for separate phases and separate channels for transmitting control signals/addresses/data, as well as burst-type communications for continuous data transfer. This type of interface may comply with ISO 26262 or IEC 61508 standards, although other standards and protocols may be used.

In some examples, the SoC(s) 1604 may include a real-time ray-tracing hardware accelerator, such as described in U.S. patent application Ser. No. 16/101,232, filed on Aug. 10, 2018. The real-time ray-tracing hardware accelerator may be used to quickly and efficiently determine the positions and extents of objects (e.g., within a world model), to generate real-time visualization simulations, for RADAR signal interpretation, for sound propagation synthesis and/or analysis, for simulation of SONAR systems, for general wave propagation simulation, for comparison to LIDAR data for purposes of localization and/or other functions, and/or for other uses. In some embodiments, one or more tree traversal units (TTUs) may be used for executing one or more ray-tracing related operations.

The accelerator(s) 1614 (e.g., the hardware accelerator cluster) have a wide array of uses for autonomous driving. The PVA may be a programmable vision accelerator that may be used for key processing stages in ADAS and autonomous vehicles. The PVA's capabilities are a good match for algorithmic domains needing predictable processing, at low power and low latency. In other words, the PVA performs well on semi-dense or dense regular computation, even on small data sets, which need predictable run-times with low latency and low power. Thus, in the context of platforms for autonomous vehicles, the PVAs are designed to run classic computer vision algorithms, as they are efficient at object detection and operating on integer math.

For example, according to one embodiment of the technology, the PVA is used to perform computer stereo vision. A semi-global matching-based algorithm may be used in some examples, although this is not intended to be limiting. Many applications for Level 3-5 autonomous driving require motion estimation/stereo matching on-the-fly (e.g., structure from motion, pedestrian recognition, lane detection, etc.). The PVA may perform computer stereo vision function on inputs from two monocular cameras.

In some examples, the PVA may be used to perform dense optical flow. According to process raw RADAR data (e.g., using a 4D Fast Fourier Transform) to provide Processed RADAR. In other examples, the PVA is used for time of flight depth processing, by processing raw time of flight data to provide processed time of flight data, for example.

The DLA may be used to run any type of network to enhance control and driving safety, including for example, a neural network that outputs a measure of confidence for each object detection. Such a confidence value may be interpreted as a probability, or as providing a relative “weight” of each detection compared to other detections. This confidence value enables the system to make further decisions regarding which detections should be considered as true positive detections rather than false positive detections. For example, the system may set a threshold value for the confidence and consider only the detections exceeding the threshold value as true positive detections. In an automatic emergency braking (AEB) system, false positive detections would cause the vehicle to automatically perform emergency braking, which is obviously undesirable. Therefore, only the most confident detections should be considered as triggers for AEB. The DLA may run a neural network for regressing the confidence value. The neural network may take as its input at least some subset of parameters, such as bounding box dimensions, ground plane estimate obtained (e.g. from another subsystem), inertial measurement unit (IMU) sensor 1666 output that correlates with the vehicle 1600 orientation, distance, 3D location estimates of the object obtained from the neural network and/or other sensors (e.g., LIDAR sensor(s) 1664 or RADAR sensor(s) 1660), among others.

The SoC(s) 1604 may include data store(s) 1616 (e.g., memory). The data store(s) 1616 may be on-chip memory of the SoC(s) 1604, which may store neural networks to be executed on the GPU and/or the DLA. In some examples, the data store(s) 1616 may be large enough in capacity to store multiple instances of neural networks for redundancy and safety. The data store(s) 1612 may comprise L2 or L3 cache(s) 1612. Reference to the data store(s) 1616 may include reference to the memory associated with the PVA, DLA, and/or other accelerator(s) 1614, as described herein.

The SoC(s) 1604 may include one or more processor(s) 1610 (e.g., embedded processors). The processor(s) 1610 may include a boot and power management processor that may be a dedicated processor and subsystem to handle boot power and management functions and related security enforcement. The boot and power management processor may be a part of the SoC(s) 1604 boot sequence and may provide runtime power management services. The boot power and management processor may provide clock and voltage programming, assistance in system low power state transitions, management of SoC(s) 1604 thermals and temperature sensors, and/or management of the SoC(s) 1604 power states. Each temperature sensor may be implemented as a ring-oscillator whose output frequency is proportional to temperature, and the SoC(s) 1604 may use the ring-oscillators to detect temperatures of the CPU(s) 1606, GPU(s) 1608, and/or accelerator(s) 1614. If temperatures are determined to exceed a threshold, the boot and power management processor may enter a temperature fault routine and put the SoC(s) 1604 into a lower power state and/or put the vehicle 1600 into a chauffeur to safe stop mode (e.g., bring the vehicle 1600 to a safe stop).

The processor(s) 1610 may further include a set of embedded processors that may serve as an audio processing engine. The audio processing engine may be an audio subsystem that enables full hardware support for multi-channel audio over multiple interfaces, and a broad and flexible range of audio I/O interfaces. In some examples, the audio processing engine is a dedicated processor core with a digital signal processor with dedicated RAM.

The processor(s) 1610 may further include an always on processor engine that may provide necessary hardware features to support low power sensor management and wake use cases. The always on processor engine may include a processor core, a tightly coupled RAM, supporting peripherals (e.g., timers and interrupt controllers), various I/O controller peripherals, and routing logic.

The processor(s) 1610 may further include a safety cluster engine that includes a dedicated processor subsystem to handle safety management for automotive applications. The safety cluster engine may include two or more processor cores, a tightly coupled RAM, support peripherals (e.g., timers, an interrupt controller, etc.), and/or routing logic. In a safety mode, the two or more cores may operate in a lockstep mode and function as a single core with comparison logic to detect any differences between their operations.

The processor(s) 1610 may further include a real-time camera engine that may include a dedicated processor subsystem for handling real-time camera management.

The processor(s) 1610 may further include a high-dynamic range signal processor that may include an image signal processor that is a hardware engine that is part of the camera processing pipeline.

The processor(s) 1610 may include a video image compositor that may be a processing block (e.g., implemented on a microprocessor) that implements video post-processing functions needed by a video playback application to produce the final image for the player window. The video image compositor may perform lens distortion correction on wide-view camera(s) 1670, surround camera(s) 1674, and/or on in-cabin monitoring camera sensors. In-cabin monitoring camera sensor is preferably monitored by a neural network running on another instance of the Advanced SoC, configured to identify in cabin events and respond accordingly. An in-cabin system may perform lip reading to activate cellular service and place a phone call, dictate emails, change the vehicle's destination, activate or change the vehicle's infotainment system and settings, or provide voice-activated web surfing. Certain functions are available to the driver only when the vehicle is operating in an autonomous mode, and are disabled otherwise.

The video image compositor may include enhanced temporal noise reduction for both spatial and temporal noise reduction. For example, where motion occurs in a video, the noise reduction weights spatial information appropriately, decreasing the weight of information provided by adjacent frames. Where an image or portion of an image does not include motion, the temporal noise reduction performed by the video image compositor may use information from the previous image to reduce noise in the current image.

The video image compositor may also be configured to perform stereo rectification on input stereo lens frames. The video image compositor may further be used for user interface composition when the operating system desktop is in use, and the GPU(s) 1608 is not required to continuously render new surfaces. Even when the GPU(s) 1608 is powered on and active doing 3D rendering, the video image compositor may be used to offload the GPU(s) 1608 to improve performance and responsiveness.

The SoC(s) 1604 may further include a mobile industry processor interface (MIPI) camera serial interface for receiving video and input from cameras, a high-speed interface, and/or a video input block that may be used for camera and related pixel input functions. The SoC(s) 1604 may further include an input/output controller(s) that may be controlled by software and may be used for receiving I/O signals that are uncommitted to a specific role.

The SoC(s) 1604 may further include a broad range of peripheral interfaces to enable communication with peripherals, audio codecs, power management, and/or other devices. The SoC(s) 1604 may be used to process data from cameras (e.g., connected over Gigabit Multimedia Serial Link and Ethernet), sensors (e.g., LIDAR sensor(s) 1664, RADAR sensor(s) 1660, etc. that may be connected over Ethernet), data from bus 1602 (e.g., speed of vehicle 1600, steering wheel position, etc.), data from GNSS sensor(s) 1658 (e.g., connected over Ethernet or CAN bus). The SoC(s) 1604 may further include dedicated high-performance mass storage controllers that may include their own DMA engines, and that may be used to free the CPU(s) 1606 from routine data management tasks.

The SoC(s) 1604 may be an end-to-end platform with a flexible architecture that spans automation levels 3-5, thereby providing a comprehensive functional safety architecture that leverages and makes efficient use of computer vision and ADAS techniques for diversity and redundancy, provides a platform for a flexible, reliable driving software stack, along with deep learning tools. The SoC(s) 1604 may be faster, more reliable, and even more energy-efficient and space-efficient than conventional systems. For example, the accelerator(s) 1614, when combined with the CPU(s) 1606, the GPU(s) 1608, and the data store(s) 1616, may provide for a fast, efficient platform for level 3-5 autonomous vehicles.

The technology thus provides capabilities and functionality that cannot be achieved by conventional systems. For example, computer vision algorithms may be executed on CPUs, which may be configured using high-level programming language, such as the C programming language, to execute a wide variety of processing algorithms across a wide variety of visual data. However, CPUs are oftentimes unable to meet the performance requirements of many computer vision applications, such as those related to execution time and power consumption, for example. In particular, many CPUs are unable to execute complex object detection algorithms in real-time, which is a requirement of in-vehicle ADAS applications, and a requirement for practical Level 3-5 autonomous vehicles.

In contrast to conventional systems, by providing a CPU complex, GPU complex, and a hardware acceleration cluster, the technology described herein allows for multiple neural networks to be performed simultaneously and/or sequentially, and for the results to be combined together to enable Level 3-5 autonomous driving functionality. For example, a CNN executing on the DLA or dGPU (e.g., the GPU(s) 1620) may include a text and word recognition, allowing the supercomputer to read and understand traffic signs, including signs for which the neural network has not been specifically trained. The DLA may further include a neural network that is able to identify, interpret, and provides semantic understanding of the sign, and to pass that semantic understanding to the path planning modules running on the CPU Complex.

As another example, multiple neural networks may be run simultaneously, as is required for Level 3, 4, or 5 driving. For example, a warning sign consisting of “Caution: flashing lights indicate icy conditions,” along with an electric light, may be independently or collectively interpreted by several neural networks. The sign itself may be identified as a traffic sign by a first deployed neural network (e.g., a neural network that has been trained), the text “Flashing lights indicate icy conditions” may be interpreted by a second deployed neural network, which informs the vehicle's path planning software (preferably executing on the CPU Complex) that when flashing lights are detected, icy conditions exist. The flashing light may be identified by operating a third deployed neural network over multiple frames, informing the vehicle's path-planning software of the presence (or absence) of flashing lights. All three neural networks may run simultaneously, such as within the DLA and/or on the GPU(s) 1608.

In some examples, a CNN for facial recognition and vehicle owner identification may use data from camera sensors to identify the presence of an authorized driver and/or owner of the vehicle 1600. The always on sensor processing engine may be used to unlock the vehicle when the owner approaches the driver door and turn on the lights, and, in security mode, to disable the vehicle when the owner leaves the vehicle. In this way, the SoC(s) 1604 provide for security against theft and/or carjacking.

In another example, a CNN for emergency vehicle detection and identification may use data from microphones 1696 to detect and identify emergency vehicle sirens. In contrast to conventional systems, that use general classifiers to detect sirens and manually extract features, the SoC(s) 1604 use the CNN for classifying environmental and urban sounds, as well as classifying visual data. In a preferred embodiment, the CNN running on the DLA is trained to identify the relative closing speed of the emergency vehicle (e.g., by using the Doppler Effect). The CNN may also be trained to identify emergency vehicles specific to the local area in which the vehicle is operating, as identified by GNSS sensor(s) 1658. Thus, for example, when operating in Europe the CNN will seek to detect European sirens, and when in the United States the CNN will seek to identify only North American sirens. Once an emergency vehicle is detected, a control program may be used to execute an emergency vehicle safety routine, slowing the vehicle, pulling over to the side of the road, parking the vehicle, and/or idling the vehicle, with the assistance of ultrasonic sensors 1662, until the emergency vehicle(s) passes.

The vehicle may include a CPU(s) 1618 (e.g., discrete CPU(s), or dCPU(s)), that may be coupled to the SoC(s) 1604 via a high-speed interconnect (e.g., PCIe). The CPU(s) 1618 may include an X86 processor, for example. The CPU(s) 1618 may be used to perform any of a variety of functions, including arbitrating potentially inconsistent results between ADAS sensors and the SoC(s) 1604, and/or monitoring the status and health of the controller(s) 1636 and/or infotainment SoC 1630, for example.

The vehicle 1600 may include a GPU(s) 1620 (e.g., discrete GPU(s), or dGPU(s)), that may be coupled to the SoC(s) 1604 via a high-speed interconnect (e.g., NVIDIA's NVLINK). The GPU(s) 1620 may provide additional artificial intelligence functionality, such as by executing redundant and/or different neural networks, and may be used to train and/or update neural networks based on input (e.g., sensor data) from sensors of the vehicle 1600.

The vehicle 1600 may further include the network interface 1624 which may include one or more wireless antennas 1626 (e.g., one or more wireless antennas for different communication protocols, such as a cellular antenna, a Bluetooth antenna, etc.). The network interface 1624 may be used to enable wireless connectivity over the Internet with the cloud (e.g., with the server(s) 1678 and/or other network devices), with other vehicles, and/or with computing devices (e.g., client devices of passengers). To communicate with other vehicles, a direct link may be established between the two vehicles and/or an indirect link may be established (e.g., across networks and over the Internet). Direct links may be provided using a vehicle-to-vehicle communication link. The vehicle-to-vehicle communication link may provide the vehicle 1600 information about vehicles in proximity to the vehicle 1600 (e.g., vehicles in front of, on the side of, and/or behind the vehicle 1600). This functionality may be part of a cooperative adaptive cruise control functionality of the vehicle 1600.

The network interface 1624 may include a SoC that provides modulation and demodulation functionality and enables the controller(s) 1636 to communicate over wireless networks. The network interface 1624 may include a radio frequency front-end for up-conversion from baseband to radio frequency, and down conversion from radio frequency to baseband. The frequency conversions may be performed through well-known processes, and/or may be performed using super-heterodyne processes. In some examples, the radio frequency front end functionality may be provided by a separate chip. The network interface may include wireless functionality for communicating over LTE, WCDMA, UMTS, GSM, CDMA2000, Bluetooth, Bluetooth LE, Wi-Fi, Z-Wave, ZigBee, LoRaWAN, and/or other wireless protocols.

The vehicle 1600 may further include data store(s) 1628 which may include off-chip (e.g., off the SoC(s) 1604) storage. The data store(s) 1628 may include one or more storage elements including RAM, SRAM, DRAM, VRAM, Flash, hard disks, and/or other components and/or devices that may store at least one bit of data.

The vehicle 1600 may further include GNSS sensor(s) 1658. The GNSS sensor(s) 1658 (e.g., GPS, assisted GPS sensors, differential GPS (DGPS) sensors, etc.), to assist in mapping, perception, occupancy grid generation, and/or path planning functions. Any number of GNSS sensor(s) 1658 may be used, including, for example and without limitation, a GPS using a USB connector with an Ethernet to Serial (RS-232) bridge.

The vehicle 1600 may further include RADAR sensor(s) 1660. The RADAR sensor(s) 1660 may be used by the vehicle 1600 for long-range vehicle detection, even in darkness and/or severe weather conditions. RADAR functional safety levels may be ASIL B. The RADAR sensor(s) 1660 may use the CAN and/or the bus 1602 (e.g., to transmit data generated by the RADAR sensor(s) 1660) for control and to access object tracking data, with access to Ethernet to access raw data in some examples. A wide variety of RADAR sensor types may be used. For example, and without limitation, the RADAR sensor(s) 1660 may be suitable for front, rear, and side RADAR use. In some example, Pulse Doppler RADAR sensor(s) are used.

The RADAR sensor(s) 1660 may include different configurations, such as long range with narrow field of view, short range with wide field of view, short range side coverage, etc. In some examples, long-range RADAR may be used for adaptive cruise control functionality. The long-range RADAR systems may provide a broad field of view realized by two or more independent scans, such as within a 250 m range. The RADAR sensor(s) 1660 may help in distinguishing between static and moving objects, and may be used by ADAS systems for emergency brake assist and forward collision warning. Long-range RADAR sensors may include monostatic multimodal RADAR with multiple (e.g., six or more) fixed RADAR antennae and a high-speed CAN and FlexRay interface. In an example with six antennae, the central four antennae may create a focused beam pattern, designed to record the vehicle's 1600 surroundings at higher speeds with minimal interference from traffic in adjacent lanes. The other two antennae may expand the field of view, making it possible to quickly detect vehicles entering or leaving the vehicle's 1600 lane.

Mid-range RADAR systems may include, as an example, a range of up to 1660 m (front) or 80 m (rear), and a field of view of up to 42 degrees (front) or 1650 degrees (rear). Short-range RADAR systems may include, without limitation, RADAR sensors designed to be installed at both ends of the rear bumper. When installed at both ends of the rear bumper, such a RADAR sensor systems may create two beams that constantly monitor the blind spot in the rear and next to the vehicle.

Short-range RADAR systems may be used in an ADAS system for blind spot detection and/or lane change assist.

The vehicle 1600 may further include ultrasonic sensor(s) 1662. The ultrasonic sensor(s) 1662, which may be positioned at the front, back, and/or the sides of the vehicle 1600, may be used for park assist and/or to create and update an occupancy grid. A wide variety of ultrasonic sensor(s) 1662 may be used, and different ultrasonic sensor(s) 1662 may be used for different ranges of detection (e.g., 2.5 m, 4 m). The ultrasonic sensor(s) 1662 may operate at functional safety levels of ASIL B.

The vehicle 1600 may include LIDAR sensor(s) 1664. The LIDAR sensor(s) 1664 may be used for object and pedestrian detection, emergency braking, collision avoidance, and/or other functions. The LIDAR sensor(s) 1664 may be functional safety level ASIL B. In some examples, the vehicle 1600 may include multiple LIDAR sensors 1664 (e.g., two, four, six, etc.) that may use Ethernet (e.g., to provide data to a Gigabit Ethernet switch).

In some examples, the LIDAR sensor(s) 1664 may be capable of providing a list of objects and their distances for a 360-degree field of view. Commercially available LIDAR sensor(s) 1664 may have an advertised range of approximately 1600 m, with an accuracy of 2 cm-3 cm, and with support for a 1600 Mbps Ethernet connection, for example. In some examples, one or more non-protruding LIDAR sensors 1664 may be used. In such examples, the LIDAR sensor(s) 1664 may be implemented as a small device that may be embedded into the front, rear, sides, and/or corners of the vehicle 1600. The LIDAR sensor(s) 1664, in such examples, may provide up to a 120-degree horizontal and 35-degree vertical field-of-view, with a 200 m range even for low-reflectivity objects. Front-mounted LIDAR sensor(s) 1664 may be configured for a horizontal field of view between 45 degrees and 135 degrees.

In some examples, LIDAR technologies, such as 3D flash LIDAR, may also be used. 3D Flash LIDAR uses a flash of a laser as a transmission source, to illuminate vehicle surroundings up to approximately 200 m. A flash LIDAR unit includes a receptor, which records the laser pulse transit time and the reflected light on each pixel, which in turn corresponds to the range from the vehicle to the objects. Flash LIDAR may allow for highly accurate and distortion-free images of the surroundings to be generated with every laser flash. In some examples, four flash LIDAR sensors may be deployed, one at each side of the vehicle 1600. Available 3D flash LIDAR systems include a solid-state 3D staring array LIDAR camera with no moving parts other than a fan (e.g., a non-scanning LIDAR device). The flash LIDAR device may use a 5 nanosecond class I (eye-safe) laser pulse per frame and may capture the reflected laser light in the form of 3D range point clouds and co-registered intensity data. By using flash LIDAR, and because flash LIDAR is a solid-state device with no moving parts, the LIDAR sensor(s) 1664 may be less susceptible to motion blur, vibration, and/or shock.

The vehicle may further include IMU sensor(s) 1666. The IMU sensor(s) 1666 may be located at a center of the rear axle of the vehicle 1600, in some examples. The IMU sensor(s) 1666 may include, for example and without limitation, an accelerometer(s), a magnetometer(s), a gyroscope(s), a magnetic compass(es), and/or other sensor types. In some examples, such as in six-axis applications, the IMU sensor(s) 1666 may include accelerometers and gyroscopes, while in nine-axis applications, the IMU sensor(s) 1666 may include accelerometers, gyroscopes, and magnetometers.

In some embodiments, the IMU sensor(s) 1666 may be implemented as a miniature, high performance GPS-Aided Inertial Navigation System (GPS/INS) that combines micro-electro-mechanical systems (MEMS) inertial sensors, a high-sensitivity GPS receiver, and advanced Kalman filtering algorithms to provide estimates of position, velocity, and attitude. As such, in some examples, the IMU sensor(s) 1666 may enable the vehicle 1600 to estimate heading without requiring input from a magnetic sensor by directly observing and correlating the changes in velocity from GPS to the IMU sensor(s) 1666. In some examples, the IMU sensor(s) 1666 and the GNSS sensor(s) 1658 may be combined in a single integrated unit.

The vehicle may include microphone(s) 1696 placed in and/or around the vehicle 1600. The microphone(s) 1696 may be used for emergency vehicle detection and identification, among other things.

The vehicle may further include any number of camera types, including stereo camera(s) 1668, wide-view camera(s) 1670, infrared camera(s) 1672, surround camera(s) 1674, long-range and/or mid-range camera(s) 1698, and/or other camera types. The cameras may be used to capture image data around an entire periphery of the vehicle 1600. The types of cameras used depends on the embodiments and requirements for the vehicle 1600, and any combination of camera types may be used to provide the necessary coverage around the vehicle 1600. In addition, the number of cameras may differ depending on the embodiment. For example, the vehicle may include six cameras, seven cameras, ten cameras, twelve cameras, and/or another number of cameras. The cameras may support, as an example and without limitation, Gigabit Multimedia Serial Link (GMSL) and/or Gigabit Ethernet. Each of the camera(s) is described with more detail herein with respect to FIG. 16A and FIG. 16B.

The vehicle 1600 may further include vibration sensor(s) 1642. The vibration sensor(s) 1642 may measure vibrations of components of the vehicle, such as the axle(s). For example, changes in vibrations may indicate a change in road surfaces. In another example, when two or more vibration sensors 1642 are used, the differences between the vibrations may be used to determine friction or slippage of the road surface (e.g., when the difference in vibration is between a power-driven axle and a freely rotating axle).

The vehicle 1600 may include an ADAS system 1638. The ADAS system 1638 may include a SoC, in some examples. The ADAS system 1638 may include autonomous/adaptive/automatic cruise control (ACC), cooperative adaptive cruise control (CACC), forward crash warning (FCW), automatic emergency braking (AEB), lane departure warnings (LDW), lane keep assist (LKA), blind spot warning (BSW), rear cross-traffic warning (RCTW), collision warning systems (CWS), lane centering (LC), and/or other features and functionality.

The ACC systems may use RADAR sensor(s) 1660, LIDAR sensor(s) 1664, and/or a camera(s). The ACC systems may include longitudinal ACC and/or lateral ACC. Longitudinal ACC monitors and controls the distance to the vehicle immediately ahead of the vehicle 1600 and automatically adjust the vehicle speed to maintain a safe distance from vehicles ahead. Lateral ACC performs distance keeping, and advises the vehicle 1600 to change lanes when necessary. Lateral ACC is related to other ADAS applications such as LCA and CWS.

CACC uses information from other vehicles that may be received via the network interface 1624 and/or the wireless antenna(s) 1626 from other vehicles via a wireless link, or indirectly, over a network connection (e.g., over the Internet). Direct links may be provided by a vehicle-to-vehicle (V2V) communication link, while indirect links may be infrastructure-to-vehicle (I2V) communication link. In general, the V2V communication concept provides information about the immediately preceding vehicles (e.g., vehicles immediately ahead of and in the same lane as the vehicle 1600), while the I2V communication concept provides information about traffic further ahead. CACC systems may include either or both I2V and V2V information sources. Given the information of the vehicles ahead of the vehicle 1600, CACC may be more reliable and it has potential to improve traffic flow smoothness and reduce congestion on the road.

FCW systems are designed to alert the driver to a hazard, so that the driver may take corrective action. FCW systems use a front-facing camera and/or RADAR sensor(s) 1660, coupled to a dedicated processor, DSP, FPGA, and/or ASIC, that is electrically coupled to driver feedback, such as a display, speaker, and/or vibrating component. FCW systems may provide a warning, such as in the form of a sound, visual warning, vibration and/or a quick brake pulse.

AEB systems detect an impending forward collision with another vehicle or other object, and may automatically apply the brakes if the driver does not take corrective action within a specified time or distance parameter. AEB systems may use front-facing camera(s) and/or RADAR sensor(s) 1660, coupled to a dedicated processor, DSP, FPGA, and/or ASIC. When the AEB system detects a hazard, it typically first alerts the driver to take corrective action to avoid the collision and, if the driver does not take corrective action, the AEB system may automatically apply the brakes in an effort to prevent, or at least mitigate, the impact of the predicted collision. AEB systems, may include techniques such as dynamic brake support and/or crash imminent braking.

LDW systems provide visual, audible, and/or tactile warnings, such as steering wheel or seat vibrations, to alert the driver when the vehicle 1600 crosses lane markings. A LDW system does not activate when the driver indicates an intentional lane departure, by activating a turn signal. LDW systems may use front-side facing cameras, coupled to a dedicated processor, DSP, FPGA, and/or ASIC, that is electrically coupled to driver feedback, such as a display, speaker, and/or vibrating component.

LKA systems are a variation of LDW systems. LKA systems provide steering input or braking to correct the vehicle 1600 if the vehicle 1600 starts to exit the lane.

BSW systems detects and warn the driver of vehicles in an automobile's blind spot. BSW systems may provide a visual, audible, and/or tactile alert to indicate that merging or changing lanes is unsafe. The system may provide an additional warning when the driver uses a turn signal. BSW systems may use rear-side facing camera(s) and/or RADAR sensor(s) 1660, coupled to a dedicated processor, DSP, FPGA, and/or ASIC, that is electrically coupled to driver feedback, such as a display, speaker, and/or vibrating component.

RCTW systems may provide visual, audible, and/or tactile notification when an object is detected outside the rear-camera range when the vehicle 1600 is backing up. Some RCTW systems include AEB to ensure that the vehicle brakes are applied to avoid a crash. RCTW systems may use one or more rear-facing RADAR sensor(s) 1660, coupled to a dedicated processor, DSP, FPGA, and/or ASIC, that is electrically coupled to driver feedback, such as a display, speaker, and/or vibrating component.

Conventional ADAS systems may be prone to false positive results which may be annoying and distracting to a driver, but typically are not catastrophic, because the ADAS systems alert the driver and allow the driver to decide whether a safety condition truly exists and act accordingly. However, in an autonomous vehicle 1600, the vehicle 1600 itself must, in the case of conflicting results, decide whether to heed the result from a primary computer or a secondary computer (e.g., a first controller 1636 or a second controller 1636). For example, in some embodiments, the ADAS system 1638 may be a backup and/or secondary computer for providing perception information to a backup computer rationality module. The backup computer rationality monitor may run a redundant diverse software on hardware components to detect faults in perception and dynamic driving tasks. Outputs from the ADAS system 1638 may be provided to a supervisory MCU. If outputs from the primary computer and the secondary computer conflict, the supervisory MCU must determine how to reconcile the conflict to ensure safe operation.

In some examples, the primary computer may be configured to provide the supervisory MCU with a confidence score, indicating the primary computer's confidence in the chosen result. If the confidence score exceeds a threshold, the supervisory MCU may follow the primary computer's direction, regardless of whether the secondary computer provides a conflicting or inconsistent result. Where the confidence score does not meet the threshold, and where the primary and secondary computer indicate different results (e.g., the conflict), the supervisory MCU may arbitrate between the computers to determine the appropriate outcome.

The supervisory MCU may be configured to run a neural network(s) that is trained and configured to determine, based on outputs from the primary computer and the secondary computer, conditions under which the secondary computer provides false alarms. Thus, the neural network(s) in the supervisory MCU may learn when the secondary computer's output may be trusted, and when it cannot. For example, when the secondary computer is a RADAR-based FCW system, a neural network(s) in the supervisory MCU may learn when the FCW system is identifying metallic objects that are not, in fact, hazards, such as a drainage grate or manhole cover that triggers an alarm. Similarly, when the secondary computer is a camera-based LDW system, a neural network in the supervisory MCU may learn to override the LDW when bicyclists or pedestrians are present and a lane departure is, in fact, the safest maneuver. In embodiments that include a neural network(s) running on the supervisory MCU, the supervisory MCU may include at least one of a DLA or GPU suitable for running the neural network(s) with associated memory. In preferred embodiments, the supervisory MCU may comprise and/or be included as a component of the SoC(s) 1604.

In other examples, ADAS system 1638 may include a secondary computer that performs ADAS functionality using traditional rules of computer vision. As such, the secondary computer may use classic computer vision rules (if-then), and the presence of a neural network(s) in the supervisory MCU may improve reliability, safety and performance. For example, the diverse implementation and intentional non-identity makes the overall system more fault-tolerant, especially to faults caused by software (or software-hardware interface) functionality. For example, if there is a software bug or error in the software running on the primary computer, and the non-identical software code running on the secondary computer provides the same overall result, the supervisory MCU may have greater confidence that the overall result is correct, and the bug in software or hardware on primary computer is not causing material error.

In some examples, the output of the ADAS system 1638 may be fed into the primary computer's perception block and/or the primary computer's dynamic driving task block. For example, if the ADAS system 1638 indicates a forward crash warning due to an object immediately ahead, the perception block may use this information when identifying objects. In other examples, the secondary computer may have its own neural network which is trained and thus reduces the risk of false positives, as described herein.

The vehicle 1600 may further include the infotainment SoC 1630 (e.g., an in-vehicle infotainment system (IVI)). Although illustrated and described as a SoC, the infotainment system may not be a SoC, and may include two or more discrete components. The infotainment SoC 1630 may include a combination of hardware and software that may be used to provide audio (e.g., music, a personal digital assistant, navigational instructions, news, radio, etc.), video (e.g., TV, movies, streaming, etc.), phone (e.g., hands-free calling), network connectivity (e.g., LTE, Wi-Fi, etc.), and/or information services (e.g., navigation systems, rear-parking assistance, a radio data system, vehicle related information such as fuel level, total distance covered, brake fuel level, oil level, door open/close, air filter information, etc.) to the vehicle 1600. For example, the infotainment SoC 1630 may radios, disk players, navigation systems, video players, USB and Bluetooth connectivity, carputers, in-car entertainment, Wi-Fi, steering wheel audio controls, hands free voice control, a heads-up display (HUD), an HMI display 1634, a telematics device, a control panel (e.g., for controlling and/or interacting with various components, features, and/or systems), and/or other components. The infotainment SoC 1630 may further be used to provide information (e.g., visual and/or audible) to a user(s) of the vehicle, such as information from the ADAS system 1638, autonomous driving information such as planned vehicle maneuvers, trajectories, surrounding environment information (e.g., intersection information, vehicle information, road information, etc.), and/or other information.

The infotainment SoC 1630 may include GPU functionality. The infotainment SoC 1630 may communicate over the bus 1602 (e.g., CAN bus, Ethernet, etc.) with other devices, systems, and/or components of the vehicle 1600. In some examples, the infotainment SoC 1630 may be coupled to a supervisory MCU such that the GPU of the infotainment system may perform some self-driving functions in the event that the primary controller(s) 1636 (e.g., the primary and/or backup computers of the vehicle 1600) fail. In such an example, the infotainment SoC 1630 may put the vehicle 1600 into a chauffeur to safe stop mode, as described herein.

The vehicle 1600 may further include an instrument cluster 1632 (e.g., a digital dash, an electronic instrument cluster, a digital instrument panel, etc.). The instrument cluster 1632 may include a controller and/or supercomputer (e.g., a discrete controller or supercomputer). The instrument cluster 1632 may include a set of instrumentation such as a speedometer, fuel level, oil pressure, tachometer, odometer, turn indicators, gearshift position indicator, seat belt warning light(s), parking-brake warning light(s), engine-malfunction light(s), airbag (SRS) system information, lighting controls, safety system controls, navigation information, etc. In some examples, information may be displayed and/or shared among the infotainment SoC 1630 and the instrument cluster 1632. In other words, the instrument cluster 1632 may be included as part of the infotainment SoC 1630, or vice versa.

FIG. 16D is a system diagram for communication between cloud-based server(s) and the example autonomous vehicle 1600 of FIG. 16A, in accordance with some embodiments of the present disclosure. The system 1676 may include server(s) 1678, network(s) 1690, and vehicles, including the vehicle 1600. The server(s) 1678 may include a plurality of GPUs 1684(A)-1684(H) (collectively referred to herein as GPUs 1684), PCIe switches 1682(A)-1682(H) (collectively referred to herein as PCIe switches 1682), and/or CPUs 1680(A)-1680(B) (collectively referred to herein as CPUs 1680). The GPUs 1684, the CPUs 1680, and the PCIe switches may be interconnected with high-speed interconnects such as, for example and without limitation, NVLink interfaces 1688 developed by NVIDIA and/or PCIe connections 1686. In some examples, the GPUs 1684 are connected via NVLink and/or NVSwitch SoC and the GPUs 1684 and the PCIe switches 1682 are connected via PCIe interconnects. Although eight GPUs 1684, two CPUs 1680, and two PCIe switches are illustrated, this is not intended to be limiting. Depending on the embodiment, each of the server(s) 1678 may include any number of GPUs 1684, CPUs 1680, and/or PCIe switches. For example, the server(s) 1678 may each include eight, sixteen, thirty-two, and/or more GPUs 1684.

The server(s) 1678 may receive, over the network(s) 1690 and from the vehicles, image data representative of images showing unexpected or changed road conditions, such as recently commenced road-work. The server(s) 1678 may transmit, over the network(s) 1690 and to the vehicles, neural networks 1692, updated neural networks 1692, and/or map information 1694, including information regarding traffic and road conditions. The updates to the map information 1694 may include updates for the HD map 1622, such as information regarding construction sites, potholes, detours, flooding, and/or other obstructions. In some examples, the neural networks 1692, the updated neural networks 1692, and/or the map information 1694 may have resulted from new training and/or experiences represented in data received from any number of vehicles in the environment, and/or based on training performed at a datacenter (e.g., using the server(s) 1678 and/or other servers).

The server(s) 1678 may be used to train machine learning models (e.g., neural networks) based on training data. The training data may be generated by the vehicles, and/or may be generated in a simulation (e.g., using a game engine). In some examples, the training data is tagged (e.g., where the neural network benefits from supervised learning) and/or undergoes other pre-processing, while in other examples the training data is not tagged and/or pre-processed (e.g., where the neural network does not require supervised learning). Training may be executed according to any one or more classes of machine learning techniques, including, without limitation, classes such as: supervised training, semi-supervised training, unsupervised training, self-learning, reinforcement learning, federated learning, transfer learning, feature learning (including principal component and cluster analyses), multi-linear subspace learning, manifold learning, representation learning (including spare dictionary learning), rule-based machine learning, anomaly detection, and any variants or combinations therefor. Once the machine learning models are trained, the machine learning models may be used by the vehicles (e.g., transmitted to the vehicles over the network(s) 1690, and/or the machine learning models may be used by the server(s) 1678 to remotely monitor the vehicles.

In some examples, the server(s) 1678 may receive data from the vehicles and apply the data to up-to-date real-time neural networks for real-time intelligent inferencing. The server(s) 1678 may include deep-learning supercomputers and/or dedicated AI computers powered by GPU(s) 1684, such as a DGX and DGX Station machines developed by NVIDIA. However, in some examples, the server(s) 1678 may include deep learning infrastructure that use only CPU-powered datacenters.

The deep-learning infrastructure of the server(s) 1678 may be capable of fast, real-time inferencing, and may use that capability to evaluate and verify the health of the processors, software, and/or associated hardware in the vehicle 1600. For example, the deep-learning infrastructure may receive periodic updates from the vehicle 1600, such as a sequence of images and/or objects that the vehicle 1600 has located in that sequence of images (e.g., via computer vision and/or other machine learning object classification techniques). The deep-learning infrastructure may run its own neural network to identify the objects and compare them with the objects identified by the vehicle 1600 and, if the results do not match and the infrastructure concludes that the AI in the vehicle 1600 is malfunctioning, the server(s) 1678 may transmit a signal to the vehicle 1600 instructing a fail-safe computer of the vehicle 1600 to assume control, notify the passengers, and complete a safe parking maneuver.

For inferencing, the server(s) 1678 may include the GPU(s) 1684 and one or more programmable inference accelerators (e.g., NVIDIA's TensorRT). The combination of GPU-powered servers and inference acceleration may make real-time responsiveness possible. In other examples, such as where performance is less critical, servers powered by CPUs, FPGAs, and other processors may be used for inferencing.

### Example Computing Device

FIG. 17 is a block diagram of an example computing device(s) 1700 suitable for use in implementing some embodiments of the present disclosure. Computing device 1700 may include an interconnect system 1702 that directly or indirectly couples the following devices: memory 1704, one or more central processing units (CPUs) 1706, one or more graphics processing units (GPUs) 1708, a communication interface 1710, input/output (I/O) ports 1712, input/output components 1714, a power supply 1716, one or more presentation components 1718 (e.g., display(s)), and one or more logic units 1720. In at least one embodiment, the computing device(s) 1700 may comprise one or more virtual machines (VMs), and/or any of the components thereof may comprise virtual components (e.g., virtual hardware components). For non-limiting examples, one or more of the GPUs 1708 may comprise one or more vGPUs, one or more of the CPUs 1706 may comprise one or more vCPUs, and/or one or more of the logic units 1720 may comprise one or more virtual logic units. As such, a computing device(s) 1700 may include discrete components (e.g., a full GPU dedicated to the computing device 1700), virtual components (e.g., a portion of a GPU dedicated to the computing device 1700), or a combination thereof.

Although the various blocks of FIG. 17 are shown as connected via the interconnect system 1702 with lines, this is not intended to be limiting and is for clarity only. For example, in some embodiments, a presentation component 1718, such as a display device, may be considered an I/O component 1714 (e.g., if the display is a touch screen). As another example, the CPUs 1706 and/or GPUs 1708 may include memory (e.g., the memory 1704 may be representative of a storage device in addition to the memory of the GPUs 1708, the CPUs 1706, and/or other components). As such, the computing device of FIG. 17 is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 17.

The interconnect system 1702 may represent one or more links or busses, such as an address bus, a data bus, a control bus, or a combination thereof. The interconnect system 1702 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, and/or another type of bus or link. In some embodiments, there are direct connections between components. As an example, the CPU 1706 may be directly connected to the memory 1704. Further, the CPU 1706 may be directly connected to the GPU 1708. Where there is direct, or point-to-point connection between components, the interconnect system 1702 may include a PCIe link to carry out the connection. In these examples, a PCI bus need not be included in the computing device 1700.

The memory 1704 may include any of a variety of computer-readable media. The computer-readable media may be any available media that may be accessed by the computing device 1700. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the memory 1704 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by computing device 1700. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

The CPU(s) 1706 may be configured to execute at least some of the computer-readable instructions to control one or more components of the computing device 1700 to perform one or more of the methods and/or processes described herein. The CPU(s) 1706 may each include one or more cores (e.g., one, two, four, eight, twenty-eight, seventy-two, etc.) that are capable of handling a multitude of software threads simultaneously. The CPU(s) 1706 may include any type of processor, and may include different types of processors depending on the type of computing device 1700 implemented (e.g., processors with fewer cores for mobile devices and processors with more cores for servers). For example, depending on the type of computing device 1700, the processor may be an Advanced RISC Machines (ARM) processor implemented using Reduced Instruction Set Computing (RISC) or an x86 processor implemented using Complex Instruction Set Computing (CISC). The computing device 1700 may include one or more CPUs 1706 in addition to one or more microprocessors or supplementary co-processors, such as math co-processors.

In addition to or alternatively from the CPU(s) 1706, the GPU(s) 1708 may be configured to execute at least some of the computer-readable instructions to control one or more components of the computing device 1700 to perform one or more of the methods and/or processes described herein. One or more of the GPU(s) 1708 may be an integrated GPU (e.g., with one or more of the CPU(s) 1706 and/or one or more of the GPU(s) 1708 may be a discrete GPU. In embodiments, one or more of the GPU(s) 1708 may be a coprocessor of one or more of the CPU(s) 1706. The GPU(s) 1708 may be used by the computing device 1700 to render graphics (e.g., 3D graphics) or perform general purpose computations. For example, the GPU(s) 1708 may be used for General-Purpose computing on GPUs (GPGPU). The GPU(s) 1708 may include hundreds or thousands of cores that are capable of handling hundreds or thousands of software threads simultaneously. The GPU(s) 1708 may generate pixel data for output images in response to rendering commands (e.g., rendering commands from the CPU(s) 1706 received via a host interface). The GPU(s) 1708 may include graphics memory, such as display memory, for storing pixel data or any other suitable data, such as GPGPU data. The display memory may be included as part of the memory 1704. The GPU(s) 1708 may include two or more GPUs operating in parallel (e.g., via a link). The link may directly connect the GPUs (e.g., using NVLINK) or may connect the GPUs through a switch (e.g., using NVSwitch). When combined together, each GPU 1708 may generate pixel data or GPGPU data for different portions of an output or for different outputs (e.g., a first GPU for a first image and a second GPU for a second image). Each GPU may include its own memory, or may share memory with other GPUs.

In addition to or alternatively from the CPU(s) 1706 and/or the GPU(s) 1708, the logic unit(s) 1720 may be configured to execute at least some of the computer-readable instructions to control one or more components of the computing device 1700 to perform one or more of the methods and/or processes described herein. In embodiments, the CPU(s) 1706, the GPU(s) 1708, and/or the logic unit(s) 1720 may discretely or jointly perform any combination of the methods, processes and/or portions thereof. One or more of the logic units 1720 may be part of and/or integrated in one or more of the CPU(s) 1706 and/or the GPU(s) 1708 and/or one or more of the logic units 1720 may be discrete components or otherwise external to the CPU(s) 1706 and/or the GPU(s) 1708. In embodiments, one or more of the logic units 1720 may be a coprocessor of one or more of the CPU(s) 1706 and/or one or more of the GPU(s) 1708.

Examples of the logic unit(s) 1720 include one or more processing cores and/or components thereof, such as Data Processing Units (DPUs), Tensor Cores (TCs), Tensor Processing Units (TPUs), Pixel Visual Cores (PVCs), Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Programmable Vision Accelerator (PVAs)—which may include one or more direct memory access (DMA) systems, one or more vision or vector processing units (VPUs), one or more pixel processing engines (PPEs)—e.g., including a 2D array of processing elements that each communicate north, south, east, and west with one or more other processing elements in the array, one or more decoupled accelerators or units (e.g., decoupled lookup table (DLUT) accelerators or units), etc., Vision Processing Units (VPUs), Optical Flow Accelerators (OFAs), Field Programmable Gate Arrays (FPGAs), Neuromorphic Chips, Quantum Processing Units (QPUs), Associative Process Units (APUs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The communication interface 1710 may include one or more receivers, transmitters, and/or transceivers that allow the computing device 1700 to communicate with other computing devices via an electronic communication network, included wired and/or wireless communications. The communication interface 1710 may include components and functionality to allow communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet. In one or more embodiments, logic unit(s) 1720 and/or communication interface 1710 may include one or more data processing units (DPUs) to transmit data received over a network and/or through interconnect system 1702 directly to (e.g., a memory of) one or more GPU(s) 1708.

The I/O ports 1712 may allow the computing device 1700 to be logically coupled to other devices including the I/O components 1714, the presentation component(s) 1718, and/or other components, some of which may be built in to (e.g., integrated in) the computing device 1700. Illustrative I/O components 1714 include a microphone, mouse, keyboard, joystick, game pad, game controller, satellite dish, scanner, printer, wireless device, etc. The I/O components 1714 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the computing device 1700. The computing device 1700 may be include depth cameras, such as stereoscopic camera systems, infrared camera systems, RGB camera systems, touchscreen technology, and combinations of these, for gesture detection and recognition. Additionally, the computing device 1700 may include accelerometers or gyroscopes (e.g., as part of an inertia measurement unit (IMU)) that allow detection of motion. In some examples, the output of the accelerometers or gyroscopes may be used by the computing device 1700 to render immersive augmented reality or virtual reality.

The power supply 1716 may include a hard-wired power supply, a battery power supply, or a combination thereof. The power supply 1716 may provide power to the computing device 1700 to allow the components of the computing device 1700 to operate.

The presentation component(s) 1718 may include a display (e.g., a monitor, a touch screen, a television screen, a heads-up-display (HUD), other display types, or a combination thereof), speakers, and/or other presentation components. The presentation component(s) 1718 may receive data from other components (e.g., the GPU(s) 1708, the CPU(s) 1706, DPUs, etc.), and output the data (e.g., as an image, video, sound, etc.).

FIG. 18 illustrates an example data center 1800 that may be used in at least one embodiments of the present disclosure. The data center 1800 may include a data center infrastructure layer 1810, a framework layer 1820, a software layer 1830, and/or an application layer 1840.

### Example Data Center

As shown in FIG. 18, the data center infrastructure layer 1810 may include a resource orchestrator 1812, grouped computing resources 1814, and node computing resources (“node C.R.s”) 1816(1)-1816(N), where “N” represents any whole, positive integer. In at least one embodiment, node C.R.s 1816(1)-1816(N) may include, but are not limited to, any number of central processing units (CPUs) or other processors (including DPUs, accelerators, field programmable gate arrays (FPGAs), graphics processors or graphics processing units (GPUs), etc.), memory devices (e.g., dynamic read-only memory), storage devices (e.g., solid state or disk drives), network input/output (NW I/O) devices, network switches, virtual machines (VMs), power modules, and/or cooling modules, etc. In some embodiments, one or more node C.R.s from among node C.R.s 1816(1)-1816(N) may correspond to a server having one or more of the above-mentioned computing resources. In addition, in some embodiments, the node C.R.s 1816(1)-18161(N) may include one or more virtual components, such as vGPUs, vCPUs, and/or the like, and/or one or more of the node C.R.s 1816(1)-1816(N) may correspond to a virtual machine (VM).

In at least one embodiment, grouped computing resources 1814 may include separate groupings of node C.R.s 1816 housed within one or more racks (not shown), or many racks housed in data centers at various geographical locations (also not shown). Separate groupings of node C.R.s 1816 within grouped computing resources 1814 may include grouped compute, network, memory or storage resources that may be configured or allocated to support one or more workloads. In at least one embodiment, several node C.R.s 1816 including CPUs, GPUs, DPUs, and/or other processors may be grouped within one or more racks to provide compute resources to support one or more workloads. The one or more racks may also include any number of power modules, cooling modules, and/or network switches, in any combination.

The resource orchestrator 1812 may configure or otherwise control one or more node C.R.s 1816(1)-1816(N) and/or grouped computing resources 1814. In at least one embodiment, resource orchestrator 1812 may include a software design infrastructure (SDI) management entity for the data center 1800. The resource orchestrator 1812 may include hardware, software, or some combination thereof.

In at least one embodiment, as shown in FIG. 18, framework layer 1820 may include a job scheduler 1828, a configuration manager 1834, a resource manager 1836, and/or a distributed file system 1838. The framework layer 1820 may include a framework to support software 1832 of software layer 1830 and/or one or more application(s) 1842 of application layer 1840. The software 1832 or application(s) 1842 may respectively include web-based service software or applications, such as those provided by Amazon Web Services, Google Cloud and Microsoft Azure. The framework layer 1820 may be, but is not limited to, a type of free and open-source software web application framework such as Apache Spark™ (hereinafter “Spark”) that may use distributed file system 1838 for large-scale data processing (e.g., “big data”). In at least one embodiment, job scheduler 1828 may include a Spark driver to facilitate scheduling of workloads supported by various layers of data center 1800. The configuration manager 1834 may be capable of configuring different layers such as software layer 1830 and framework layer 1820 including Spark and distributed file system 1838 for supporting large-scale data processing. The resource manager 1836 may be capable of managing clustered or grouped computing resources mapped to or allocated for support of distributed file system 1838 and job scheduler 1828. In at least one embodiment, clustered or grouped computing resources may include grouped computing resource 1814 at data center infrastructure layer 1810. The resource manager 1836 may coordinate with resource orchestrator 1812 to manage these mapped or allocated computing resources.

In at least one embodiment, software 1832 included in software layer 1830 may include software used by at least portions of node C.R.s 1816(1)-1816(N), grouped computing resources 1814, and/or distributed file system 1838 of framework layer 1820. One or more types of software may include, but are not limited to, Internet web page search software, e-mail virus scan software, database software, and streaming video content software.

In at least one embodiment, application(s) 1842 included in application layer 1840 may include one or more types of applications used by at least portions of node C.R.s 1816(1)-1816(N), grouped computing resources 1814, and/or distributed file system 1838 of framework layer 1820. One or more types of applications may include, but are not limited to, any number of a genomics application, a cognitive compute, and a machine learning application, including training or inferencing software, machine learning framework software (e.g., PyTorch, TensorFlow, Caffe, etc.), and/or other machine learning applications used in conjunction with one or more embodiments.

In at least one embodiment, any of configuration manager 1834, resource manager 1836, and resource orchestrator 1812 may implement any number and type of self-modifying actions based on any amount and type of data acquired in any technically feasible fashion. Self-modifying actions may relieve a data center operator of data center 1800 from making possibly bad configuration decisions and possibly avoiding underutilized and/or poor performing portions of a data center.

The data center 1800 may include tools, services, software or other resources to train one or more machine learning models or predict or infer information using one or more machine learning models according to one or more embodiments described herein. For example, a machine learning model(s) may be trained by calculating weight parameters according to a neural network architecture using software and/or computing resources described above with respect to the data center 1800. In at least one embodiment, trained or deployed machine learning models corresponding to one or more neural networks may be used to infer or predict information using resources described above with respect to the data center 1800 by using weight parameters calculated through one or more training techniques, such as but not limited to those described herein.

In at least one embodiment, the data center 1800 may use CPUs, application-specific integrated circuits (ASICs), GPUs, FPGAs, and/or other hardware (or virtual compute resources corresponding thereto) to perform training and/or inferencing using above-described resources. Moreover, one or more software and/or hardware resources described above may be configured as a service to allow users to train or performing inferencing of information, such as image recognition, speech recognition, or other artificial intelligence services.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the computing device(s) 1700 of FIG. 17—e.g., each device may include similar components, features, and/or functionality of the computing device(s) 1700. In addition, where backend devices (e.g., servers, NAS, etc.) are implemented, the backend devices may be included as part of a data center 1800, an example of which is described in more detail herein with respect to FIG. 18.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example computing device(s) 1700 described herein with respect to FIG. 17. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

The disclosure may be described in the general context of computer code or machine-useable instructions, including computer-executable instructions such as program modules, being executed by a computer or other machine, such as a personal data assistant or other handheld device. Generally, program modules including routines, programs, objects, components, data structures, etc., refer to code that perform particular tasks or implement particular abstract data types. The disclosure may be practiced in a variety of system configurations, including hand-held devices, consumer electronics, general-purpose computers, more specialty computing devices, etc. The disclosure may also be practiced in distributed computing environments where tasks are performed by remote-processing devices that are linked through a communications network.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure.

Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

### EXAMPLE PARAGRAPHS

A. A method comprising: generating, based at least on using one or more language models to process input data corresponding to a request, text data representing one or more tasks associated with moving one or more items in an environment; generating, based at least on image data representing one or more images depicting one or more portions of the environment, a simulated version of the environment; determining, using the simulated version of the environment and based at least on the text data, one or more machines from among a plurality of machines that are located within a threshold proximity of one or more first locations in the environment corresponding to the one or more items; and based at least on the one or more machines being located within the threshold proximity of the one or more first locations, causing the one or more machines to perform one or more control operations to move the one or more items from the one or more first locations to one or more second locations in the environment.

B. The method of paragraph A, further comprising: updating, based at least on second image data representing one or more second images depicting the one or more portions of the environment, the simulated version of the environment; and causing, based at least on the updating of the simulated version of the environment, the one or more machines to perform one or more second control operations.

C. The method of any one of paragraphs A-B, wherein: the one or more machines comprise one or more autonomous robots including one or more manipulators, and causing the one or more machines to perform the one or more control operations comprises causing the one or more autonomous robots to use the one or more manipulators to at least one of grasp, lift, or transport the one or more items from the one or more first locations to the one or more second locations.

D. The method of any one of paragraphs A-C, further comprising: determining, using the simulated version of the environment, a plurality of paths traversable by the one or more machines to move from one or more current locations to the one or more first locations; determining one or more optimal paths from among the plurality of paths based at least on the one or more optimal paths being shorter than one or other paths; and causing the one or more machines to perform one or more second control operations to traverse the one or more optimal paths.

E. The method of any one of paragraphs A-D, further comprising: obtaining sensor data generated using one or more sensors of the one or more machines; detecting, based at least on the sensor data, a presence of one or more obstacles along one or more planned paths of the one or more machines; and causing the one or more machines to perform one or more second control operations to at least partially deviate from the one or more planned paths.

F. The method of any one of paragraphs A-E, further comprising: generating one or more three-dimensional (3D) models corresponding to the one or more items, wherein the generating of the simulated version of the environment comprises updating the simulated version of the environment to include the one or more 3D models positioned at the one or more first locations.

G. The method of any one of paragraphs A-F, further comprising: generating, based at least on the simulated version of the environment, one or more waypoint graphs including at least one or more first nodes corresponding to the one or more first locations and one or more second nodes corresponding to one or more current locations of the one or more machines; and determining, based at least on computing one or more distances between the one or more first nodes and the one or more second nodes, one or more paths for the one or more machines to traverse between the one or more current locations and the one or more first locations, wherein the one or more control operations cause the one or more machines to traverse the one or more paths.

H. A system comprising: one or more processors to: generate, based at least on image data representing one or more images of an environment, a simulation of the environment; determine, using the simulation of the environment, one or more machines located within a threshold proximity of one or more items; and based at least on the one or more machines being located within the threshold proximity of the one or more items, cause the one or more machines to reposition the one or more items from one or more first locations in the environment to one or more second locations in the environment.

I. The system of paragraph H, the one or more processors further to: update, based at least on second image data representing one or more second images of the environment, the simulation of the environment; and cause, based at least on the update of the simulation of the environment, the one or more machines to perform one or more control operations.

J. The system of any one of paragraphs H-I, wherein: the one or more machines comprise one or more autonomous robots including one or more manipulators, and causing the one or more machines to reposition the one or more items comprises causing the one or more autonomous robots to use the one or more manipulators to at least one of grasp, lift, place, or transport the one or more items.

K. The system of any one of paragraphs H-J, the one or more processors further to: determine, using the simulation of the environment, a plurality of paths traversable by the one or more machines to reposition the one or more items from the one or more first locations to the one or more second locations; determine one or more optimal paths from among the plurality of paths; and cause the one or more machines to traverse the one or more optimal paths to reposition the one or more items from the one or more first locations to the one or more second locations.

L. The system of any one of paragraphs H-K, the one or more processors further to: detect, based at least on sensor data generated using one or more sensors, a presence of one or more obstacles along one or more planned paths of the one or more machines; and cause the one or more machines to perform one or more control operations to at least partially deviate from the one or more planned paths.

M. The system of any one of paragraphs H-L, the one or more processors further to: generate one or more three-dimensional (3D) models corresponding to the one or more items, wherein the generation of the simulation of the environment comprises updating the simulation of the environment to include the one or more 3D models.

N. The system of any one of paragraphs H-M, the one or more processors further to: generate, based at least on the simulation of the environment, one or more waypoint graphs including a plurality of nodes corresponding to a plurality of locations in the environment; and determine, based at least on computing one or more distances between one or more first nodes and one or more second nodes of the plurality of nodes, one or more paths for the one or more machines to traverse between the one or more first locations and the one or more second locations, wherein the one or more machines reposition the one or more items from the one or more first locations to the one or more second locations along the one or more paths.

O. The system of any one of paragraphs H-N, wherein the simulation of the environment comprises a digital twin of the environment generated using one or more light transport simulation techniques.

P. The system of any one of paragraphs H-O, the one or more processors further to: generate, based at least on using one or more language models to process input data corresponding to a request, text data representing one or more tasks associated with moving the one or more items in the environment, wherein the determination of the one or more machines located within the threshold proximity of the one or more items is based at least on the text data.

Q. The system of any one of paragraphs H-P, the one or more processors further to update the simulation of the environment based at least on the movement of the one or more items from the one or more first locations to the one or more second locations.

R. The system of any one of paragraphs H-Q, wherein the system is comprised in at least one of: a control system for an autonomous or semi-autonomous machine; a perception system for an autonomous or semi-autonomous machine; a system for performing simulation operations; a system for performing digital twin operations; a system for performing light transport simulation; a system for performing collaborative content creation for 3D assets; a system for performing deep learning operations; a system for performing remote operations; a system for performing real-time streaming; a system for generating or presenting one or more of augmented reality content, virtual reality content, or mixed reality content; a system implemented using an edge device; a system implemented using a robot; a system for performing conversational AI operations; a system implementing one or more multi-modal language models; a system implementing one or more large language models (LLMs); a system implementing one or more small language models (SLMs); a system implementing one or more vision language models (VLMs); a system for generating synthetic data using AI; a system incorporating one or more virtual machines (VMs); a system using or deploying one or more inference microservices; a system that incorporates one or more machine learning models deployed in a service or microservice along with an OS-level virtualization package (e.g., a container); a system implemented at least partially in a data center; or a system implemented at least partially using cloud computing resources.

S. One or more processors comprising: processing circuitry to send, to one or more autonomous robots operating in an environment, one or more control inputs to cause the one or more autonomous robots to manipulate one or more items in the environment, wherein the one or more autonomous robots are selected from among a plurality of autonomous robots based at least on: generating a simulated version of the environment based at least on image data representing one or more images of the environment; and determining, using the simulated version of the environment, that the one or more autonomous robots are located within a threshold proximity of the one or more items.

T. The one or more processors of paragraph S, wherein the one or more processors are comprised in at least one of: a control system for an autonomous or semi-autonomous machine; a perception system for an autonomous or semi-autonomous machine; a system for performing simulation operations; a system for performing digital twin operations; a system for performing light transport simulation; a system for performing collaborative content creation for 3D assets; a system for performing deep learning operations; a system for performing remote operations; a system for performing real-time streaming; a system for generating or presenting one or more of augmented reality content, virtual reality content, or mixed reality content; a system implemented using an edge device; a system implemented using a robot; a system for performing conversational AI operations; a system implementing one or more multi-modal language models; a system implementing one or more large language models (LLMs); a system implementing one or more small language models (SLMs); a system implementing one or more vision language models (VLMs); a system for generating synthetic data using AI; a system incorporating one or more virtual machines (VMs); a system using or deploying one or more inference microservices; a system that incorporates one or more machine learning models deployed in a service or microservice along with an OS-level virtualization package (e.g., a container); a system implemented at least partially in a data center; or a system implemented at least partially using cloud computing resources.

What is claimed is:

1. A method comprising:
generating, based at least on using one or more language models to process input data corresponding to a request, text data representing one or more tasks associated with moving one or more items in an environment;
generating, based at least on image data representing one or more images depicting one or more portions of the environment, a simulated version of the environment;
determining, using the simulated version of the environment and based at least on the text data, one or more machines from among a plurality of machines that are located within a threshold proximity of one or more first locations in the environment corresponding to the one or more items; and
based at least on the one or more machines being located within the threshold proximity of the one or more first locations, causing the one or more machines to perform one or more control operations to move the one or more items from the one or more first locations to one or more second locations in the environment.

2. The method of claim 1, further comprising:
updating, based at least on second image data representing one or more second images depicting the one or more portions of the environment, the simulated version of the environment; and
causing, based at least on the updating of the simulated version of the environment, the one or more machines to perform one or more second control operations.

3. The method of claim 1, wherein:
the one or more machines comprise one or more autonomous robots including one or more manipulators, and
causing the one or more machines to perform the one or more control operations comprises causing the one or more autonomous robots to use the one or more manipulators to at least one of grasp, lift, or transport the one or more items from the one or more first locations to the one or more second locations.

4. The method of claim 1, further comprising:
determining, using the simulated version of the environment, a plurality of paths traversable by the one or more machines to move from one or more current locations to the one or more first locations;
determining one or more optimal paths from among the plurality of paths based at least on the one or more optimal paths being shorter than one or other paths; and
causing the one or more machines to perform one or more second control operations to traverse the one or more optimal paths.

5. The method of claim 1, further comprising:
obtaining sensor data generated using one or more sensors of the one or more machines;
detecting, based at least on the sensor data, a presence of one or more obstacles along one or more planned paths of the one or more machines; and
causing the one or more machines to perform one or more second control operations to at least partially deviate from the one or more planned paths.

6. The method of claim 1, further comprising:
generating one or more three-dimensional (3D) models corresponding to the one or more items,
wherein the generating of the simulated version of the environment comprises updating the simulated version of the environment to include the one or more 3D models positioned at the one or more first locations.

7. The method of claim 1, further comprising:
generating, based at least on the simulated version of the environment, one or more waypoint graphs including at least one or more first nodes corresponding to the one or more first locations and one or more second nodes corresponding to one or more current locations of the one or more machines; and
determining, based at least on computing one or more distances between the one or more first nodes and the one or more second nodes, one or more paths for the one or more machines to traverse between the one or more current locations and the one or more first locations,
wherein the one or more control operations cause the one or more machines to traverse the one or more paths.

8. A system comprising:
one or more processors to:
generate, based at least on image data representing one or more images of an environment, a simulation of the environment;
determine, using the simulation of the environment, one or more machines located within a threshold proximity of one or more items; and
based at least on the one or more machines being located within the threshold proximity of the one or more items, cause the one or more machines to reposition the one or more items from one or more first locations in the environment to one or more second locations in the environment.

9. The system of claim 8, the one or more processors further to:
update, based at least on second image data representing one or more second images of the environment, the simulation of the environment; and
cause, based at least on the update of the simulation of the environment, the one or more machines to perform one or more control operations.

10. The system of claim 8, wherein:
the one or more machines comprise one or more autonomous robots including one or more manipulators, and
causing the one or more machines to reposition the one or more items comprises causing the one or more autonomous robots to use the one or more manipulators to at least one of grasp, lift, place, or transport the one or more items.

11. The system of claim 8, the one or more processors further to:
determine, using the simulation of the environment, a plurality of paths traversable by the one or more machines to reposition the one or more items from the one or more first locations to the one or more second locations;
determine one or more optimal paths from among the plurality of paths; and
cause the one or more machines to traverse the one or more optimal paths to reposition the one or more items from the one or more first locations to the one or more second locations.

12. The system of claim 8, the one or more processors further to:
detect, based at least on sensor data generated using one or more sensors, a presence of one or more obstacles along one or more planned paths of the one or more machines; and
cause the one or more machines to perform one or more control operations to at least partially deviate from the one or more planned paths.

13. The system of claim 8, the one or more processors further to:
generate one or more three-dimensional (3D) models corresponding to the one or more items,
wherein the generation of the simulation of the environment comprises updating the simulation of the environment to include the one or more 3D models.

14. The system of claim 8, the one or more processors further to:
generate, based at least on the simulation of the environment, one or more waypoint graphs including a plurality of nodes corresponding to a plurality of locations in the environment; and
determine, based at least on computing one or more distances between one or more first nodes and one or more second nodes of the plurality of nodes, one or more paths for the one or more machines to traverse between the one or more first locations and the one or more second locations,
wherein the one or more machines reposition the one or more items from the one or more first locations to the one or more second locations along the one or more paths.

15. The system of claim 8, wherein the simulation of the environment comprises a digital twin of the environment generated using one or more light transport simulation techniques.

16. The system of claim 8, the one or more processors further to:
generate, based at least on using one or more language models to process input data corresponding to a request, text data representing one or more tasks associated with moving the one or more items in the environment,
wherein the determination of the one or more machines located within the threshold proximity of the one or more items is based at least on the text data.

17. The system of claim 8, the one or more processors further to update the simulation of the environment based at least on the movement of the one or more items from the one or more first locations to the one or more second locations.

18. The system of claim 8, wherein the system is comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more multi-modal language models;
a system implementing one or more large language models (LLMs);
a system implementing one or more small language models (SLMs);
a system implementing one or more vision language models (VLMs);
a system for generating synthetic data using AI;
a system incorporating one or more virtual machines (VMs);
a system using or deploying one or more inference microservices;
a system that incorporates one or more machine learning models deployed in a service or microservice along with an OS-level virtualization package (e.g., a container);
a system implemented at least partially in a data center; or
a system implemented at least partially using cloud computing resources.

19. One or more processors comprising:
processing circuitry to send, to one or more autonomous robots operating in an environment, one or more control inputs to cause the one or more autonomous robots to manipulate one or more items in the environment, wherein the one or more autonomous robots are selected from among a plurality of autonomous robots based at least on:
generating a simulated version of the environment based at least on image data representing one or more images of the environment; and
determining, using the simulated version of the environment, that the one or more autonomous robots are located within a threshold proximity of the one or more items.

20. The one or more processors of claim 19, wherein the one or more processors are comprised in at least one of:
a control system for an autonomous or semi-autonomous machine;
a perception system for an autonomous or semi-autonomous machine;
a system for performing simulation operations;
a system for performing digital twin operations;
a system for performing light transport simulation;
a system for performing collaborative content creation for 3D assets;
a system for performing deep learning operations;
a system for performing remote operations;
a system for performing real-time streaming;
a system for generating or presenting one or more of augmented reality content, virtual reality content, or mixed reality content;
a system implemented using an edge device;
a system implemented using a robot;
a system for performing conversational AI operations;
a system implementing one or more multi-model language models;
a system implementing one or more large language models (LLMs);
a system implementing one or more small language models (SLMs);
a system implementing one or more vision language models (VLMs);
a system for generating synthetic data using AI;
a system incorporating one or more virtual machines (VMs);
a system using or deploying one or more inference microservices;
a system that incorporates one or more machine learning models deployed in a service or microservice along with an OS-level virtualization package (e.g., a container);
a system implemented at least partially in a data center; or
a system implemented at least partially using cloud computing resources.
